(19) United States
(12) Patent Application Publication
(10) Pub. No.: US 2021/0278761 A1
(43) Pub. Date: Sep. 9, 2021

(54) COLORING PHOTOSENSITIVE COMPOSITION, FILM, COLOR FILTER, SOLID-STATE IMAGING ELEMENT, AND IMAGE DISPLAY DEVICE

(71) Applicant: FUJIFILM Corporation, Tokyo (JP)

(72) Inventors: Masaomi MAKINO, Shizuoka (JP); Hiroaki IDEI, Shizuoka (JP); Yasuhiro SAWAMURA, Shizuoka (JP)

(73) Assignee: FUJIFILM Corporation, Tokyo (JP)

(21) Appl. No.: 17/329,177

(22) Filed: May 25, 2021

Related U.S. Application Data
(63) Continuation of application No. PCT/JP2019/045535, filed on Nov. 21, 2019.

(30) Foreign Application Priority Data
Nov. 27, 2018 (JP) 2018-221327

(51) Int. Cl. G03F 7/00; G03F 7/028; G03F 7/38; G03F 7/32; G03F 7/40; G03F 7/105; C09B 62/04; C09B 47/04; G02B 5/22

(52) U.S. Cl. CPC G03F 7/0007; G03F 7/028; G03F 7/38; G03F 7/327; G02B 5/223; G03F 7/40; G03F 7/105; C09B 62/04; C09B 47/04; G03F 7/322

(57) ABSTRACT

Provided are a coloring photosensitive composition including, a pigment derivative A1 in which a maximum value of a molar light absorption coefficient in a wavelength range of 400 to 700 nm is 3,000 L·mol⁻¹·cm⁻¹ or less, a pigment derivative A2 in which a maximum value of a molar light absorption coefficient in a wavelength range of 400 to 700 nm is more than 3,000 L·mol⁻¹·cm⁻¹, a pigment, a polymerizable compound, a photopolymerization initiator; a film formed from the coloring photosensitive composition; a color filter; a solid-state imaging element; and an image display device.

### CROSS-REFERENCE TO RELATED APPLICATIONS

This application is a Continuation of PCT International Application No. PCT/JP2019/045535 filed on Nov. 21, 2019, which claims priority under 35 U.S.C § 119(a) to Japanese Patent Application No. 2018-221327 filed on Nov. 27, 2018. Each of the above application(s) is hereby expressly incorporated by reference, in its entirety, into the present application.

### BACKGROUND OF THE INVENTION

### 1. Field of the Invention

The present invention relates to a coloring photosensitive composition including a pigment. The present invention further relates to a film formed from the coloring photosensitive composition, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. As a key device of a display or an optical element, a color filter, an infrared cut filter, and the like have been used.

The color filter or the infrared cut filter is manufactured by using a coloring photosensitive composition including a colorant and a polymerizable compound. In addition, in a case where a pigment is used as the colorant, the pigment is generally dispersed in the coloring photosensitive composition using a dispersant or the like.

JP2003-081972A discloses an invention relating to a coloring photosensitive composition which includes a pigment dispersion composition prepared by dispersing a predetermined triazine compound and a pigment in an organic solvent, a binder polymer having an acidic group, a polyfunctional monomer having two or more ethylenically unsaturated double bonds, and a photopolymerization initiator.

In addition, JP2000-239554A discloses a pigment dispersing agent characterized by containing an azo coloring agent having a specific structure.

### SUMMARY OF THE INVENTION

For a film formed by using the coloring photosensitive composition, further improvement in both adhesiveness with a support and contrast of the obtained film is desired.

In JP2003-081972A, dispersion stability of the composition after dispersing the pigment is studied, but adhesiveness with the support is not studied at all. In addition, there is room for further improvement in contrast of the obtained film.

In addition, in JP2000-239554A, improvement in contrast of the obtained film is disclosed, but adhesiveness with the support is not studied at all.

Therefore, an object of the present invention is to provide a coloring photosensitive composition capable of forming a film excellent in both adhesiveness with a support and contrast of the obtained film. Another object of the present invention is to provide a film formed from the above-described coloring photosensitive composition, a color filter, a solid-state imaging element, and an image display device.

According to the studies conducted by the present inventor, it has been found that the above-described object can be achieved by adopting the following configuration, thereby leading to the completion of the present invention. Therefore, the present invention provides the following.

<1> A coloring photosensitive composition comprising:

a pigment derivative A1 in which a maximum value of a molar light absorption coefficient in a wavelength range of 400 to 700 nm is 3,000 L·mol⁻¹·cm⁻¹ or less;

a pigment derivative A2 in which a maximum value of a molar light absorption coefficient in a wavelength range of 400 to 700 nm is more than 3,000 L·mol⁻¹·cm⁻¹;

a pigment;

a polymerizable compound; and

a photopolymerization initiator.

<2> The coloring photosensitive composition according to <1>,

in which a content of the pigment derivative A1 is 50% to 90% by mass with respect to a total mass of the pigment derivative A1 and the pigment derivative A2.

<3> The coloring photosensitive composition according to <1> or <2>,

in which a total content of the pigment derivative A1 and the pigment derivative A2 is 1 to 30 parts by mass with respect to 100 parts by mass of the pigment.

<4> The coloring photosensitive composition according to any one of <1> to <3>,

in which the pigment derivative A1 is a compound represented by Formula (1),

A¹-L¹-Z¹ (1)

in Formula (1), A¹ represents a group including an aromatic ring,

L¹ represents a single bond or a divalent linking group, and

Z¹ represents a group represented by Formula (Z1),

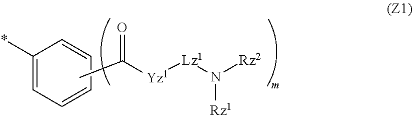

in Formula (Z1), * represents a bonding hand,
Yz¹ represents —N(Ry¹)— or —O—, where Ry′ represents a hydrogen atom or a hydrocarbon group,
Lz¹ represents a single bond or a divalent linking group,
Rz¹ and Rz² each independently represent a hydrogen atom or a hydrocarbon group, where Rz¹ and Rz² may be bonded to each other through a divalent group to form a ring, and
m represents an integer of 1 to 5.

<5> The coloring photosensitive composition according to <4>,

in which the group represented by Formula (Z1) is a group represented by Formula (Z2),

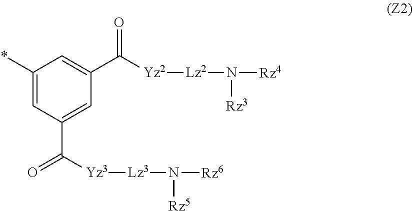

in Formula (Z2), * represents a bonding hand,

Yz² and Yz³ each independently represent —N(Ry²)— or —O—, where Ry^{e} represents a hydrogen atom or a hydrocarbon group,

Lz² and Lz³ each independently represent a divalent linking group, and

Rz³ to Rz⁶ each independently represent a hydrogen atom or a hydrocarbon group, where Rz³ and Rz⁴, and Rz⁵ and Rz⁶ may be respectively bonded to each other through a divalent group to form a ring.

<6> The coloring photosensitive composition according to any one of <1> to <5>,

in which the pigment derivative A2 includes a compound having a coloring agent partial structure, and

the coloring agent partial structure includes a partial structure derived from at least one coloring agent selected from the group consisting of a benzimidazolone coloring agent, a benzimidazolinone coloring agent, a quinophthalone coloring agent, a phthalocyanine coloring agent, an anthraquinone coloring agent, a diketopyrrolopyrrole coloring agent, a quinacridone coloring agent, an azo coloring agent, an isoindolinone coloring agent, an isoindoline coloring agent, a dioxazine coloring agent, a perylene coloring agent, and a thioindigo coloring agent.

<7> The coloring photosensitive composition according to any one of <1> to <6>,

in which the pigment derivative A2 includes at least one partial structure selected from the group consisting of Formulae (Pg-1) to (Pg-10),

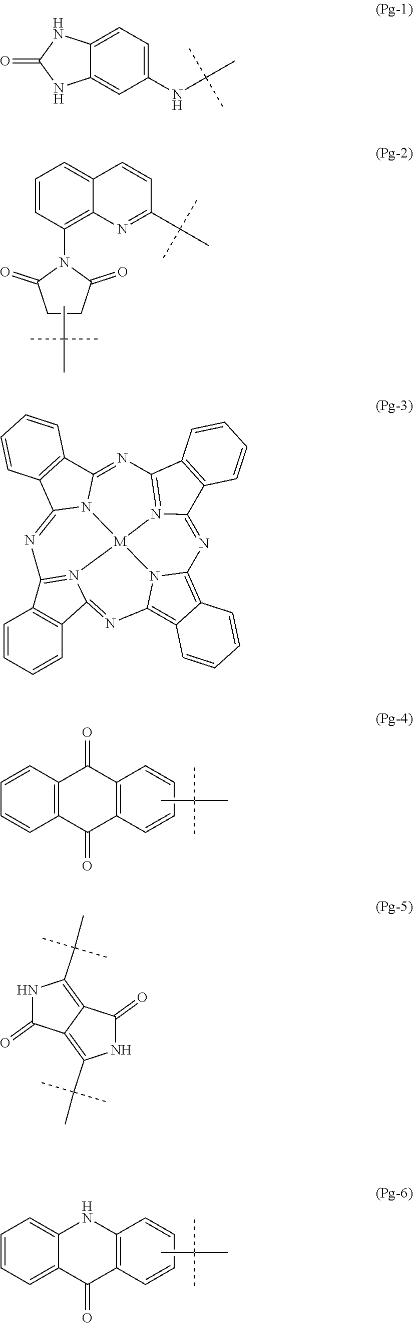

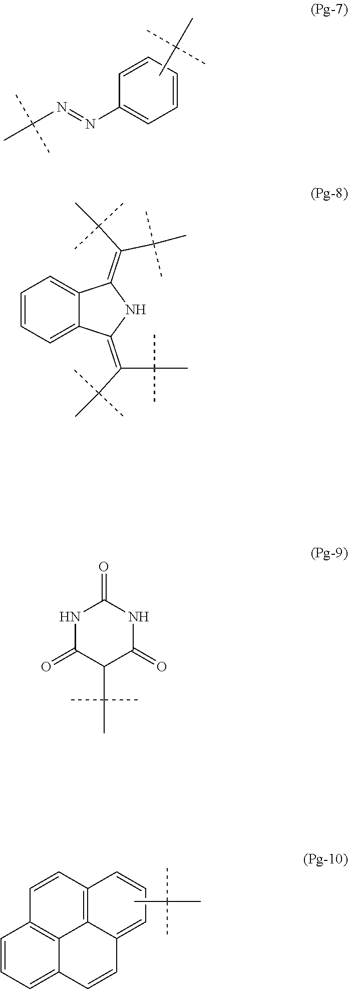

in Formulae (Pg-1) to (Pg-10), a broken line portion represents a bonding site with another structure.

<8> The coloring photosensitive composition according to any one of <1> to <7>,

in which the pigment includes halogenated phthalocyanine.

<9> The coloring photosensitive composition according to any one of <1> to <8>,

in which the photopolymerization initiator includes an oxime compound.

<10> The coloring photosensitive composition according to any one of <1> to <9>,

in which a molar light absorption coefficient of the photopolymerization initiator at a wavelength of 365 nm is 3,000 L·mol⁻¹ cm⁻¹ or more.

<11> The coloring photosensitive composition according to any one of <1> to <10>, further comprising:

a dispersant which is a resin.

<12> The coloring photosensitive composition according to any one of <1> to <11>, further comprising:

a resin having an acid group.

<13> A film formed from the coloring photosensitive composition according to any one of <1> to <12>.

<14> A color filter formed from the coloring photosensitive composition according to any one of <1> to <12>.

<15> A solid-state imaging element comprising:

the film according to <13>.

<16> An image display device comprising:

the film according to <13>.

According to the present invention, a coloring photosensitive composition capable of forming a film having excellent adhesiveness with a support is provided. In addition, a film formed from the above-described coloring photosensitive composition, a color filter, a solid-state imaging element, and an image display device are provided.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight (Mw) and a number-average molecular weight (Mn) are values in terms of polystyrene measured by gel permeation chromatography (GPC) method.

In the present specification, near-infrared rays denote light having a wavelength in a range of 700 to 2,500 nm.

In the present specification, a total solid content denotes the total mass of all the components of the composition excluding a solvent.

In the present specification, a pigment means a compound which is hardly dissolved in a solvent. For example, as the pigment, both of the solubility in 100 g of water at 23° C. and 100 g of propylene glycol monomethyl ether acetate at 23° C. is preferably 0.1 g or less and more preferably 0.01 g or less.

In the present specification, the term “step” denotes not only an individual step but also a step which is not clearly distinguishable from another step as long as an effect expected from the step can be achieved.

In the present specification, unless otherwise specified, a composition may include, as each component included in the composition, two or more kinds of compounds corresponding to the component. In addition, unless otherwise specified, a content of each component in the composition means the total content of all the compounds corresponding to the component.

In the present specification, unless otherwise specified, a wavy line portion or * (asterisk) in the structural formula represents a bonding site with another structure.

In addition, in the present specification, a combination of preferred aspects is a more preferred aspect.

(Coloring Photosensitive Composition)

A coloring photosensitive composition according to an embodiment of the present invention includes a pigment derivative A1 (hereinafter, also referred to as a “colorless pigment derivative A1”) in which a maximum value of a molar light absorption coefficient in a wavelength range of 400 to 700 nm is 3,000 L·mol⁻¹·cm⁻¹ or less, a pigment derivative A2 (hereinafter, also referred to as a “colored pigment derivative A2”) in which a maximum value of a molar light absorption coefficient in a wavelength range of 400 to 700 nm is more than 3,000 L·mol⁻¹·cm⁻¹, a pigment, a polymerizable compound, and a photopolymerization initiator.

According to the coloring photosensitive composition according to the embodiment of the present invention, a film excellent in both adhesiveness with a support and contrast of the obtained film is obtained. The reason why the above-described effect is obtained is presumed as follows.

The coloring photosensitive composition according to the embodiment of the present invention includes a photopolymerization initiator. Since the photopolymerization initiator is generally a highly photodegradable compound, it is presumed that, even in a case where the coloring photosensitive composition is stored or the like, decomposition reaction of the photopolymerization initiator proceeds and the performance of the photopolymerization initiator is easily deactivated.

In particular, in addition to a pigment, a pigment derivative may be used in the coloring photosensitive composition for the purpose of dispersing the pigment and the like. In a case where the coloring photosensitive composition includes, as the above-described pigment derivative, only a compound having absorption in a wavelength range of 400 to 700 nm, it is presumed that, since such a compound acts as a sensitizer, the performance of the photopolymerization initiator is more easily deactivated.

In the coloring photosensitive composition according to the embodiment of the present invention, the colorless pigment derivative A1 is used in combination with the above-described compound having absorption in a wavelength range of 400 to 700 nm. Therefore, it is presumed that the above-described sensitizing action of the compound is suppressed while blending a desired amount of the pigment derivative, and the performance deactivation of the photopolymerization initiator in the coloring photosensitive composition is suppressed. For the reason that the photosensitivity of the coloring photosensitive composition is improved by suppressing the above-described deactivation, it is considered that, in a case of curing the coloring photosensitive composition, the coloring photosensitive composition is easily cured to a deep portion of the film (support side of the film, and a film having excellent adhesiveness is formed.

In addition, in a case where only a colorless pigment derivative is used as the pigment derivative, the contrast of the obtained film may be low. It is considered that this is because the presence of the colorless pigment derivative between pigments in the film lowers the absorption of visible light in the film as compared with a case where a colored pigment derivative is included. The coloring photosensitive composition according to the embodiment of the present invention includes the colored pigment derivative A2 as a pigment derivative. Since the above-described colored pigment derivative A2 supplements the above-described absorption of visible light, it is considered that a film having excellent contrast is obtained.

That is, since the coloring photosensitive composition according to the embodiment of the present invention includes the colorless pigment derivative A1 and the colored pigment derivative A2, it is considered that the concentration of the pigment derivatives can be increased while maintaining both the above-described adhesiveness and the above-described contrast well. Therefore, it is considered that the coloring photosensitive composition is also likely to be excellent in dispersibility.

In addition, since the above-described decomposition of the photopolymerization initiator is suppressed in the coloring photosensitive composition according to the embodiment of the present invention, it is considered that the coloring photosensitive composition is also likely to be excellent in storage stability.

The coloring photosensitive composition according to the embodiment of the present invention can be used for a color filter, a near-infrared transmission filter, a near-infrared cut filter, a black matrix, a light-shielding film, a refractive index adjusting film, a microlens, and the like.

Examples of the color filter include a filter having a colored pixel which transmits light having a specific wavelength, and a filter having at least one colored pixel selected from the group consisting of a red pixel, a blue pixel, a green pixel, a yellow pixel, a cyan pixel, and a magenta pixel is preferable.

The color filter can be formed using a coloring photosensitive composition including a chromatic pigment.

Examples of the near-infrared cut filter include a filter having a maximum absorption wavelength in a wavelength range of 700 to 1,800 nm. As the near-infrared cut filter, a filter having a maximum absorption wavelength in a wavelength range of 700 to 1,300 nm is preferable, and a filter having a maximum absorption wavelength in a wavelength range of 700 to 1,000 nm is more preferable.

In addition, in the near-infrared cut filter, a transmittance of in the entire wavelength range of 400 to 650 nm is preferably 70% or more, more preferably 80% or more, and still more preferably 90% or more. In addition, the transmittance at at least one point in a wavelength range of 700 to 1,800 nm is preferably 20% or less.

In addition, in the near-infrared cut filter, absorbance Aₘₐₓ/absorbance A₅₅₀, which is a ratio of an absorbance Aₘₐₓ at a maximum absorption wavelength to an absorbance A₅₅₀ at a wavelength of 550 nm, is preferably 20 to 500, more preferably 50 to 500, still more preferably 70 to 450, and particularly preferably 100 to 400.

The near-infrared cut filter can be formed using a coloring photosensitive composition including a near-infrared absorbing pigment.

The near-infrared transmission filter is a filter which transmits at least a part of near-infrared rays. The near-infrared transmission filter may be a filter (transparent film) which transmits both visible light and near-infrared ray, or may be a filter which shields at least a part of visible light and transmits at least a part of near-infrared rays. Preferred examples of the near-infrared transmission filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1,100 to 1,300 nm is 70% or more (preferably 75% or more and more preferably 80% or more).

The near-infrared transmission filter is preferably a filter which satisfies any one of the following spectral characteristics (1) to (4).

(1): filter in which the maximum value of a transmittance in a wavelength range of 400 to 640 nm is 20% or less (preferably 15% or less and more preferably 10% or less) and the minimum value of a transmittance in a wavelength range of 800 to 1,300 nm is 70% or more (preferably 75% or more and more preferably 80% or more).

(2): filter in which the maximum value of a transmittance in a wavelength range of 400 to 750 nm is 20% or less (preferably 15% or less and more preferably 10% or less) and the minimum value of a transmittance in a wavelength range of 900 to 1,300 nm is 70% or more (preferably 75% or more and more preferably 80% or more).

(3): filter in which the maximum value of a transmittance in a wavelength range of 400 to 830 nm is 20% or less (preferably 15% or less and more preferably 10% or less) and the minimum value of a transmittance in a wavelength range of 1,000 to 1,300 nm is 70% or more (preferably 75% or more and more preferably 80% or more).

(4): filter in which the maximum value of a transmittance in a wavelength range of 400 to 950 nm is 20% or less (preferably 15% or less and more preferably 10% or less) and the minimum value of a transmittance in a wavelength range of 1,100 to 1,300 nm is 70% or more (preferably 75% or more and more preferably 80% or more).

The coloring photosensitive composition according to the embodiment of the present invention can be preferably used as a coloring photosensitive composition for a color filter. Specifically, the coloring photosensitive composition according to the embodiment of the present invention can be preferably used as a coloring photosensitive composition for forming a pixel of a color filter, and can be more preferably used as a coloring photosensitive composition for forming a pixel of a color filter used in a solid-state imaging element.

In addition, the coloring photosensitive composition according to the embodiment of the present invention can be preferably used as a curable composition for forming a green pixel of a color filter.

In addition, the coloring photosensitive composition according to the embodiment of the present invention can also be used as a composition for forming a color microlens. Examples of a method for manufacturing the color microlens include the method described in JP2018-010162A.

Hereinafter, the respective components used in the coloring photosensitive composition according to the embodiment of the present invention will be described.

<Colorless Pigment Derivative A1>

The coloring photosensitive composition according to the embodiment of the present invention includes a pigment derivative A1 (colorless pigment derivative A1) in which a maximum value of a molar light absorption coefficient in a wavelength range of 400 to 700 nm is 3,000 L·mol⁻¹·cm⁻¹ or less.

From the viewpoint of the adhesiveness of the obtained film with a support, the maximum value of the molar light absorption coefficient of the colorless pigment derivative A1 in a wavelength range of 400 to 700 nm is preferably 1,000 L·mol⁻¹·cm⁻¹ or less, more preferably 500 L·mol⁻¹·cm⁻¹ or less, and still more preferably 100 L·mol⁻¹·cm⁻¹ or less. The minimum value thereof is not particularly limited, but may be 0 L·mol⁻¹·cm⁻¹ or more.

In the present specification, the value of the molar light absorption coefficient of the colorless pigment derivative A1 is a value measured by a method described in Examples described later.

[Compound (1)]

The colorless pigment derivative A1 is preferably a compound (also referred to as a “compound (1)”) represented by Formula (1).

A¹-L¹-Z¹ (1)

In Formula (1), A¹ represents a group including an aromatic ring,

L¹ represents a single bond or a divalent linking group, and

Z¹ represents a group represented by Formula (Z1).

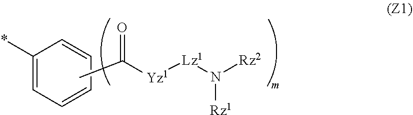

In Formula (Z1), * represents a bonding hand,

Yz¹ represents —N(Ry¹)— or —O—, where Ry′ represents a hydrogen atom or a hydrocarbon group,

Lz¹ represents a single bond or a divalent linking group,

Rz¹ and Rz² each independently represent a hydrogen atom or a hydrocarbon group, where Rz¹ and Rz² may be bonded to each other through a divalent group to form a ring, and m represents an integer of 1 to 5.

—A¹—

In Formula (1), A¹ represents a group including an aromatic ring. The aromatic ring may be an aromatic hydrocarbon ring or an aromatic heterocyclic ring. In addition, the aromatic ring may be a monocyclic ring or a fused ring.

Examples of the group represented by A¹ include a group including an aromatic ring selected from the group consisting of a benzene ring, a naphthalene ring, a fluorene ring, a perylene ring, an imidazole ring, a pyrazole ring, an oxazole ring, a thiazole ring, an imidazoline ring, a pyridine ring, a triazole ring a pyrazine ring, a pyrimidine ring, a pyridazine ring, a quinoline ring, an isoquinoline ring, a quinoxaline ring, a quinazoline ring, a benzimidazole ring, a benzopyrazole ring, a benzoxazole ring, a benzothiazole ring, a benzotriazole ring, an indole ring, an isoindole ring, a triazine ring, a pyrrole ring, a carbazole ring, a benzimidazolinone ring, a phthalimide ring, a phthalocyanine ring, an anthraquinone ring, a diketopyrrolopyrrole ring, an isoindolinone ring, an isoindoline ring, and a quinacridone ring; and a group including a fused ring which includes these aromatic rings. The above-described fused ring may be an aromatic ring or a non-aromatic ring, but is preferably an aromatic ring.

In addition, in A¹, the atom at the bonding position with L¹ is preferably an atom which is a ring member included in the aromatic ring or fused ring included in A¹, and is more preferably a carbon atom which is a ring member included in the aromatic ring or fused ring included in A¹.

In addition, the group represented by A¹ may be a group having only one aromatic ring or fused ring described above, but for the reason that, as the number of aromatic rings increases, pigment adsorbability is improved and storage stability of the composition is easily improved by π-π interaction, it is preferable to have two or more of these rings.

In a case where A¹ includes two or more rings, it is preferable that these rings are bonded by a single bond, —O—, an amide bond, —S—, —C(═O)—, an ester bond, a urea bond, an imide bond, or the like. R^{a} represents a hydrogen atom or a hydrocarbon group, and a hydrogen atom, an alkyl group, an alkenyl group, an alkynyl group, or an aryl group is preferable, a hydrogen atom or an alkyl group is more preferable, and a hydrogen atom is still more preferable.

The hydrocarbon group represented by R^{a} preferably has 1 to 30 carbon atoms, more preferably has 1 to 20 carbon atoms, and still more preferably has 1 to 12 carbon atoms. The hydrocarbon group represented by R^{a} may further have a substituent. Examples of the substituent include the substituent T described later.

The alkyl group represented by R^{a} preferably has 1 to 20 carbon atoms, more preferably has 1 to 15 carbon atoms, and still more preferably has 1 to 8 carbon atoms. The alkyl group may be linear, branched, or cyclic, and may have a structure in which two or more thereof are combined, but is preferably linear or branched and more preferably linear. The alkyl group represented by R^{a} may further have a substituent. Examples of the substituent include the substituent T described later.

The alkenyl group represented by R^{a} preferably has 2 to 20 carbon atoms, more preferably has 2 to 12 carbon atoms, and still more preferably has 2 to 8 carbon atoms. The alkenyl group may be linear, branched, or cyclic, and may have a structure in which two or more thereof are combined, but is preferably linear or branched and more preferably linear. The alkenyl group represented by R^{a} may further have a substituent. Examples of the substituent include the substituent T described later.

The alkynyl group represented by R^{a} preferably has 2 to 40 carbon atoms, more preferably has 2 to 30 carbon atoms, and still more preferably has 2 to 25 carbon atoms. The alkynyl group may be linear, branched, or cyclic, and may have a structure in which two or more thereof are combined, but is preferably linear or branched and more preferably linear. The alkynyl group represented by R^{a} may further have a substituent. Examples of the substituent include the substituent T described later.

The aryl group represented by R^{a} preferably has 6 to 30 carbon atoms, more preferably has 6 to 20 carbon atoms, and still more preferably has 6 to 12 carbon atoms. The aryl group represented by R^{a} may further have a substituent. Examples of the substituent include the substituent T described later.

The group represented by A¹ may further have a substituent. Examples of the substituent include the substituent T described later.

From the viewpoint of improving the dispersibility of the pigment in the coloring photosensitive composition, or from the viewpoint of improving the storage stability of the coloring photosensitive composition, the group represented by A¹ is preferably a group having a structure which easily interacts with the pigment included in the coloring photosensitive composition according to the embodiment of the present invention or a structure similar to the pigment. In addition, from the reason that the effects of the present invention are more easily obtained, the group represented by A¹ is preferably a group including an aromatic heterocyclic ring, more preferably a group including a nitrogen-containing aromatic heterocyclic ring, still more preferably a group including a triazine ring, and particularly preferably a group represented by Formula (A1).

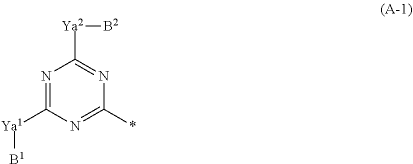

In Formula (A1), * represents a bonding hand,

Ya¹ and Ya² each independently represent —N(Ra¹)— or —O—, where Ra¹ represents a hydrogen atom or a hydrocarbon group, and

B″ and B² each independently represent a hydrogen atom or a substituent.

In Formula (A1), Ya¹ and Ya² each independently represent —N(Ra¹)— or —O—, and from the reason that the effects of the present invention are more easily obtained remarkably, —N(Ra¹)— is more preferable.

Ra¹ represents a hydrogen atom or a hydrocarbon group, and a preferred aspect of Ra¹ is the same as the preferred aspect of R^{a} described above.

In Formula (A1), B¹ and B² each independently represent a hydrogen atom or a substituent. Examples of the substituent include the substituent T described later, and an alkyl group, an aryl group, or a heterocyclic group is preferable, an aryl group or a heterocyclic group is more preferable, and an aryl group is still more preferable from the reason that pigment adsorbability is enhanced and storage stability of the composition is easily improved.

The alkyl group, aryl group, and heterocyclic group represented by B¹ and B² may further have a substituent. Examples of the further substituent include an alkyl group (preferably an alkyl group having 1 to 30 carbon atoms), a fluoroalkyl group (preferably a fluoroalkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably an acyl group having 1 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably a heteroarylthio group having 1 to 30 carbon atoms), an alkylsulfonyl group (preferably an alkylsulfonyl group having 1 to 30 carbon atoms), an arylsulfonyl group (preferably an arylsulfonyl group having 6 to 30 carbon atoms), a heteroarylsulfonyl group (preferably a heteroarylsulfonyl group having 1 to 30 carbon atoms), an alkylsulfinyl group (preferably an alkylsulfinyl group having 1 to 30 carbon atoms), an arylsulfinyl group (preferably an arylsulfinyl group having 6 to 30 carbon atoms), a heteroarylsulfinyl group (preferably a heteroarylsulfinyl group having 1 to 30 carbon atoms), a ureido group (preferably a ureido group having 1 to 30 carbon atoms), a phosphoric acid amide group (preferably a phosphoric acid amide group having 1 to 30 carbon atoms), a hydroxy group, a carboxy group, a sulfo group, a phosphoric acid group, a mercapto group, a halogen atom, a cyano group, an alkylsulfino group, an arylsulfino group, a hydrazino group, and an imino group. Among these, an alkyl group, a fluoroalkyl group, an alkoxy group, an amino group, a halogen atom, an alkenyl group, a hydroxy group, an alkoxycarbonyl group, an acyloxy group, an acylamino group, or a nitro group is preferable.

It is also preferable that the alkyl group, aryl group, and heterocyclic group represented by B¹ and B² do not have the above-described further substituent.

<<Substituent T>>

Examples of a substituent T include a halogen atom, a cyano group, a nitro group, an alkyl group, an alkenyl group, an alkynyl group, an aryl group, a heterocyclic group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Rt¹ and Rt² each independently represent a hydrogen atom, an alkyl group, an alkenyl group, an alkynyl group, an aryl group, or a heteroaryl group. Rt¹ and Rt² may be bonded to each other to form a ring.

Examples of the halogen atom include a fluorine atom, a chlorine atom, a bromine atom, and an iodine atom.

The alkyl group preferably has 1 to 30 carbon atoms, more preferably has 1 to 15 carbon atoms, and still more preferably has 1 to 8 carbon atoms. The alkyl group may be linear, branched, or cyclic, and is preferably linear or branched and more preferably linear.

The alkenyl group preferably has 2 to 30 carbon atoms, more preferably has 2 to 12 carbon atoms, and particularly preferably has 2 to 8 carbon atoms. The alkenyl group may be linear, branched, or cyclic, and is preferably linear or branched and more preferably linear.

The alkynyl group preferably has 2 to 30 carbon atoms and more preferably has 2 to 25 carbon atoms. The alkynyl group may be linear, branched, or cyclic, and is preferably linear or branched and more preferably linear.

The aryl group preferably has 6 to 30 carbon atoms, more preferably has 6 to 20 carbon atoms, and still more preferably has 6 to 12 carbon atoms.

The heterocyclic group may be monocyclic or a fused ring. The heterocyclic group is preferably monocyclic or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The alkyl group, the alkenyl group, the alkynyl group, the aryl group, and the heterocyclic group may have a substituent or may be unsubstituted. Examples of the substituent include the substituent described in the substituent T.

Specific examples of A¹ include groups having the following structures. In the following structural formulae, Me represents a methyl group and a wavy line portion represents a bonding site with

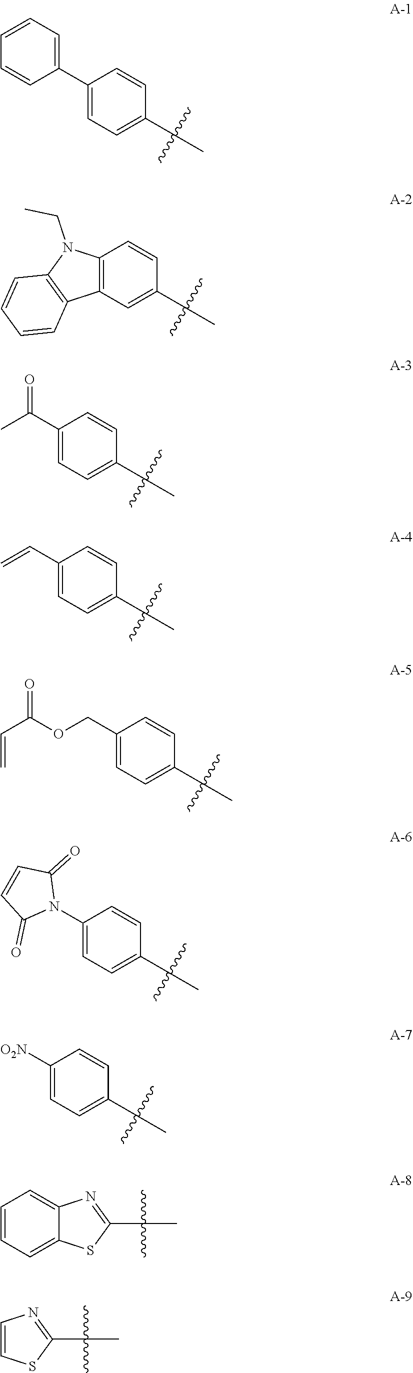

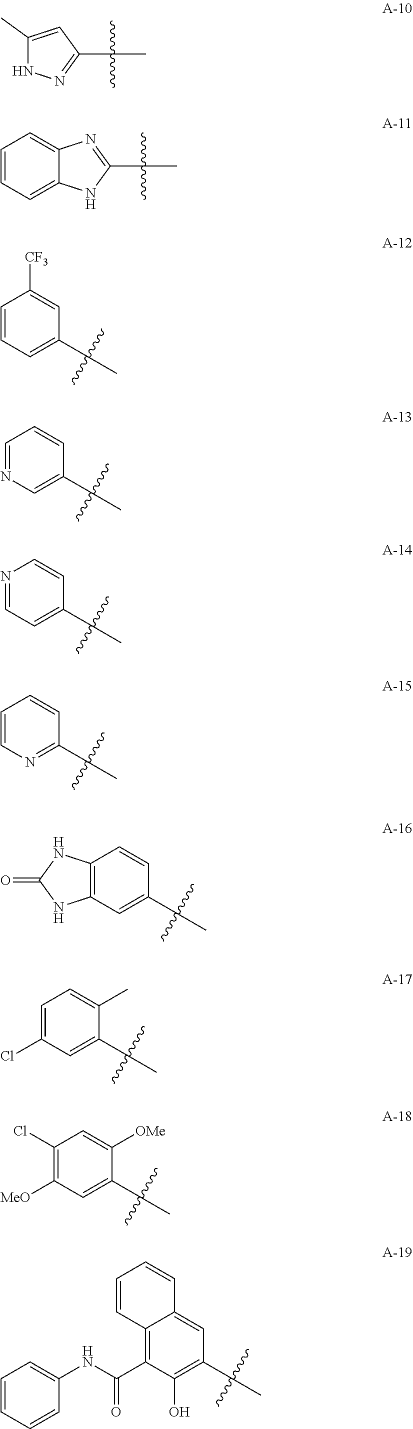

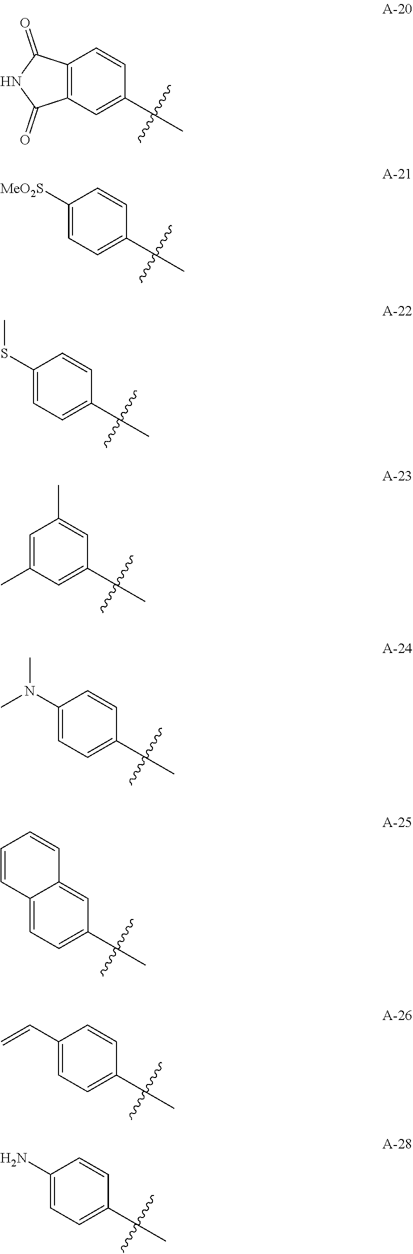

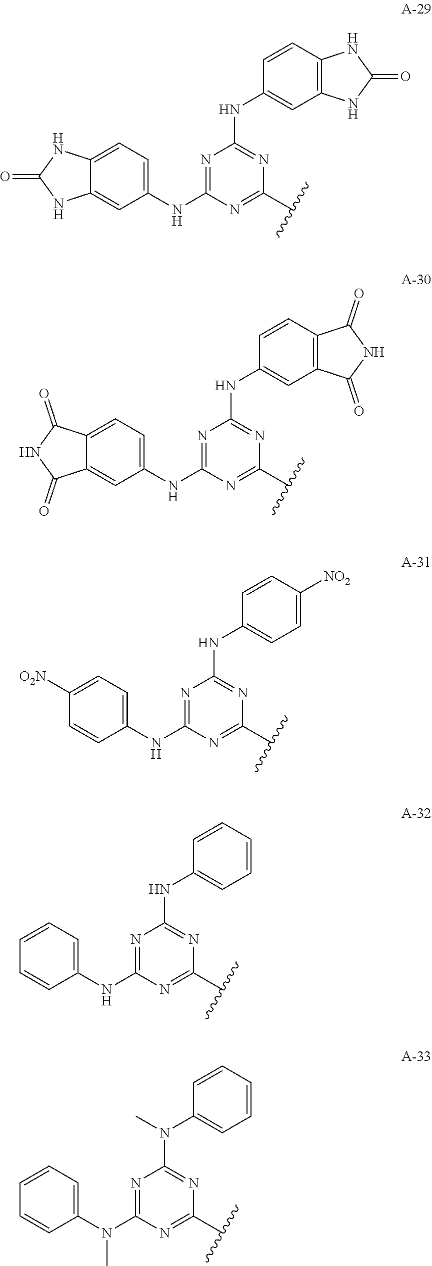

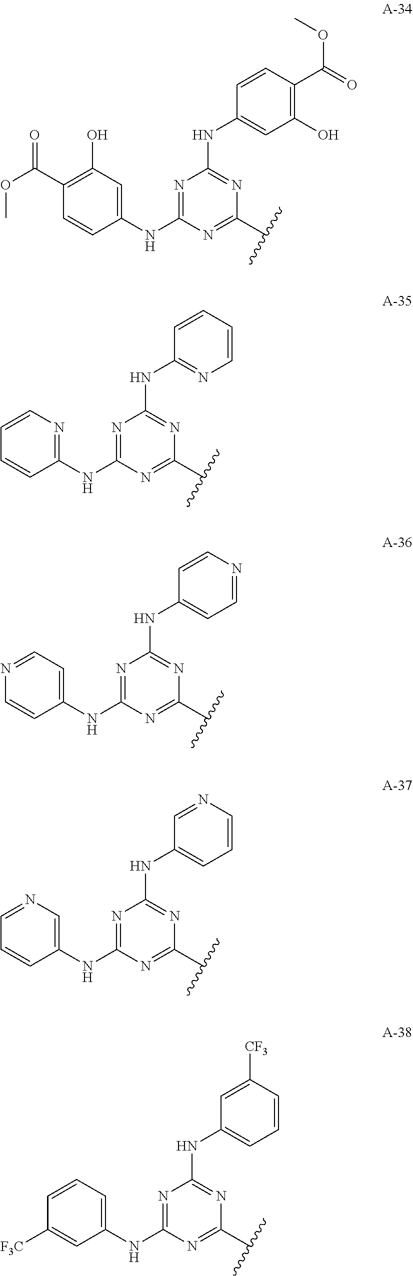

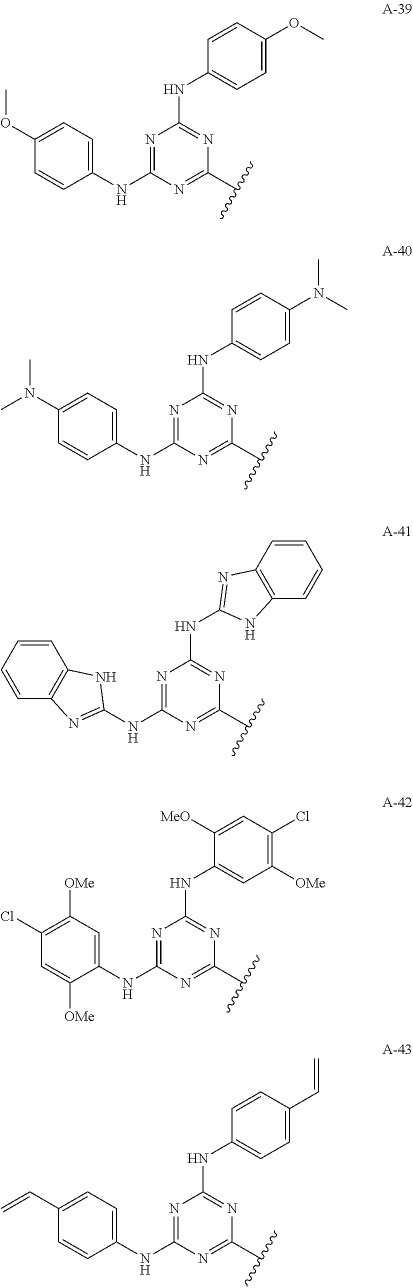

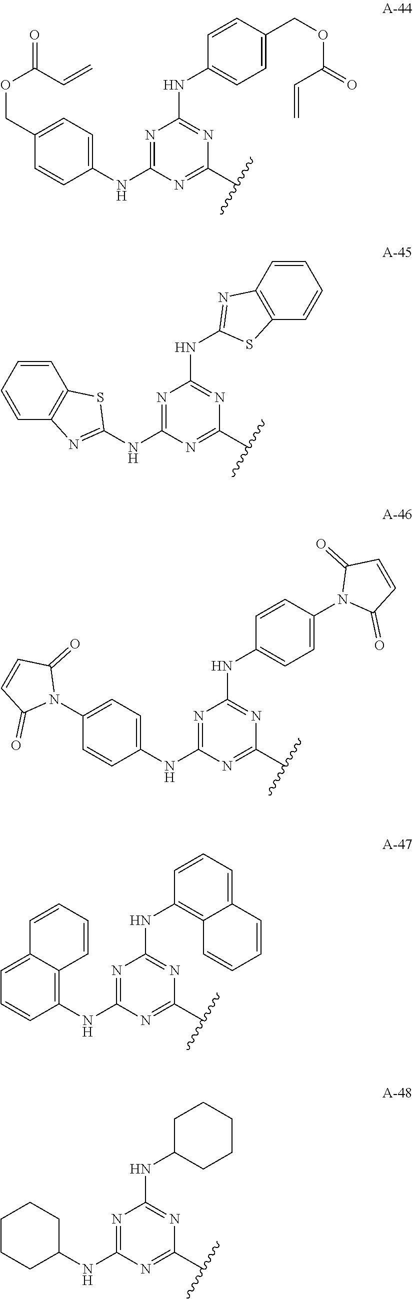

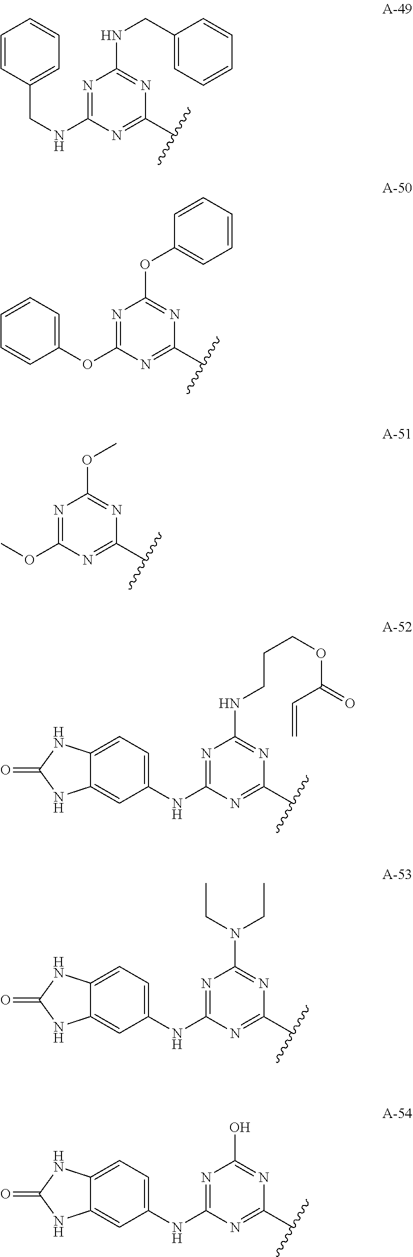

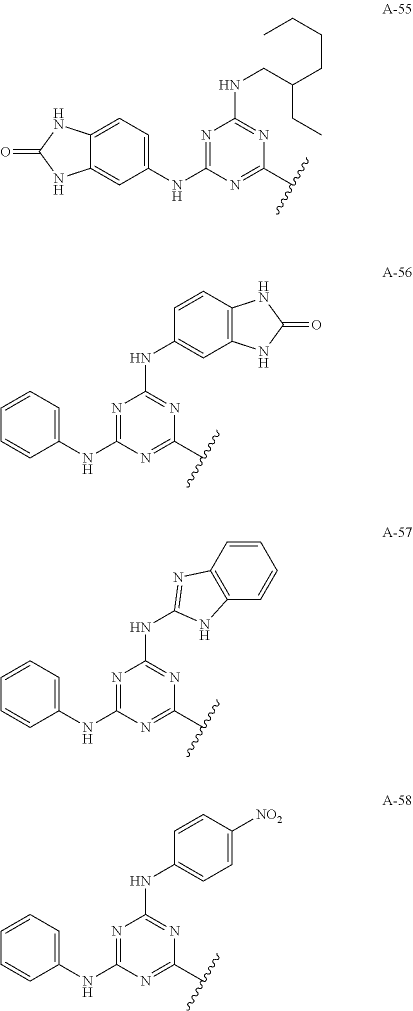

In Formula (1), L¹ represents a single bond or a divalent linking group, and a divalent linking group is preferable. Examples of the divalent linking group represented by L¹ include an alkylene group, an arylene group, a heterocyclic group, —O—, —N(R^{L1})—, —NHCO—, —CONH—, —OCO—, —COO—, —CO—, —SO₂NH—, —SO₂—, and a group formed by a combination of two or more of these groups. The alkylene group preferably has 1 to 30 carbon atoms, more preferably has 1 to 15 carbon atoms, still more preferably has 1 to 8 carbon atoms, and particularly preferably has 1 to 5 carbon atoms. The alkylene group may be linear, branched, or cyclic, and may have a structure in which two or more thereof are combined, but is preferably linear or branched and particularly preferably linear. The arylene group preferably has 6 to 30 carbon atoms and more preferably has 6 to 15 carbon atoms. The arylene group is preferably a phenylene group.

R^{L1} represents a hydrogen atom or a hydrocarbon group, and a preferred aspect of R^{L1} is the same as the preferred aspect of R^{a} described above.

The divalent linking group represented by L¹ is preferably a group represented by Formula (L1).

*^{A}-L^{1A}-L^{1B}-L^{1C}-*^{Z} (L1)

In the formula, L^{1A} and L^{1C} each independently represent —O—, —NHCO—, —CONH—, —OCO—, —COO—, —CO—, —SO₂NH—, or —SO₂—, L^{1B} represents a single bond or a divalent linking group, *^{A} represents a bonding site with A¹ in Formula (1), and *^{Z} represents a bonding site with Z¹ in Formula (1).

Examples of the divalent linking group represented by L^{1B} include an alkylene group, an arylene group, a group in which an alkylene group and an arylene group are bonded to each other through a single bond, —O—, —NHCO—, —CONH—, —OCO—, —COO—, —CO—, —SO₂NH—, —SO₂—, or a group selected from the group consisting of combinations of two or more of these groups, and a group in which alkylene groups or arylene groups are bonded to each other through —O—, —NHCO—, —CONH—, —OCO—, —COO—, —CO—, —SO₂NH—, —SO₂—, or a group selected from the group consisting of combinations of two or more of these groups.

In a case where A¹ in the compound represented by Formula (1) is the group represented by Formula (A1), it is preferable that L^{1A} is —N(R^{L1})—, and it is more preferable that L^{1A} is —N(R^{L1})— and the bonding site with L^{1A} in L^{1B} is an arylene group.

In addition, L^{1C} is preferably —N(R^{L1})—, —NHCO—, or —CONH—.

Specific examples of L¹ include groups having the following structures. In the following structures, a wavy line portion on the left side of the paper surface is the bonding site with A¹, and a wavy line portion on the right side of the paper surface is the bonding site with Z¹.

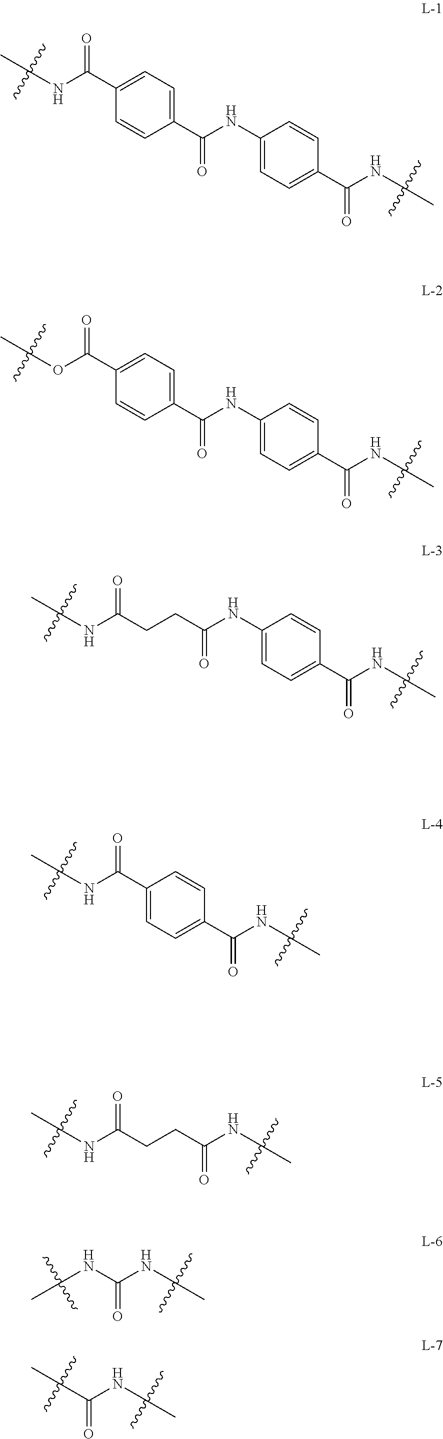

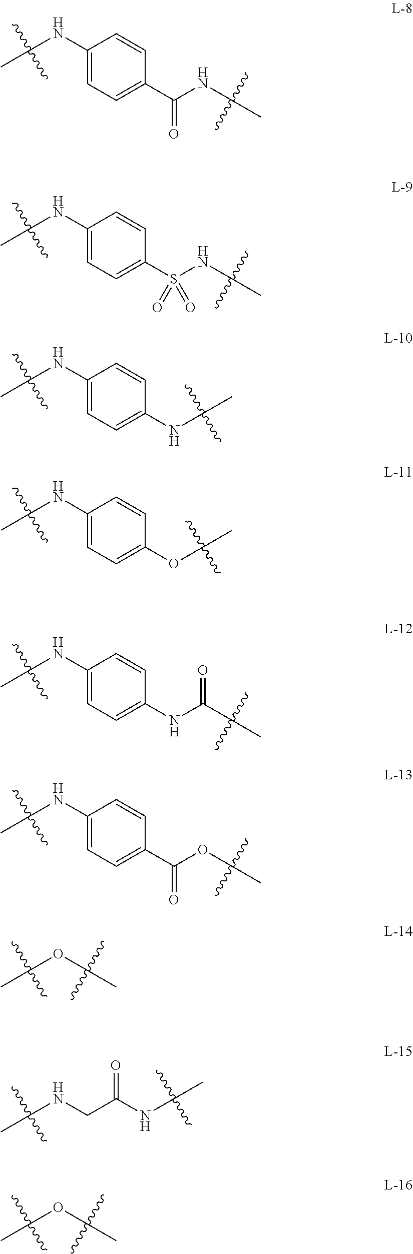

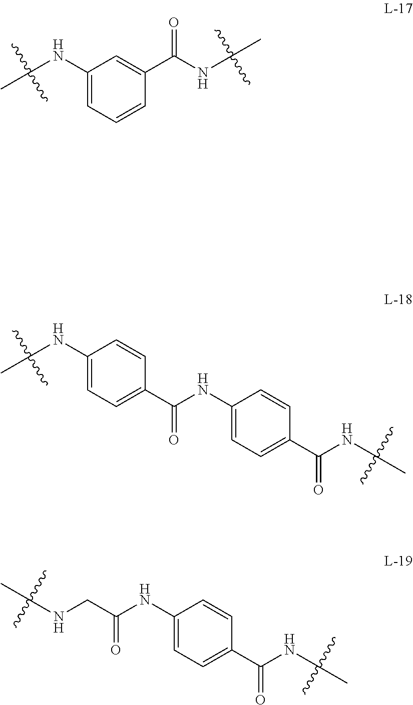 [SMILES: *NC(=O)c1cccc(N*)c1 ; *NC(=O)c1ccc(NC(=O)c2ccc(N*)cc2)cc1 ; *NCC(=O)Nc1ccc(C(=O)N*)cc1]

—Z¹—

<<Formula Z^{1>>}

In Formula (1), Z¹ represents a group represented by Formula (Z1).

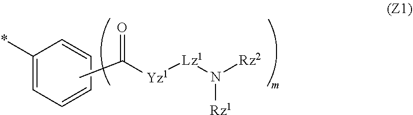

In the formula, * represents a bonding hand,

Yz¹ represents —N(Ry¹)— or —O—, where Ry′ represents a hydrogen atom or a hydrocarbon group,

Lz¹ represents a single bond or a divalent linking group,

Rz¹ and Rz² each independently represent a hydrogen atom or a hydrocarbon group, where Rz¹ and Rz² may be bonded to each other through a divalent group to form a ring, and

m represents an integer of 1 to 5.

In Formula (Z1), Yz¹ represents —N(Ry¹)— or —O—, and from the reason that durability is easily improved, —N(Ry¹)— is preferable.

Ry¹ represents a hydrogen atom or a hydrocarbon group, and a preferred aspect of Ry¹ is the same as the preferred aspect of R^{a} described above.

In Formula (Z1), examples of the divalent linking group represented by Lz¹ include an alkylene group, an arylene group, a heterocyclic group, —O—, —NHCO—, —CONH—, —OCO—, —COO—, —CO—, —SO₂NH—, —SO₂—, and a group formed by a combination of two or more of these groups, and an alkylene group is preferable. The alkylene group preferably has 1 to 30 carbon atoms, more preferably has 1 to 15 carbon atoms, still more preferably has 1 to 8 carbon atoms, and particularly preferably has 1 to 5 carbon atoms. The alkylene group may be linear, branched, or cyclic, and is preferably linear or branched and particularly preferably linear.

In Formula (Z1), Rz¹ and Rz² each independently represent a hydrogen atom or a hydrocarbon group, and a hydrogen atom, an alkyl group, an alkenyl group, an alkynyl group, or an aryl group is preferable, an alkyl group or an aryl group more is preferable, and an alkyl group is still more preferable. The hydrocarbon group preferably has 1 to 30 carbon atoms, more preferably has 1 to 20 carbon atoms, and still more preferably has 1 to 12 carbon atoms. The alkyl group preferably has 1 to 10 carbon atoms, more preferably has 1 to 5 carbon atoms, still more preferably has 1 to 3 carbon atoms, and particularly preferably has 1 or 2 carbon atoms. The alkyl group may be linear, branched, or cyclic, and is preferably linear or branched and more preferably linear. The alkenyl group preferably has 2 to 10 carbon atoms, more preferably has 2 to 8 carbon atoms, and particularly preferably has 2 to 5 carbon atoms. The alkenyl group may be linear, branched, or cyclic, and is preferably linear or branched and more preferably linear. The alkynyl group preferably has 2 to 10 carbon atoms, more preferably has 2 to 8 carbon atoms, and particularly preferably has 2 to 5 carbon atoms. The alkynyl group may be linear, branched, or cyclic, and is preferably linear or branched and more preferably linear. The aryl group preferably has 6 to 30 carbon atoms, more preferably has 6 to 20 carbon atoms, and still more preferably has 6 to 12 carbon atoms.

In a case where Rz¹ is a hydrocarbon group, the hydrocarbon group may have a substituent, and examples of the substituent include the above-described substituent T.

In a case where Rz² is a hydrocarbon group, the hydrocarbon group may have a substituent, and examples of the substituent include the above-described substituent T.

In a case where m is 2 or more, two or more of Rz¹'s may be the same as or different from each other.

In a case where m is 2 or more, two or more of Rz²'s may be the same as or different from each other.

In Formula (Z1), Rz¹ and Rz² may be bonded to each other through a divalent group to form a ring. It is preferable that the ring to be formed is a 5-membered or 6-membered ring. Examples of the divalent group include —CH₂—, —O—, and —SO₂—. Specific examples of the ring formed by bonding Rz¹ and Rz² to each other through the divalent group include the following.

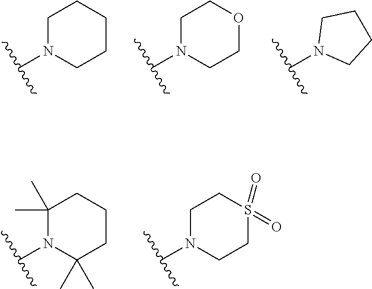

In Formula (Z1), m represents an integer of 1 to 5, and is preferably 1 to 4, more preferably 1 to 3, still more preferably 2 or 3, and particularly preferably 2.

<<Formula Z2>>

In Formula (1), Z¹ is preferably a group represented by Formula (Z2).

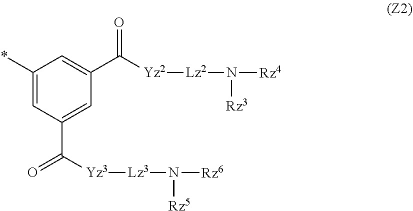

In the formula, * represents a bonding hand,

Yz² and Yz³ each independently represent —N(Ry²)— or —O—, where Ry² represents a hydrogen atom or a hydrocarbon group,

Lz² and Lz³ each independently represent a divalent linking group, and

Rz³ to Rz⁶ each independently represent a hydrogen atom or a hydrocarbon group, where Rz³ and Rz⁴, and Rz⁵ and Rz⁶ may be respectively bonded to each other through a divalent group to form a ring.

Yz² and Yz³ in Formula (Z2) have the same meanings as Yz¹ in Formula (Z1), and the preferred ranges are also the same. Ry² represents a hydrogen atom or a hydrocarbon group, and a preferred aspect of Ry² is the same as the preferred aspect of R^{a} described above.

Lz² and Lz³ in Formula (Z2) have the same meanings as Lz¹ in Formula (Z1), and the preferred ranges are also the same. Rz³ to Rz⁶ in Formula (Z2) have the same meanings as Rz¹ and Rz² in Formula (Z1), and the preferred ranges are also the same.

Specific examples of Z¹ include groups having the following structures. In the following structural formulae, Ph represents a phenyl group. The parenthesized subscript in the structural formulae represents the number of repetitions.

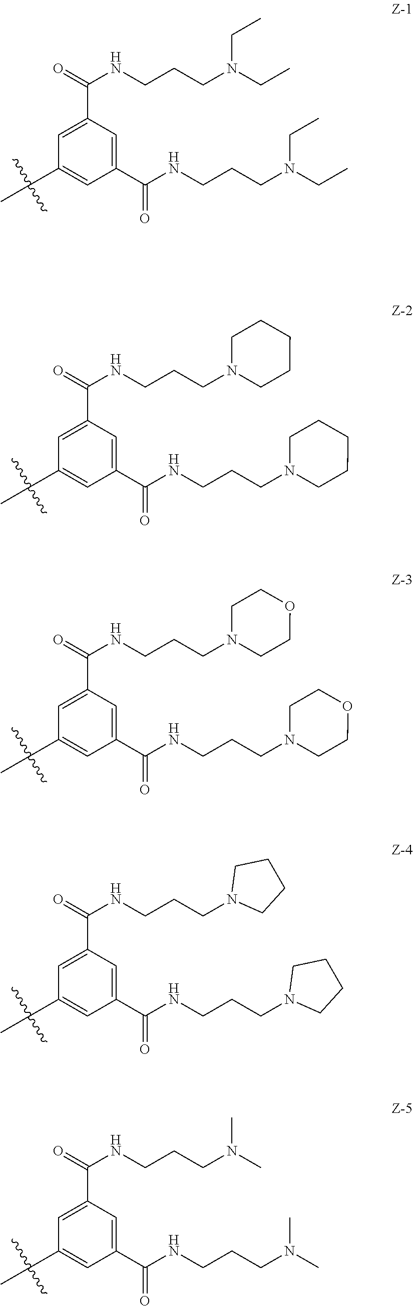 [SMILES: *c1cc(C(=O)NCCCN(CC)CC)cc(C(=O)NCCCN(CC)CC)c1 ; *c1cc(C(=O)NCCCN2CCCCC2)cc(C(=O)NCCCN2CCCCC2)c1 ; *c1cc(C(=O)NCCCN2CCOCC2)cc(C(=O)NCCCN2CCOCC2)c1 ; *c1cc(C(=O)NCCCN2CCCC2)cc(C(=O)NCCCN2CCCC2)c1 ; *c1cc(C(=O)NCCCN(C)C)cc(C(=O)NCCCN(C)C)c1]

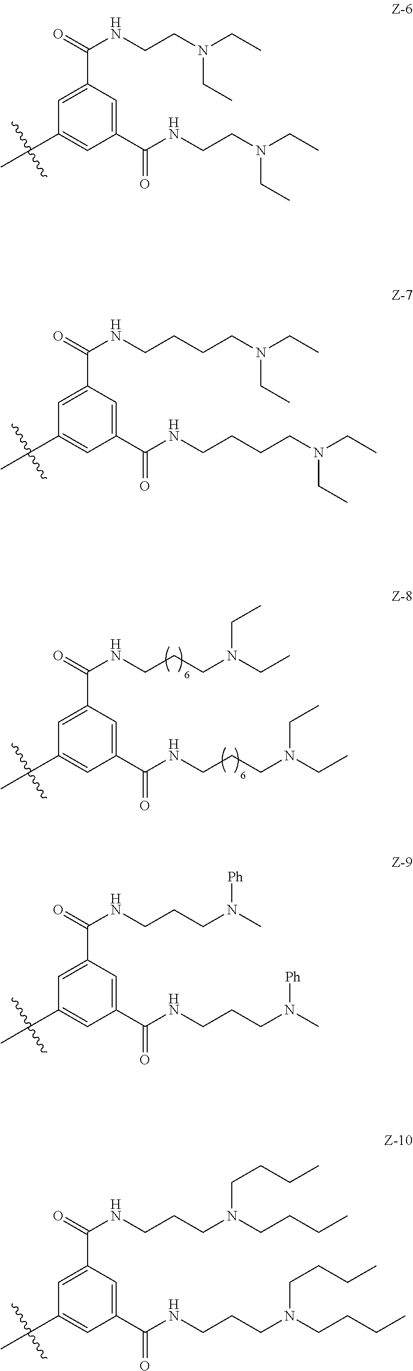

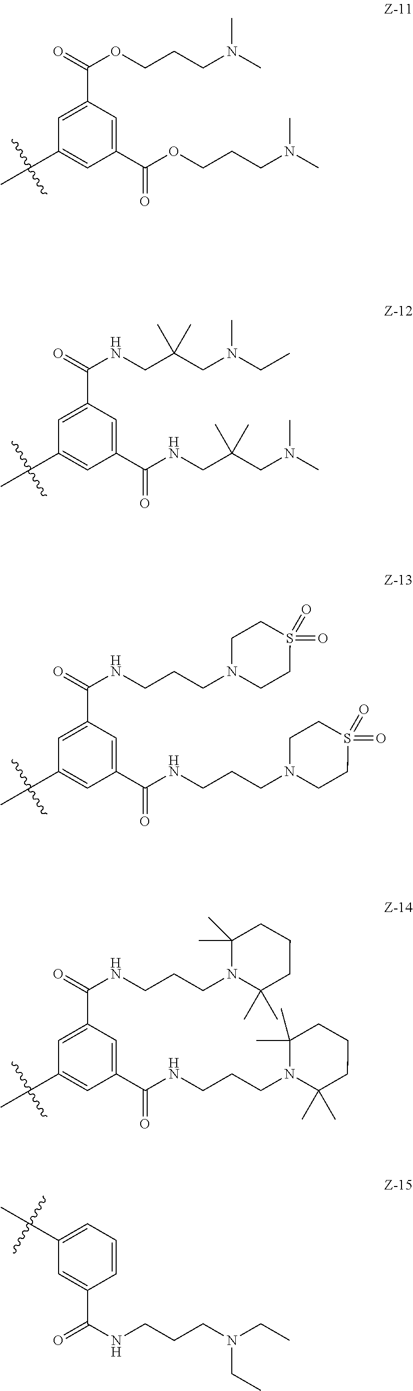 [SMILES: *c1cc(C(=O)OCCCN(C)C)cc(C(=O)OCCCN(C)C)c1 ; *c1cc(C(=O)NCC(C)(C)CN(C)C)cc(C(=O)NCC(C)(C)CN(C)CC)c1 ; *c1cc(C(=O)NCCCN2CCS(=O)(=O)CC2)cc(C(=O)NCCCN2CCS(=O)(=O)CC2)c1 ; *c1cc(C(=O)NCCCN2C(C)(C)CCCC2(C)C)cc(C(=O)NCCCN2C(C)(C)CCCC2(C)C)c1 ; *c1cccc(C(=O)NCCCN(CC)CC)c1]

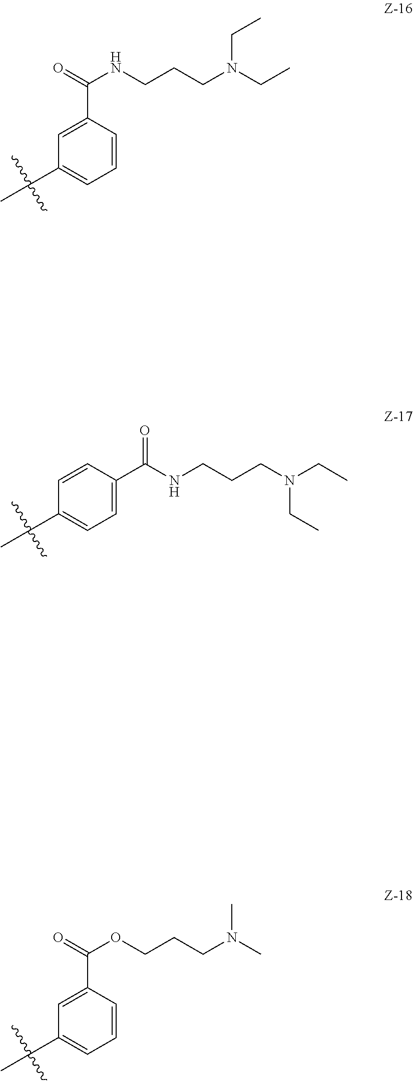 [SMILES: *c1cccc(C(=O)NCCCN(CC)CC)c1 ; *c1ccc(C(=O)NCCCN(CC)CC)cc1 ; *c1cccc(C(=O)OCCCN(C)C)c1]

The compound (1) used in the coloring photosensitive composition according to the embodiment of the present invention, that is, the compound which is the colorless pigment derivative A1 and is represented by Formula (1) is preferably a compound represented by Formula (2). By using such a compound, the effects of the present invention are more remarkably obtained.

A¹-X¹-L²-X²—Z¹ (2)

In Formula (2), A¹ represents a group including an aromatic ring,

X¹ and X² each independently represent a single bond, —O—, —N(R¹)—, —NHCO—, —CONH—, —OCO—, —COO—, —CO—, —SO₂NH—, or —SO₂—, where R¹ represents a hydrogen atom or a hydrocarbon group,

L² represents a single bond or a divalent linking group, and

Z¹ represents the group represented by Formula (Z1).

A¹ and Z¹ in Formula (2) have the same meanings as A¹ and Z¹ in Formula (1), and the preferred ranges are also the same.

X¹ and X² in Formula (2) each independently represent a single bond, —O—, —N(R¹)—, —NHCO—, —CONH—, —OCO—, —COO—, —CO—, —SO₂NH—, or —SO₂—, —O—, —N(R¹)—, —NHCO—, —CONH—, —OCO—, —COO—, —CO—, —SO₂NH—, or —SO₂— is preferable. R¹ represents a hydrogen atom or a hydrocarbon group, and a preferred aspect of R¹ is the same as the preferred aspect of R^{a} described above.

L² in Formula (2) represents a single bond or a divalent linking group. Examples of the divalent linking group represented by L² include an alkylene group, an arylene group, a group in which an alkylene group and an arylene group are bonded to each other through a single bond, —O—, —N(R²)—, —NHCO—, —CONH—, —OCO—, —COO—, —CO—, —SO₂NH—, —SO₂—, or a group selected from the group consisting of combinations of two or more of these groups, and a group in which alkylene groups or arylene groups are bonded to each other through —O—, —N(R²)—, —NHCO—, —CONH—, —OCO—, —COO—, —CO—, —SO₂NH—, —SO₂—, or a group selected from the group consisting of combinations of two or more of these groups. R² represents a hydrogen atom or a hydrocarbon group, and a preferred aspect of R² is the same as the preferred aspect of R^{a} described above.

Specific examples of the compound (1), which is a preferred aspect of the colorless pigment derivative used in the present invention, include the following. In the table, the description in “No.” column indicates the compound number, and the symbols in “L¹”, and “Z¹” columns indicate the structures exemplified in the specific examples of A¹, the specific examples of L¹, and the specific examples of Z¹ in Formula (1), respectively.

TABLE 1

| No. | A¹ | L¹ | Z¹ |
|---|---|---|---|
| (A1)-1 | A-1 | L-1 | Z-1 |
| (A1)-2 | A-2 | L-1 | Z-1 |
| (A1)-3 | A-3 | L-1 | Z-1 |
| (A1)-4 | A-4 | L-1 | Z-1 |
| (A1)-5 | A-5 | L-1 | Z-1 |
| (A1)-6 | A-6 | L-1 | Z-1 |
| (A1)-7 | A-7 | L-1 | Z-1 |
| (A1)-8 | A-8 | L-1 | Z-1 |
| (A1)-9 | A-9 | L-1 | Z-1 |
| (A1)-10 | A-10 | L-1 | Z-1 |
| (A1)-11 | A-11 | L-1 | Z-1 |
| (A1)-12 | A-12 | L-1 | Z-1 |
| (A1)-13 | A-13 | L-1 | Z-1 |
| (A1)-14 | A-14 | L-1 | Z-1 |
| (A1)-15 | A-15 | L-1 | Z-1 |
| (A1)-16 | A-16 | L-1 | Z-1 |
| (A1)-17 | A-17 | L-1 | Z-1 |
| (A1)-18 | A-18 | L-1 | Z-1 |
| (A1)-19 | A-19 | L-1 | Z-1 |
| (A1)-20 | A-20 | L-1 | Z-1 |
| (A1)-21 | A-21 | L-1 | Z-1 |
| (A1)-22 | A-22 | L-1 | Z-1 |
| (A1)-23 | A-23 | L-1 | Z-1 |
| (A1)-24 | A-24 | L-1 | Z-1 |
| (A1)-25 | A-25 | L-2 | Z-1 |
| (A1)-26 | A-26 | L-2 | Z-1 |
| (A1)-27 | A-16 | L-3 | Z-1 |
| (A1)-28 | A-16 | L-4 | Z-1 |
| (A1)-29 | A-16 | L-5 | Z-1 |
| (A1)-30 | A-16 | L-6 | Z-1 |
| (A1)-31 | A-7 | L-7 | Z-1 |
| (A1)-32 | A-28 | L-7 | Z-1 |
| (A1)-33 | A-29 | L-8 | Z-1 |
| (A1)-34 | A-30 | L-8 | Z-1 |
| (A1)-35 | A-31 | L-8 | Z-1 |
| (A1)-36 | A-32 | L-8 | Z-1 |
| (A1)-37 | A-33 | L-8 | Z-1 |
| (A1)-38 | A-34 | L-8 | Z-1 |
| (A1)-39 | A-35 | L-8 | Z-1 |
| (A1)-40 | A-36 | L-8 | Z-1 |
| (A1)-41 | A-37 | L-8 | Z-1 |
| (A1)-42 | A-38 | L-8 | Z-1 |
| (A1)-43 | A-39 | L-8 | Z-1 |
| (A1)-44 | A-40 | L-8 | Z-1 |
| (A1)-45 | A-41 | L-8 | Z-1 |
| (A1)-46 | A-42 | L-8 | Z-1 |
| (A1)-47 | A-43 | L-8 | Z-1 |
| (A1)-48 | A-44 | L-8 | Z-1 |
| (A1)-49 | A-45 | L-8 | Z-1 |
| (A1)-50 | A-46 | L-8 | Z-1 |
| (A1)-51 | A-47 | L-8 | Z-1 |
| (A1)-52 | A-48 | L-8 | Z-1 |
| (A1)-53 | A-49 | L-8 | Z-1 |
| (A1)-54 | A-50 | L-8 | Z-1 |
| (A1)-55 | A-51 | L-8 | Z-1 |
| (A1)-56 | A-52 | L-8 | Z-1 |
| (A1)-57 | A-53 | L-8 | Z-1 |
| (A1)-58 | A-54 | L-8 | Z-1 |
| (A1)-59 | A-55 | L-8 | Z-1 |
| (A1)-60 | A-56 | L-8 | Z-1 |
| (A1)-61 | A-57 | L-8 | Z-1 |
| (A1)-62 | A-58 | L-8 | Z-1 |
| (A1)-63 | A-32 | L-9 | Z-1 |
| (A1)-64 | A-32 | L-10 | Z-1 |
| (A1)-65 | A-32 | L-11 | Z-1 |
| (A1)-66 | A-32 | L-12 | Z-1 |
| (A1)-67 | A-32 | L-13 | Z-1 |
| (A1)-68 | A-32 | L-14 | Z-1 |
| (A1)-69 | A-32 | L-15 | Z-1 |
| (A1)-70 | A-32 | L-16 | Z-1 |
| (A1)-71 | A-32 | L-17 | Z-1 |
| (A1)-72 | A-32 | L-18 | Z-1 |
| (A1)-73 | A-32 | L-19 | Z-1 |
| (A1)-74 | A-32 | L-8 | Z-2 |
| (A1)-75 | A-32 | L-8 | Z-3 |
| (A1)-76 | A-32 | L-8 | Z-4 |
| (A1)-77 | A-32 | L-8 | Z-5 |
| (A1)-78 | A-32 | L-8 | Z-6 |
| (A1)-79 | A-32 | L-8 | Z-7 |
| (A1)-80 | A-32 | L-8 | Z-8 |
| (A1)-81 | A-32 | L-8 | Z-9 |
| (A1)-82 | A-32 | L-8 | Z-10 |
| (A1)-83 | A-32 | L-8 | Z-11 |
| (A1)-84 | A-32 | L-8 | Z-12 |
| (A1)-85 | A-32 | L-8 | Z-13 |
| (A1)-86 | A-32 | L-8 | Z-14 |
| (A1)-87 | A-32 | L-8 | Z-15 |
| (A1)-88 | A-32 | L-8 | Z-16 |
| (A1)-89 | A-32 | L-8 | Z-17 |
| (A1)-90 | A-32 | L-8 | Z-18 |
| (A1)-91 | A-16 | L-1 | Z-17 |
| (A1)-92 | A-15 | L-1 | Z-17 |

It is also preferable that the colorless pigment derivative A1 satisfies any one of the following spectral characteristics (a) to (d).

(a) maximum value of the molar light absorption coefficient in a wavelength range of more than 700 nm and 750 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

(b) maximum value of the molar light absorption coefficient in a wavelength range of more than 750 nm and 800 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

(c) maximum value of the molar light absorption coefficient in a wavelength range of more than 800 nm and 850 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

(d) maximum value of the molar light absorption coefficient in a wavelength range of more than 850 nm and 900 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

The content of the colorless pigment derivative A1 in the total solid content of the coloring photosensitive composition is preferably 0.3% to 20% by mass. The lower limit is preferably 0.6% by mass or more and more preferably 0.9% by mass or more. The upper limit is preferably 15% by mass or less, more preferably 12.5% by mass or less, and still more preferably 10% by mass or less.

In addition, the content of the colorless pigment derivative A1 is preferably 1 to 30 parts by mass with respect to 100 parts by mass of the pigment. The lower limit is preferably 2 parts by mass or more and more preferably 3 parts by mass or more. The upper limit is preferably 20 parts by mass or less and more preferably 15 parts by mass or less. The colorless pigment derivative A1 may be used singly or in combination of two or more kinds thereof. In a case where two or more kinds thereof are used in combination, the total amount thereof is preferably within the above-described range.

<Colored Pigment Derivative A2>

The coloring photosensitive composition according to the embodiment of the present invention includes a pigment derivative A2 (colored pigment derivative A2) in which a maximum value of a molar light absorption coefficient in a wavelength range of 400 to 700 nm is more than 3,000 L·mol⁻¹·cm⁻¹.

From the viewpoint of improving the contrast of the obtained film, the minimum value of the molar light absorption coefficient of the colored pigment derivative A2 in a wavelength range of 400 to 700 nm is preferably 4,000 L·mol⁻¹·cm⁻¹ or more and more preferably 5,000 L·mol⁻¹ cm⁻¹ or more. In addition, the maximum value thereof may be, for example, 100,000 L·mol⁻¹·cm⁻¹ or less.

In the present specification, the value of the molar light absorption coefficient of the colored pigment derivative A2 is a value measured by a method described in Examples described later.

[Coloring Agent Partial Structure]

The colored pigment derivative A2 preferably includes a compound having a coloring agent partial structure.

As the above-described coloring agent partial structure, a partial structure derived from at least one coloring agent selected from the group consisting of a benzimidazolone coloring agent, a benzimidazolinone coloring agent, a quinophthalone coloring agent, a phthalocyanine coloring agent, an anthraquinone coloring agent, a diketopyrrolopyrrole coloring agent, a quinacridone coloring agent, an azo coloring agent, an isoindolinone coloring agent, an isoindoline coloring agent, a dioxazine coloring agent, a perylene coloring agent, and a thioindigo coloring agent is preferable. In addition, from the reason that the effects of the present invention are more easily obtained remarkably, a partial structure derived from at least one coloring agent selected from the group consisting of a benzimidazolone coloring agent, a benzimidazolinone coloring agent, a quinophthalone coloring agent, a phthalocyanine coloring agent, a diketopyrrolopyrrole coloring agent, and an azo coloring agent is more preferable, and a partial structure derived from at least one coloring agent selected from the group consisting of a benzimidazolinone coloring agent and an azo coloring agent is still more preferable.

It is preferable that the colored pigment derivative A2 includes at least one partial structure selected from the group consisting of Formulae (Pg-1) to (Pg-10).

It is preferable that the colored pigment derivative A2 includes, as the above-described coloring agent partial structure, at least one partial structure selected from the group consisting of Formulae (Pg-1) to (Pg-10).

Among these, it is more preferable to have a structure represented by any one of Formula (Pg-1), Formula (Pg-2), Formula (Pg-3), Formula (Pg-5), or Formula (Pg-7) or a structure in which one or more hydrogen atoms are further removed from these structures. In Formula (Pg-3), M represents a metal atom, a metal oxide, or a metal halide.

In Formulae (Pg-1) to (Pg-10), a broken line portion represents a bonding site with another structure.

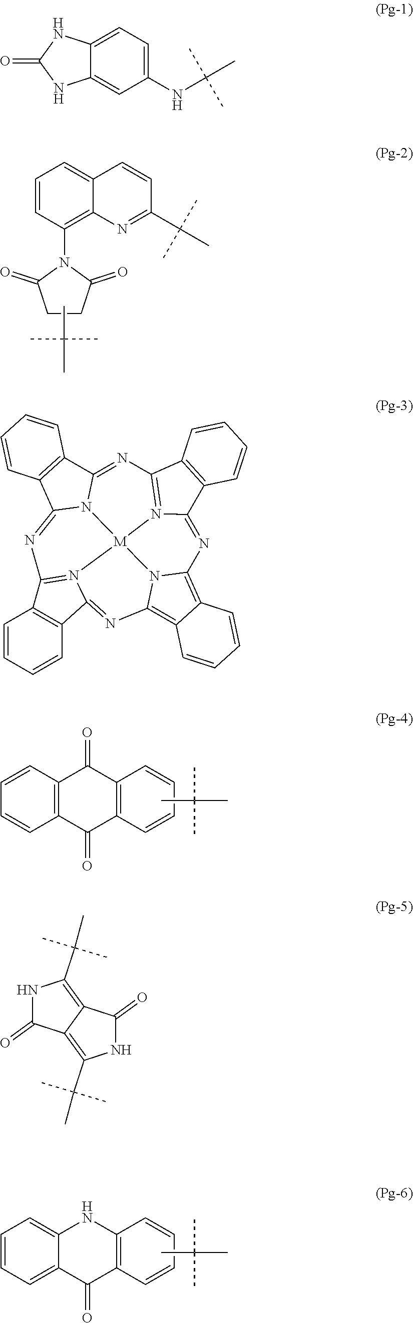

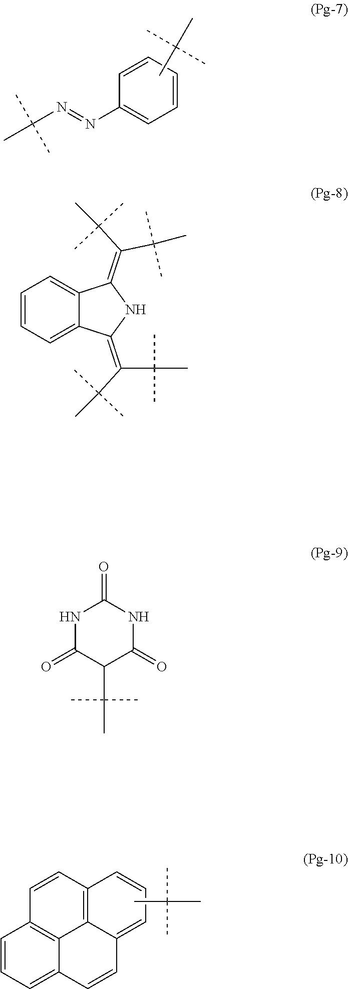

The number of coloring agent partial structures included in the colored pigment derivative A2 may be 1, or may be 2 or more.

[Acid Group or Basic Group]

The colored pigment derivative A2 preferably includes an acid group or a basic group.

The acid group in the colored pigment derivative A2 is preferably at least one selected from the group consisting of a carboxy group, a sulfo group, a phosphoric acid group, and salts thereof, and more preferably at least one selected from the group consisting of a carboxy group, a sulfo group, and salts thereof. Examples of an atom or atomic group constituting the salts include alkali metal ions (Li⁺, Na⁺, K⁺, and the like), alkaline earth metal ions (Ca′, Mg′, and the like), an ammonium ion, an imidazolium ion, a pyridinium ion, and a phosphonium ion.

The basic group included in the colored pigment derivative A2 is preferably at least one selected from the group consisting of an amino group, a pyridyl group, salts thereof, a salt of an ammonium group, and a phthalimidomethyl group, more preferably at least one selected from the group consisting of an amino group, a salt of an amino group, and a salt of an ammonium group, and more preferably an amino group or a salt of an amino group. Examples of the amino group include —NH2, a dialkylamino group, an alkylarylamino group, a diarylamino group, and a cyclic amino group. The dialkylamino group, alkylarylamino group, diarylamino group, and cyclic amino group may further have a substituent. Examples of the substituent include the above-described substituent T and a curable group. Examples of an atom or atomic group constituting the salts include a hydroxide ion, a halogen ion, a carboxylate ion, a sulfonate ion, and a phenoxide ion.

The number of acid groups or basic groups included in the colored pigment derivative A2 may be 1, or may be 2 or more. In a case where the number of acid groups or basic groups included in the colored pigment derivative A2 is 1, the coloring photosensitive composition is likely to be excellent in curability. In addition, in a case where the number of acid groups or basic groups included in the colored pigment derivative A2 is 2 or more, the coloring photosensitive composition tends to be excellent in dispersibility of the pigment. In addition, in a case where the number of acid groups or basic groups included in the colored pigment derivative A2 is 2 or more, from the viewpoint of dispersibility, it is preferable to include only two or more acid groups or include only two or more basic groups. In addition, it is preferable that the colored pigment derivative A2 has a basic group.

The number of acid groups or basic groups included in the colored pigment derivative A2 is preferably 1 to 4, more preferably 1 to 3, and still more preferably 1 or 2. In a case where the number of acid groups or basic groups is within the above-described range, for example, affinity between the colored pigment derivative A2 and a resin is likely to be improved, and the dispersibility of the pigment in the composition is likely to be improved.

[Curable Group]

From the viewpoint of improving curability of the coloring photosensitive composition, the colored pigment derivative A2 preferably includes a curable group.

The curable group is preferably at least one selected from the group consisting of an ethylenic unsaturated group and a cyclic ether group, and from the reason that more excellent curability is easily obtained, is preferably an ethylenic unsaturated group. Examples of the ethylenic unsaturated group include a vinyl group, a vinylphenyl group, an allyl group, a (meth)acryloyl group, a (meth)acrylamide group, and a maleimide group. Among these, a (meth)acryloyl group is preferable, and a (meth)acryloxy group is more preferable. Examples of the cyclic ether group include an epoxy group and an oxetanyl group, and an epoxy group is preferable. The number of curable groups included in the colored pigment derivative A2 is preferably 1 to 8, more preferably 2 to 6, and still more preferably 2 to 4. In a case where the number of curable groups is within the above-described range, the curability of the coloring photosensitive composition is good, and line width sensitivity and adhesiveness can be more improved.

[Formula (A2-1) to Formula (A2-3)]

In the present invention, the colored pigment derivative A2 is preferably a compound represented by any one of Formulae (A2-1) to (A2-3), and from the reason that the dispersibility of the pigment is excellent, more preferably a compound represented by Formula (A2-1) or Formula (A2-2).

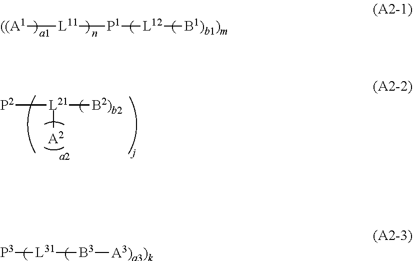

In Formula (A2-1), P¹ represents a coloring agent partial structure, L¹¹'s each independently represent an a1+1 valent linking group, L¹²'s each independently represent a b1+1 valent linking group, A¹'s each independently represent a curable group, B¹'s each independently represent an acid group or a basic group, a1's each independently represent an integer of 1 or more, b1's each independently represent an integer of 1 or more, n represents an integer of 0 or more, and m represents an integer of 1 or more;

in Formula (A2-2), P² represents a coloring agent partial structure, L²¹ represents an a2+b2+1 valent linking group, A² represents a curable group, B² represents an acid group or a basic group, a2's each independently represent an integer of 0 or more, b2's each independently represent an integer of 1 or more, and j represents an integer of 1 or more; and in Formula (A2-3), P³ represents a coloring agent partial structure, L³¹ represents an a3+1 valent linking group, A³ represents a curable group, B³ represents an acid group or a basic group, a3's each independently represent an integer of 1 or more, and k represents an integer of 1 or more.

In Formula (A2-1), a1 is preferably 1 to 4, more preferably 1 to 3, and still more preferably 1 or 2. n is preferably 0 to 4, more preferably 0 to 3, and still more preferably 0, 1, or 2. b1 is preferably 1 to 4, more preferably 1 to 3, and still more preferably 1 or 2. m is preferably 1 to 4, more preferably 1 to 3, and still more preferably 1 or 2.

In Formula (A2-2), a2 is preferably 0 to 4, more preferably 0 to 3, and still more preferably 0, 1, or 2. b2 is preferably 1 to 4, more preferably 1 to 3, and still more preferably 1 or 2. j is preferably 1 to 4, more preferably 1 to 3, and still more preferably 1 or 2.

In Formula (A2-3), a3 is preferably 1 to 4, more preferably 1 to 3, and still more preferably 1 or 2.

In Formula (A2-3), k is preferably 1 to 4, more preferably 1 to 3, and still more preferably 1 or 2.

In Formulae (A2-1) to (A2-3), examples of the coloring agent partial structure represented by P¹ to P³ include the structure described as the coloring agent partial structure in the above-described colored pigment derivative A2, and the preferred aspects are also the same.

In Formulae (A2-1) to (A2-3), examples of the curable group represented by A¹ to A³ include the group described as the curable group in the above-described colored pigment derivative A2, and the preferred aspects are also the same.

In Formulae (A2-1) to (A2-3), B¹ to B³ each independently represent an acid group or a basic group. Examples of the acid group and the basic group include the above-described groups, and the preferred aspects are also the same.

In Formulae (A2-1) to (A2-3), examples of the a1+1 valent linking group represented by L¹¹, the b1+1 valent linking group represented by L¹², the a2+b2+1 valent linking group represented by L²¹, and the a3+1 valent linking group represented by L³¹ include a hydrocarbon group, a heterocyclic group, —O—, —S—, —CO—, —COO—, —OCO—, —SO₂—, —NR^{L}—, —NR^{L}SO₂—, —SO₂NR^{L}—, and a group of a combination of two or more of these groups, in which R^{L} represents a hydrogen atom, an alkyl group, or an aryl group. The hydrocarbon group may be an aliphatic hydrocarbon group or an aromatic hydrocarbon group. Examples of the hydrocarbon group include an alkylene group, an arylene group, and a group obtained by removing one or more hydrogen atoms from these groups. The number of carbon atoms in the alkylene group is preferably 1 to 30, more preferably 1 to 15, and still more preferably 1 to 10. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10. The heterocyclic group is preferably monocyclic or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12. The hydrocarbon group and heterocyclic group may have a substituent. Examples of the substituent include groups in the description of the substituent T described above. The number of carbon atoms in the alkyl group represented by R^{L} is preferably 1 to 20, more preferably 1 to 15, and still more preferably 1 to 8. The alkyl group may be linear, branched, or cyclic, and is preferably linear or branched and more preferably linear. The alkyl group represented by R^{L} may further have a substituent. Examples of the substituent include the above-described substituent T. The aryl group represented by R^{L} preferably has 6 to 30 carbon atoms, more preferably has 6 to 20 carbon atoms, and still more preferably has 6 to 12 carbon atoms. The aryl group represented by R^{L} may further have a substituent. Examples of the substituent include the above-described substituent T.

In Formulae (A2-1) to (A2-3), it is preferable that L¹¹, L¹², L²¹, and L³¹ are each independently a group represented by any one of Formulae (L-1) to (L-5). According to this aspect, affinity between the colored pigment derivative A2 and the pigment is improved, and the dispersibility of the pigment in the composition can be more improved.

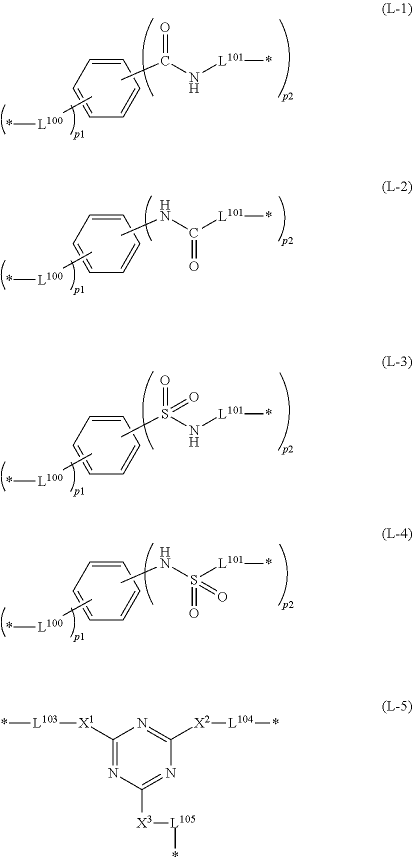

In the formulae, * represents a bonding hand,

p1 represents an integer of 0 to 5 and p2 represents an integer of 1 to 6, where p1+p2 is an integer of 2 to 6,

L¹⁰⁰ to L¹⁰⁵ each independently represent a single bond or a divalent linking group, and

X¹, X², and X³ each independently represent —O—, —S—, or —NR^{L1}—, where R^{L1} represents a hydrogen atom, an alkyl group, or an aryl group.

The alkyl group and aryl group represented by R^{L1} have the same meanings as the alkyl group and aryl group described in the above section of R^{L}, and the preferred ranges are also the same. In addition, the alkyl group and aryl group represented by R^{L1} may further have a substituent. Examples of the substituent include the above-described substituent T.

Examples of the divalent linking group represented by L¹⁰⁰ to L¹⁰⁵ include an alkylene group, an arylene group, a heterocyclic group, —O—, —S—, —CO—, —COO—, —OCO—, —SO₂—, —NR^{L2}—, —NR^{L2}CO—, —CONR^{L2}—, —NR^{L2}SO₂—, —SO₂NR^{L2}—, and a group formed by a combination of two or more of these groups.

The number of carbon atoms in the alkylene group is preferably 1 to 30, more preferably 1 to 15, and still more preferably 1 to 10. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10. The heterocyclic group is preferably monocyclic or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12. The alkylene group, arylene group, and heterocyclic group may have a substituent. Examples of the substituent include the above-described substituent T.

R^{L2} represents a hydrogen atom, an alkyl group, or an aryl group. The alkyl group and aryl group represented by R^{L2} have the same meanings as the alkyl group and aryl group described in the above section of R^{L}, and the preferred ranges are also the same. In addition, the alkyl group and aryl group represented by R^{L2} may further have a substituent. Examples of the substituent include the above-described substituent T.

In Formula (L-5), X¹, X², and X³ each independently represent —O—, —S—, or —NR^{L1}—, and —NR^{L1}— is preferable. In addition, R^{L1} is preferably a hydrogen atom.

The colored pigment derivative A2 preferably includes a functional group having an intermolecular interaction. In a case where the colored pigment derivative A2 has such a functional group, the affinity between the colored pigment derivative A2 and the pigment is improved, and the dispersibility of the pigment in the composition can be more improved. Examples of the above-described functional group include an amide group, a urea group, a urethane group, a sulfonamide group, a triazine group, an isocyanuric group, an imide group, and an imidazolidinone group. These functional groups may be included in the coloring agent partial structure, or may be included in a site (for example, L¹¹ or L¹² in Formula (A1), L²¹ in Formula (A2), L³¹ in Formula (A3), and the like) other than the coloring agent partial structure.

Specific examples of the colored pigment derivative A2 include compounds having the following structures. In the following structural formulae, Ac represents an acetyl group.

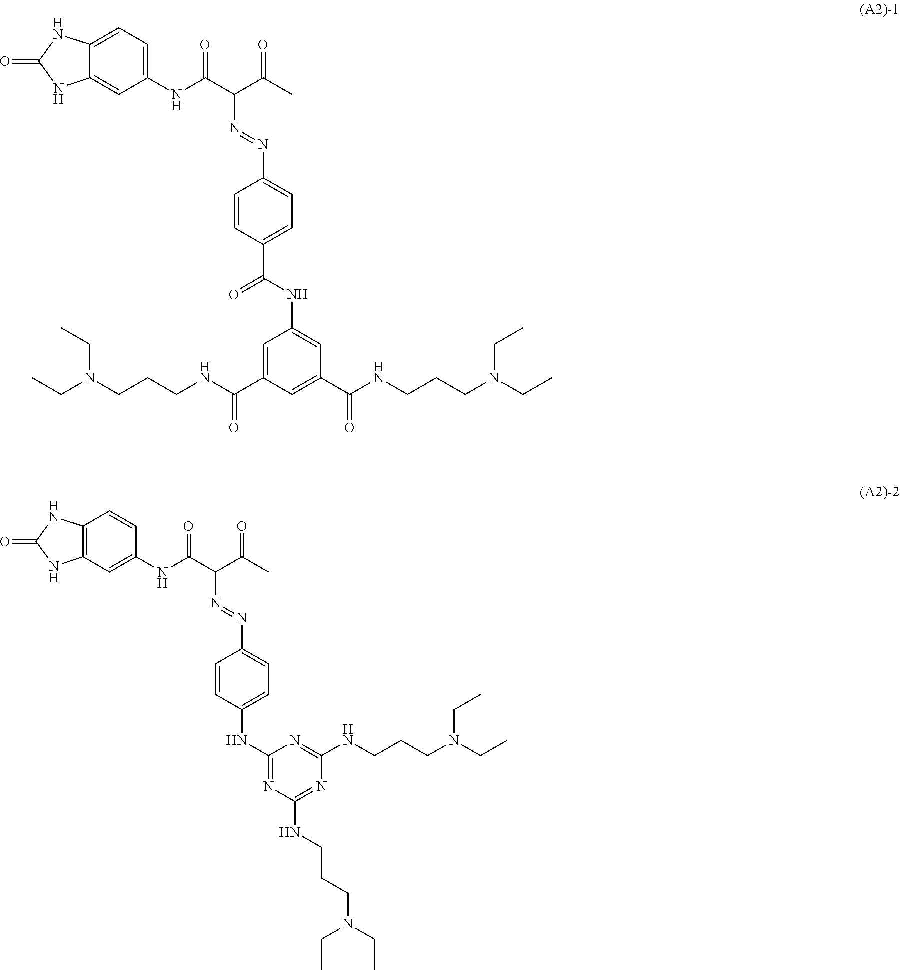 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1 ; CCN(CC)CCCNc1nc(NCCCN(CC)CC)nc(Nc2ccc(/N=N/C(C(C)=O)C(=O)Nc3ccc4[nH]c(=O)[nH]c4c3)cc2)n1]

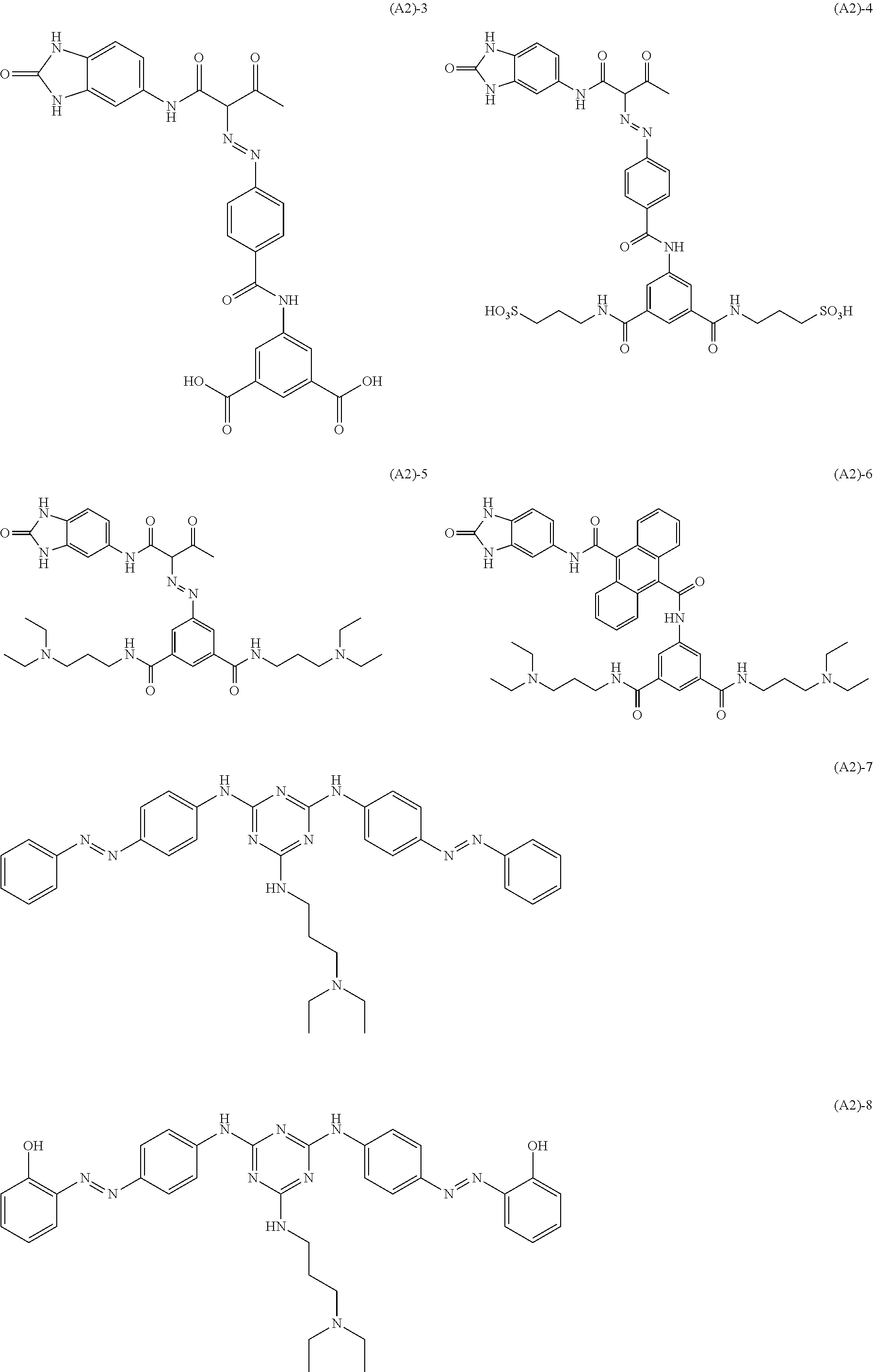

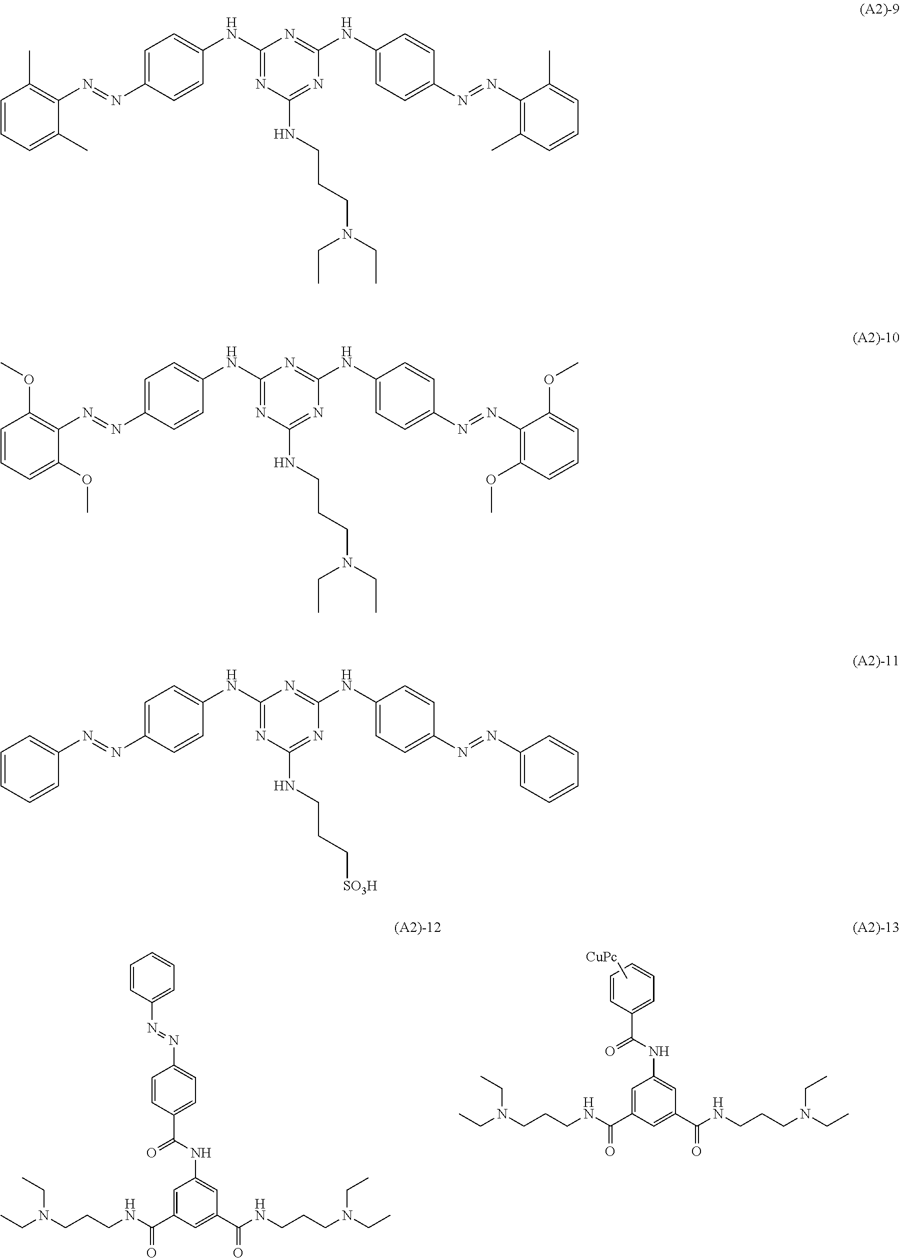

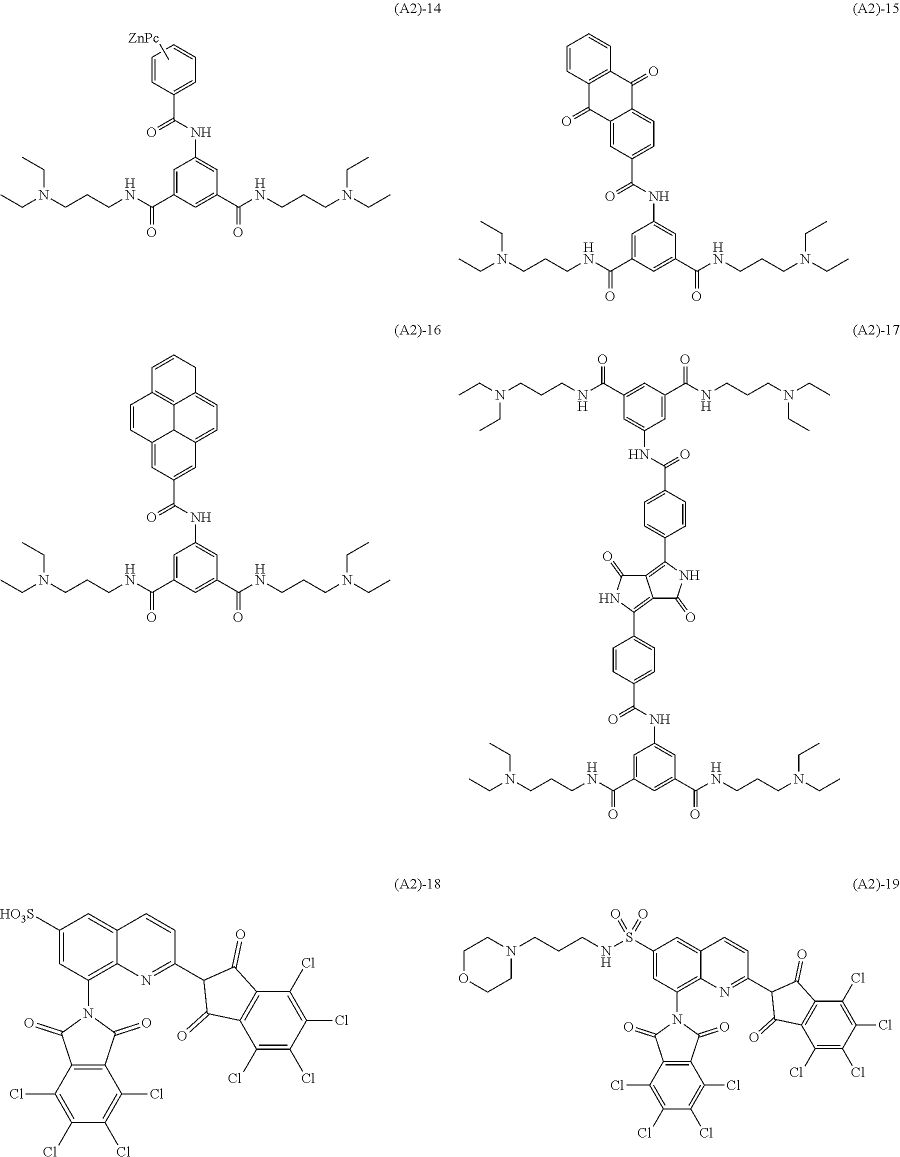

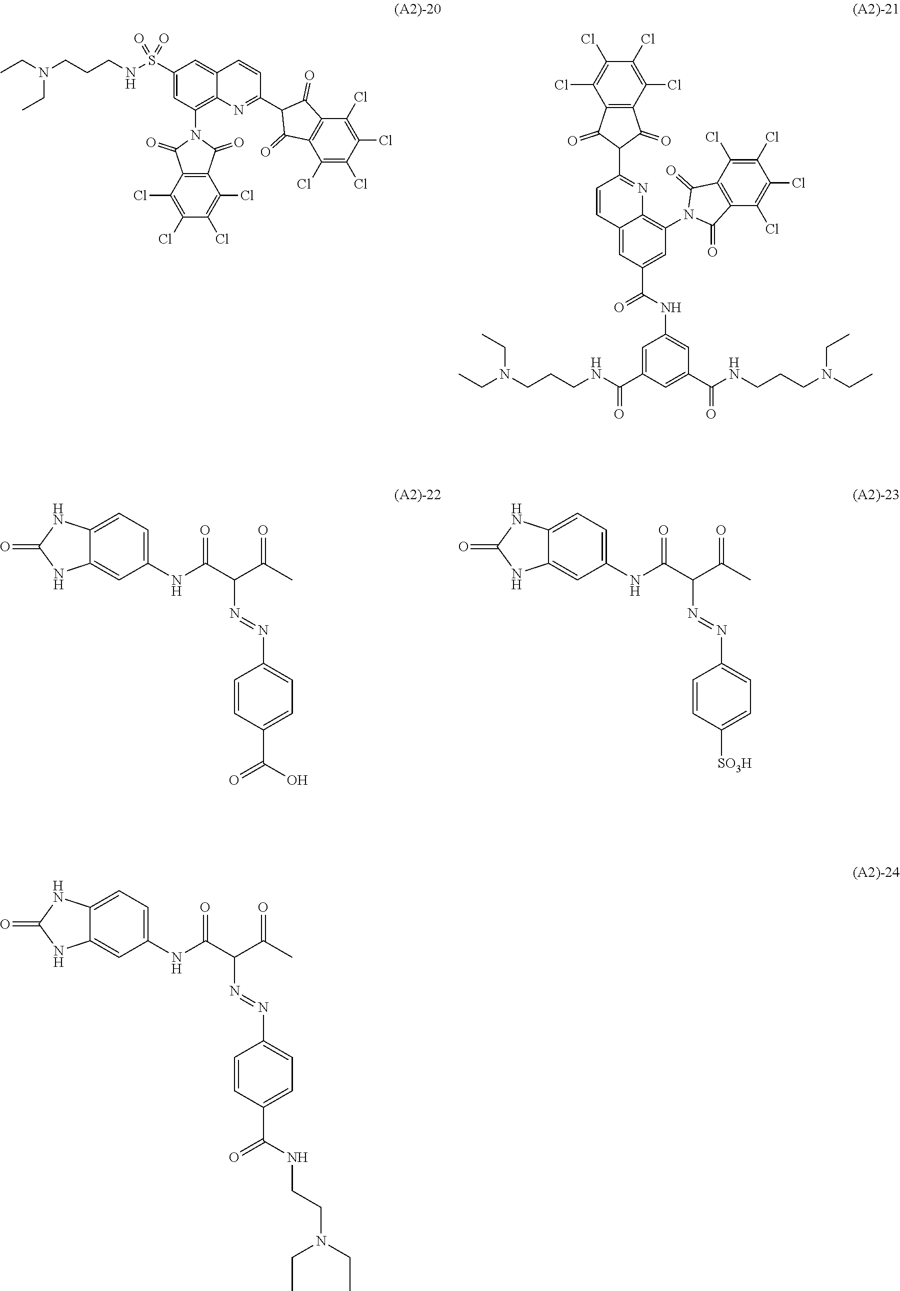 [SMILES: CCN(CC)CCCNS(=O)(=O)c1cc(N2C(=O)c3c(Cl)c(Cl)c(Cl)c(Cl)c3C2=O)c2nc(C3C(=O)c4c(Cl)c(Cl)c(Cl)c(Cl)c4C3=O)ccc2c1 ; CCN(CC)CCCNC(=O)c1cc(NC(=O)c2cc(N3C(=O)c4c(Cl)c(Cl)c(Cl)c(Cl)c4C3=O)c3nc(C4C(=O)c5c(Cl)c(Cl)c(Cl)c(Cl)c5C4=O)ccc3c2)cc(C(=O)NCCCN(CC)CC)c1 ; CC(=O)C(/N=N/c1ccc(C(=O)O)cc1)C(=O)Nc1ccc2[nH]c(=O)[nH]c2c1 ; CC(=O)C(/N=N/c1ccc(S(=O)(=O)O)cc1)C(=O)Nc1ccc2[nH]c(=O)[nH]c2c1 ; CCN(CC)CCNC(=O)c1ccc(/N=N/C(C(C)=O)C(=O)Nc2ccc3[nH]c(=O)[nH]c3c2)cc1]

In Formula (A2)-12, CuPc represents copper phthalocyanine (Formula (CuPc); * represents a bonding site with (A2)-12), and in Formula (A2)-13, ZnPc represents zinc phthalocyanine (Formula (ZnPc); * represents a bonding site with (A2)-13).

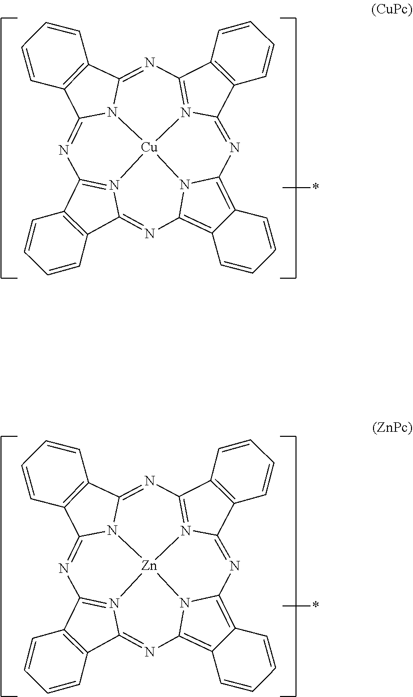

The molecular weight of the colored pigment derivative A2 is preferably 2,000 or less, more preferably 1,500 or less, and more preferably 1,000 or less. The lower limit is preferably 300 or more.

In a case where the colored pigment derivative A2 has a curable group, the curable group value is preferably 0.1 to 10 mmol/g. The lower limit is preferably 0.5 mmol/g or more and more preferably 1 mmol/g or more. The upper limit is preferably 8 mmol/g or less and more preferably 4 mmol/g or less. The curable group value of the colored pigment derivative A2 is a value calculated by dividing the number of curable groups included in one molecule of the colored pigment derivative A2 by the molecular weight of the colored pigment derivative A2. Examples of the curable group include an ethylenic unsaturated group and a cyclic ether group.

In addition, in a case where the curable group included in the colored pigment derivative A2 is an ethylenic unsaturated group, the ethylenic unsaturated group value (hereinafter, also referred to as a C═C value) of the colored pigment derivative A2 is preferably 0.1 to 10 mmol/g. The lower limit is preferably 0.5 mmol/g or more and more preferably 1 mmol/g or more. The upper limit is preferably 8 mmol/g or less and more preferably 4 mmol/g or less. The C═C value of the colored pigment derivative A2 is a value calculated by dividing the number of ethylenic unsaturated groups included in one molecule of the colored pigment derivative A2 by the molecular weight of the colored pigment derivative A2.

In a case where the colored pigment derivative A2 is a compound having a basic group, the basic group value of the colored pigment derivative A2 is preferably 10 mmol/g or less, more preferably 8 mmol/g or less, and still more preferably 5 mmol/g or less. The lower limit is preferably 0.1 mmol/g or more, more preferably 1 mmol/g or more, and still more preferably 2 mmol/g or more.

In addition, in a case where the colored pigment derivative A2 is a compound having an acid group, the acid value of the colored pigment derivative A2 is preferably 10 mmol/g or less, more preferably 8 mmol/g or less, and still more preferably 5 mmol/g or less. The lower limit is preferably 0.1 mmol/g or more, more preferably 1 mmol/g or more, and still more preferably 2 mmol/g or more.

The colored pigment derivative A2 is also preferably a hydrophilic compound. According to this aspect, interaction between the pigment surface and the resin is improved, and dispersibility of the pigment in the composition can be more improved. Hydrophilicity of the colored pigment derivative A2 can be evaluated by, for example, Log P value, and as the Log P value of the colored pigment derivative A2 is smaller, the hydrophilicity tends to be higher. The Log P value of the colored pigment derivative A2 is preferably 3 or less, more preferably 2 or less, and still more preferably 1 or less. The Log P value of the colored pigment derivative A2 is a value of the common logarithm of partition coefficient P of the compound A2 in 1-octanol/water. In the present specification, the Log P value of the compound A2 is obtained by prediction calculation using ChemiBioDraw Ultra, ver. 13.0.2.3021 (manufactured by Cambridge Soft).

The colored pigment derivative A2 preferably has one or more maximum absorption wavelength in a range of 350 to 700 nm, more preferably has one or more maximum absorption wavelength in a range of 380 to 600 nm, and still more preferably has one or more maximum absorption wavelength in a range of 400 to 500 nm.

It is also preferable that the colored pigment derivative A2 satisfies any one of the following spectral characteristics (a) to (d).

(a) maximum value of the molar light absorption coefficient in a wavelength range of more than 700 nm and 750 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

(b) maximum value of the molar light absorption coefficient in a wavelength range of more than 750 nm and 800 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

(c) maximum value of the molar light absorption coefficient in a wavelength range of more than 800 nm and 850 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

(d) maximum value of the molar light absorption coefficient in a wavelength range of more than 850 nm and 900 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

The content of the colored pigment derivative A2 in the total solid content of the coloring photosensitive composition is 1% to 15% by mass. The lower limit is preferably 2% by mass or more and more preferably 3% by mass or more. The upper limit is preferably 12% by mass or less and more preferably 10% by mass or less.

In addition, the content of the colored pigment derivative A2 is preferably 0.1 to 20 parts by mass with respect to 100 parts by mass of the pigment. The lower limit is preferably 1 parts by mass or more, more preferably 2 parts by mass or more, and still more preferably 5 parts by mass or more. The upper limit is preferably 18 parts by mass or less and more preferably 15 parts by mass or less. The colored pigment derivative A2 may be used singly or in combination of two or more kinds thereof. In a case where two or more kinds thereof are used in combination, the total amount thereof is preferably within the above-described range.

<Content Ratio of Colorless Pigment Derivative A1 and Colored Pigment Derivative A2>

The content ratio of the colorless pigment derivative A1 and the colored pigment derivative A2 in the coloring photosensitive composition according to the embodiment of the present invention is not particularly limited as long as the colorless pigment derivative A1 and the colored pigment derivative A2 are mixed. However, with respect to the total mass of the pigment derivative A1 and the pigment derivative A2, the content of the pigment derivative A1 is preferably 5% to 98% by mass, more preferably 10% to 95% by mass, still more preferably 20% to 90% by mass, and even more preferably 50% to 90% by mass.

<Molar Light Absorption Coefficient of Colorless Pigment Derivative A1 and Colored Pigment Derivative A2>

The difference between the maximum value of the molar light absorption coefficient of the colorless pigment derivative A1 in a wavelength range of 400 to 700 nm and the maximum value of the molar light absorption coefficient of the colored pigment derivative A2 in a wavelength range of 400 to 700 nm is preferably 300 to 100,000 L·mol⁻¹·cm⁻¹ and more preferably 500 to 50,000 L·mol⁻¹·cm⁻¹.

<Pigment>

The coloring photosensitive composition according to the embodiment of the present invention contains a pigment. Examples of the pigment include a white pigment, a black pigment, a chromatic pigment, and a near-infrared absorbing pigment. In the present invention, the white pigment includes not only a pure white pigment but also a bright gray (for example, grayish-white, light gray, and the like) pigment close to white.

In addition, the pigment may be an inorganic pigment or an organic pigment, but from the viewpoint that dispersion stability is more easily improved, an organic pigment is preferable.

In addition, as the pigment, a pigment having a maximum absorption wavelength in a wavelength range of 400 to 2,000 nm is preferable, and a pigment having a maximum absorption wavelength in a wavelength range of 400 to 700 nm is more preferable.

In addition, in a case of using a pigment (preferably a chromatic pigment) having a maximum absorption wavelength in a wavelength range of 400 to 700 nm, the coloring photosensitive composition according to the embodiment of the present invention can be preferably used as a coloring photosensitive composition for forming a colored layer in a color filter.

Examples of the colored layer include a red-colored layer, a green-colored layer, a blue-colored layer, a magenta-colored layer, a cyan-colored layer, and a yellow-colored layer.

The average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the coloring photosensitive composition is good. In the present invention, the primary particle diameter of the pigment can be determined from an image obtained by observing primary particles of the pigment using a transmission electron microscope. Specifically, a projected area of the primary particles of the pigment is determined, and a diameter (corresponding circle diameter) of a perfect circle with the same area as the projected area is calculated as the primary particle diameter of the pigment. In addition, the average primary particle diameter in the present invention is the arithmetic average of the primary particle diameters with respect to 400 primary particles of the pigment. In addition, the primary particle of the pigment refers to a particle which is independent without aggregation.

[Chromatic Pigment]

The chromatic pigment is not particularly limited, and a known chromatic pigment can be used. Examples of the chromatic pigment include a pigment having a maximum absorption wavelength in a wavelength range of 400 to 700 nm. Examples thereof include a yellow pigment, an orange pigment, a red pigment, a green pigment, a violet pigment, and a blue pigment. Specific examples of these pigments include the following pigments.

Color Index (C. I.) Pigment Yellow (hereinafter, also simply referred to as “PY”) 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 231, 232 (methine/polymethine-based), and the like (all of which are yellow pigments);

C. I. Pigment Orange (hereinafter, also simply referred to as “PO”) 2, 5, 13, 16, 17:1, 31, 34, 36, 38, 43, 46, 48, 49, 51, 52, 55, 59, 60, 61, 62, 64, 71, 73, and the like (all of which are orange pigments);

C. I. Pigment Red (hereinafter, also simply referred to as “PR”) 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based, Organo Ultramarine, Bluish Red), and the like (all of which are red pigments);

C. I. Pigment Green (hereinafter, also simply referred to as “PG”) 7, 10, 36, 37, 58, 59, 62, 63, and the like (all of which are green pigments);

C. I. Pigment Violet (hereinafter, also simply referred to as “PV”) 1, 19, 23, 27, 32, 37, 42, 60 (triarylmethane-based), 61 (xanthene-based), and the like (all of which are violet pigments; hereinafter); and

C. I. Pigment Blue (hereinafter, also simply referred to as “PB”) 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In the coloring photosensitive composition according to the embodiment of the present invention, from the viewpoint that the effects of the present invention are more easily obtained, it is preferable to include a green pigment as the pigment, more preferable to include halogenated phthalocyanine, and still more preferable to include PG 36 and/or PG 58.

In addition, in the coloring photosensitive composition according to the embodiment of the present invention, it is also preferable to use the above-described green pigment and a yellow pigment in combination. Preferred examples of the yellow pigment to be used in combination include PY 150 and/or PY 185.

—Green Pigment—

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A. In addition, as the green pigment, compounds described in CN2010-6909027A, a phthalocyanine compound having a phosphoric acid ester as a ligand, or the like can also be used.

—Blue Pigment—

In addition, an aluminum phthalocyanine compound having a phosphorus atom can also be used as the blue pigment. Specific examples thereof include the compounds described in paragraphs 0022 to 0030 of JP2012-247591A and paragraph 0047 of JP2011-157478A.

—Yellow Pigment—

In addition, as the yellow pigment, pigments described in JP2017-201003A and pigments described in JP2017-197719A can be used.

In addition, as the yellow pigment, a metal azo pigment which includes at least one kind of an anion selected from the group consisting of an azo compound represented by Formula (I) and an azo compound having a tautomeric structure of the azo compound represented by Formula (I), two or more kinds of metal ions, and a melamine compound can also be used.

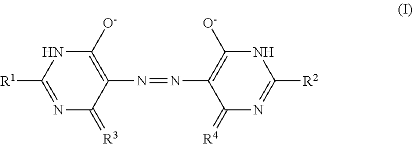

In the formula, R^{L} and R² each independently represent —OH or —NR⁵R⁶, R³ and R⁴ each independently represent ═O or ═NR⁷, and R⁵ to R⁷ each independently represent a hydrogen atom or an alkyl group. The alkyl group represented by R⁵ to R⁷ preferably has 1 to 10 carbon atoms, more preferably has 1 to 6 carbon atoms, and still more preferably has 1 to 4 carbon atoms. The alkyl group may be linear, branched, or cyclic, and is preferably linear or branched and more preferably linear. The alkyl group may have a substituent. The substituent is preferably a halogen atom, a hydroxy group, an alkoxy group, a cyano group, or an amino group.

With regard to the metal azo pigment, reference can be made to the description in paragraph Nos. 0011 to 0062 and 0137 to 0276 of JP2017-171912A, paragraph Nos. 0010 to 0062 and 0138 to 0295 of JP2017-171913A, paragraph Nos. 0011 to 0062 and 0139 to 0190 of JP2017-171914A, and paragraph Nos. 0010 to 0065 and 0142 to 0222 of JP2017-171915A, the contents of which are incorporated herein by reference.

—Red Pigment—

As the red pigment, diketopyrrolopyrrole-based pigments described in JP2017-201384A, in which the structure has at least one substituted bromine atom, diketopyrrolopyrrole-based pigments described in paragraph Nos. 0016 to 0022 of JP6248838B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the compound, a compound represented by Formula (DPP1) is preferable, and a compound represented by Formula (DPP2) is more preferable.

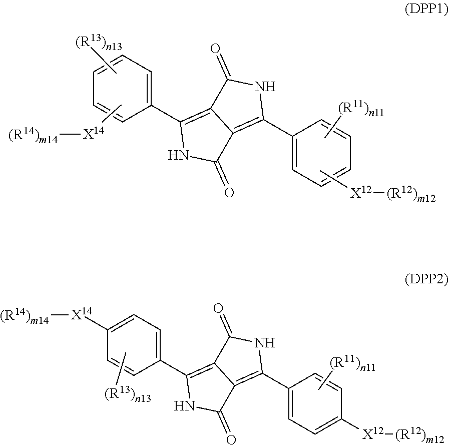

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Examples of the substituent represented by R¹¹ and R¹³ include the groups in the above-described substituent T, and preferred specific examples thereof include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

In the present invention, the chromatic pigment may be used in combination of two or more kinds thereof. In addition, in a case where the chromatic pigment is used in combination of two or more kinds thereof, the combination of two or more chromatic pigments may form black. Examples of such a combination include the following aspects (1) to (7). In a case where two or more chromatic pigments are included in the coloring photosensitive composition and the combination of two or more chromatic pigments forms black, the coloring photosensitive composition according to the embodiment of the present invention can be preferably used as the near-infrared transmission filter.

(1) aspect in which a red pigment and a blue pigment are contained.

(2) aspect in which a red pigment, a blue pigment, and a yellow pigment are contained.

(3) aspect in which a red pigment, a blue pigment, a yellow pigment, and a violet pigment are contained.

(4) aspect in which a red pigment, a blue pigment, a yellow pigment, a violet pigment, and a green pigment are contained.

(5) aspect in which a red pigment, a blue pigment, a yellow pigment, and a green pigment are contained.

(6) aspect in which a red pigment, a blue pigment, and a green pigment are contained.

(7) aspect in which a yellow pigment and a violet pigment are contained.

[White Pigment]

Examples of the white pigment include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. In addition, the white pigment is preferably a particle having a refractive index of 2.10 or more at 25° C. with respect to light having a wavelength of 589 nm. The above-described refractive index is preferably 2.10 to 3.00 and more preferably 2.50 to 2.75.

In addition, as the white pigment, the titanium oxide described in “Titanium Oxide-Physical Properties and Applied Technology, written by Manabu Kiyono, pages 13 to 45, published in Jun. 25, 1991, published by Shuppan Co., Ltd.” can also be used.

The white pigment is not limited to a compound formed of a single inorganic substance, and may be particles combined with other materials. For example, it is preferable to use a particle having a pore or other materials therein, a particle having a number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraph Nos. 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

[Black Pigment]

The black pigment is not particularly limited, and a known black pigment can be used. Examples thereof include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black pigment include Color Index (C. I.) Pigment Black 1 and 7. It is preferable that the titanium black has a small primary particle diameter of the individual particles and has a small average primary particle diameter. Specifically, the average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.).

[Near-Infrared Absorbing Pigment]

The near-infrared absorbing pigment is preferably an organic pigment. In addition, the near-infrared absorbing pigment preferably has a maximum absorption wavelength in a wavelength range of more than 700 nm and 1,400 nm or less. In addition, the maximum absorption wavelength of the near-infrared absorbing pigment is preferably 1,200 nm or less, more preferably 1,000 nm or less, and still more preferably 950 nm or less. In addition, in the near-infrared absorbing pigment, A550/Aₘₐₓ, which is a ratio of an absorbance A550 at a wavelength of 550 nm to an absorbance Aₘₐₓ at the maximum absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near-infrared absorbing pigment excellent in visible light transparency and near-infrared rays shielding property can be obtained. In the present invention, the maximum absorption wavelength of the near-infrared absorbing pigment and values of absorbance at each wavelength are values obtained from an absorption spectrum of a film formed by using a coloring photosensitive composition including the near-infrared absorbing pigment.

The near-infrared absorbing pigment is not particularly limited, and examples thereof include a pyrrolopyrrole compound, a perylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. Among these, at least one compound selected from the group consisting of a pyrrolopyrrole compound, a squarylium compound, a cyanine compound, a phthalocyanine compound, and a naphthalocyanine compound is preferable, and a pyrrolopyrrole compound or a squarylium compound is more preferable, and a pyrrolopyrrole compound is particularly preferable.

The content of the pigment in the total solid content of the coloring photosensitive composition is preferably 5% by mass or more, more preferably 10% by mass or more, still more preferably 20% by mass or more, and even more preferably 30% by mass or more, and particularly preferably 40% by mass or more. The upper limit is preferably 80% by mass or less, more preferably 70% by mass or less, and still more preferably 60% by mass or less.

[Dye]

The coloring photosensitive composition according to the embodiment of the present invention can contain a dye. The dye is not particularly limited and a known dye can be used. The dye may be a chromatic dye or may be a near-infrared absorbing dye. Examples of the chromatic dye include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound. In addition, the thiazole compound described in JP2012-158649A, the azo compound described in JP2011-184493A, or the azo compound described in JP2011-145540A can also be used. In addition, as yellow dyes, the quinophthalone compounds described in paragraph Nos. 0011 to 0034 of JP2013-054339A, or the quinophthalone compounds described in paragraph Nos. 0013 to 0058 of JP2014-026228A can be used. Examples of the near-infrared absorbing dye include a pyrrolopyrrole compound, a perylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. In addition, the squarylium compounds described in JP2017-197437A, the squarylium compounds described in paragraph Nos. 0090 to 0107 of WO2017/213047A, the pyrrole ring-containing compounds described in paragraph Nos. 0019 to 0075 of JP2018-054760A, the pyrrole ring-containing compounds described in paragraph Nos. 0078 to 0082 of JP2018-040955A, the pyrrole ring-containing compounds described in paragraph Nos. 0043 to 0069 of JP2018-002773A, the squarylium compounds having an aromatic ring at the α-amide position described in paragraph Nos. 0024 to 0086 of JP2018-041047A, the amide-linked squarylium compounds described in JP2017-179131A, the compounds having a pyrrole bis-type squarylium skeleton or a croconium skeleton described in JP2017-141215A, the dihydrocarbazole bis-type squarylium compounds described in JP2017-082029, the asymmetric compounds described in paragraph Nos. 0027 to 0114 of JP2017-068120A, the pyrrole ring-containing compounds (carbazole type) described in JP2017-067963A, the phthalocyanine compounds described in JP6251530B, and the like can also be used.

The content of the dye in the total solid content of the coloring photosensitive composition is preferably 1% by mass or more, more preferably 5% by mass or more, and particularly preferably 10% by mass or more. The upper limit is not particularly limited, but is preferably 70% by mass or less, more preferably 65% by mass or less, and still more preferably 60% by mass or less.

In addition, the content of the dye is preferably 5 to 50 parts by mass with respect to 100 parts by mass of the pigment. The upper limit is preferably 45 parts by mass or less and more preferably 40 parts by mass or less. The lower limit is preferably 10 parts by mass or more and still more preferably 15 parts by mass or more.

In addition, it is also possible that the coloring photosensitive composition according to the embodiment of the present invention does not substantially contain the dye. The case where the coloring photosensitive composition according to the embodiment of the present invention does not substantially include the dye means that the content of the dye in the total solid content of the coloring photosensitive composition according to the embodiment of the present invention is preferably 0.1% by mass or less, more preferably 0.05% by mass or less, and particularly preferably 0% by mass.

<Content Ratio of Pigment and Pigment Derivative>

The content ratio of the above-described pigment, the colorless pigment derivative A1, and the colored pigment derivative A2 in the coloring photosensitive composition according to the embodiment of the present invention is not particularly limited as long as the pigment is dispersed. However, with respect to 100 parts by mass of the pigment, the total content of the colorless pigment derivative A1 and the colored pigment derivative A2 is preferably 1 to 30 parts by mass, more preferably 2 to 20 parts by mass, and particularly preferably 3 to 15 parts by mass.

<Polymerizable Compound>

The coloring photosensitive composition according to the embodiment of the present invention contains a polymerizable compound. The above-described colored pigment derivative A2 and a compound corresponding to the dispersant having a curable group described later are not considered to be the polymerizable compound. As the polymerizable compound, a known compound which is cross-linkable by a radical, an acid, or heat can be used. In the present invention, the polymerizable compound is preferably, for example, a compound having an ethylenic unsaturated group. Examples of the ethylenic unsaturated group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3,000. The upper limit is more preferably 2,000 or less and still more preferably 1,500 or less. The lower limit is more preferably 150 or more and still more preferably 250 or more.

The polymerizable compound is preferably a compound including 3 or more ethylenic unsaturated groups, more preferably a compound including 3 to 15 ethylenic unsaturated groups, and still more preferably a compound having 3 to 6 ethylenic unsaturated groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the polymerizable compound in an unexposed area is easily removed during development of a film formed from the coloring photosensitive composition and the generation of a development residue can be suppressed. Examples of the acid group include a carboxy group, a sulfo group, and a phosphoric acid group, and a carboxy group is preferable. Examples of a commercially available product of the polymerizable compound having an acid group include ARONIX M-510, M-520, and ARONIX TO-2349 (manufactured by TOAGOSEI CO., LTD). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility of the film in a developer is good, and in a case where the acid value of the polymerizable compound is 40 mgKOH/g or less, it is advantageous in production and handling.

In the present specification, unless otherwise specified, the acid value is a value measured by a titration method specified in JIS K0070 (1992).

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

The content of the polymerizable compound in the total solid content of the coloring photosensitive composition is preferably 0.1% to 50% by mass. The lower limit is more preferably 0.5% by mass or more and still more preferably 1% by mass or more. The upper limit is more preferably 45% by mass or less and still more preferably 40% by mass or less. The polymerizable compound may be used singly or in combination of two or more kinds thereof. In a case where two or more kinds thereof are used in combination, the total thereof is preferably within the above-described range.

<Photopolymerization Initiator>

The coloring photosensitive composition according to the embodiment of the present invention includes a photopolymerization initiator. The photopolymerization initiator is not particularly limited, and can be appropriately selected from known photopolymerization initiators. For example, a compound having photosensitivity to light ray in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from the group consisting of an oxime compound, an α-hydroxyketone compound, an α-aminoketone compound, and an acylphosphine compound is more preferable, and from the viewpoint that the effects of the present invention are easily obtained, an oxime compound is still more preferable. The details of the photopolymerization initiator can be found in paragraphs 0065 to 0111 of JP2014-130173A and in JP6301489B, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all manufactured by BASF). Examples of a commercially available product of the α-aminoketone compound include IRGACURE-907, IRGACURE-369, IRGACURE-379, and IRGACURE-379EG (all manufactured by BASF). Examples of a commercially available product of the acylphosphine compound include IRGACURE-819 and DAROCUR-TPO (both manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2000-080068A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, and the compounds described in paragraph Nos. 0025 to 0038 of WO2017/164127A. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one. Examples of a commercially available product include IRGACURE OXE01, IRGACURE OXE02, IRGACURE OXE03, and IRGACURE OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having low colorability or a compound having high transparency and being resistant to discoloration. Examples of a commercially available product include ADEKA ARKLS NCI-730, NCI-831, and NCI-930 (all of which are manufactured by ADEKA Corporation).

In the present invention, an oxime compound having a fluorene ring can also be used as the photopolymerization initiator. Specific examples of the oxime compound having a fluorene ring include the compounds described in JP2014-137466A. The contents thereof are incorporated herein by reference.

In the present invention, an oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A. The contents thereof are incorporated herein by reference.

In the present invention, an oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

In the present invention, an oxime compound having a benzofuran skeleton can also be used as the photopolymerization initiator. Specific examples thereof include OE-01 to OE-75 described in WO2015/036910A.

Specific examples of the oxime compound which are preferably used in the present invention are shown below, but the present invention is not limited thereto.

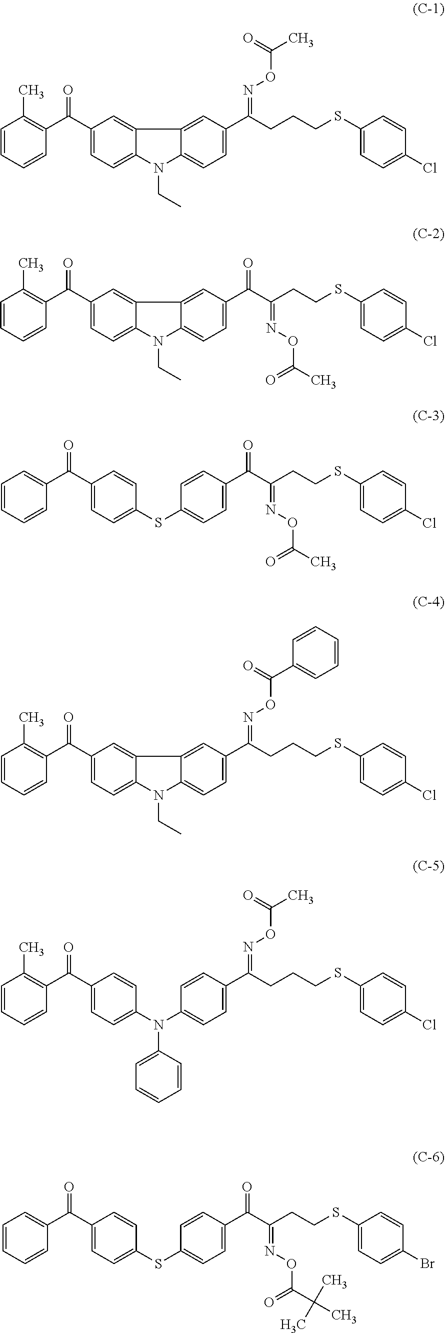 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

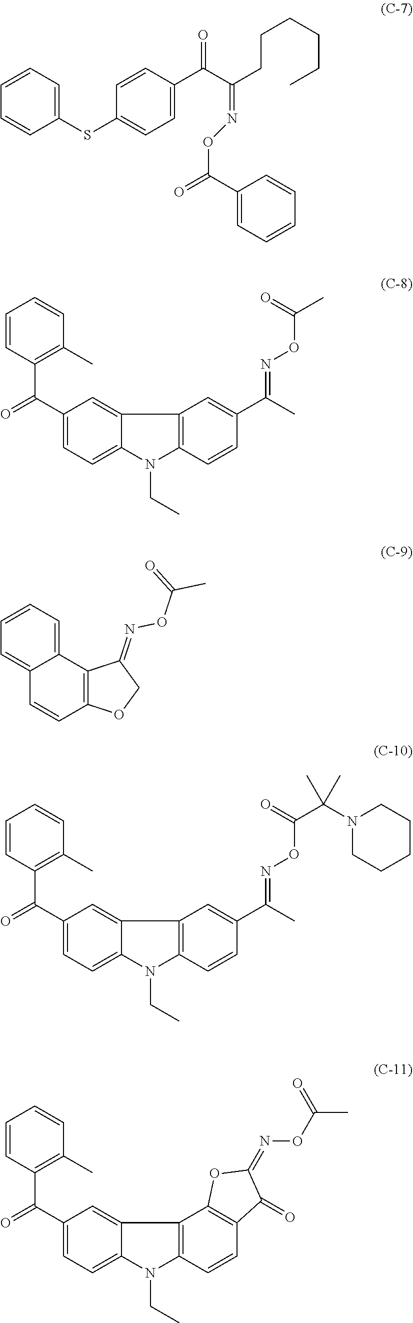 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

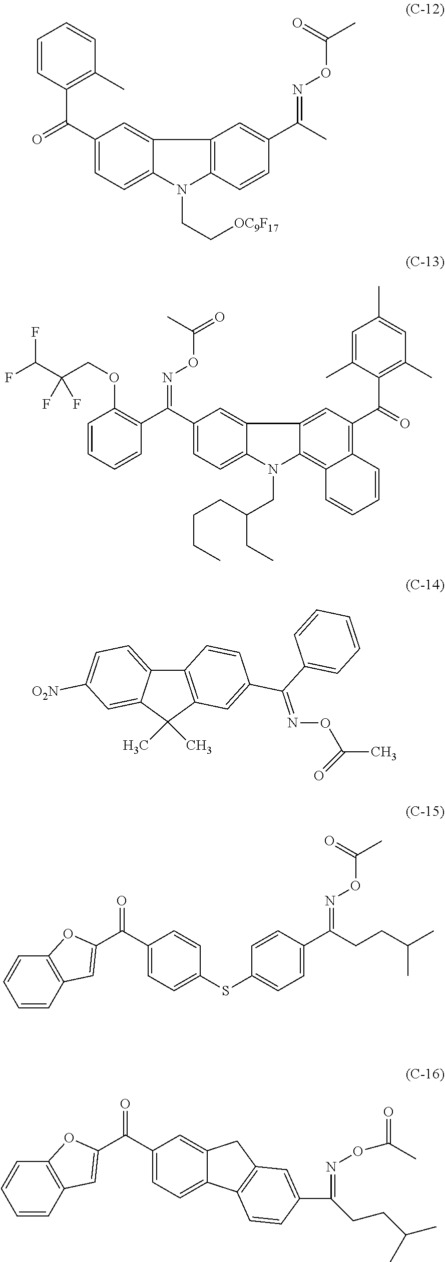

The photopolymerization initiator used in the present invention is preferably a compound having a maximum absorption wavelength in a wavelength range of 350 to 500 nm and more preferably a compound having a maximum absorption wavelength in a wavelength range of 360 to 480 nm.

The difference between the maximum absorption wavelength of the colored pigment derivative A2 in a wavelength range of 400 to 700 nm and the maximum absorption wavelength of the photopolymerization initiator is preferably 20 to 200 nm and more preferably 50 to 100 nm.

In addition, from the viewpoint that the effects of the present invention are more easily obtained, the molar light absorption coefficient of the photopolymerization initiator used in the present invention at a wavelength of 365 nm is preferably 1,000 L·mol⁻¹·cm⁻¹ or more, more preferably 3,000 L·mol⁻¹·cm⁻¹ or more, and still more preferably 5,000 L·mol⁻¹·cm⁻¹ or more. In addition, the maximum value thereof is not particularly limited, but is preferably 100,000 L·mol⁻ⁱ·cm⁻¹ or less. The molar light absorption coefficient of the photopolymerization initiator can be measured using a known method. For example, the molar light absorption coefficient is preferably measured by a spectrophotometer (Cary-5 spectrophotometer, manufactured by Varian) using an ethyl acetate solvent at a concentration of 0.01 g/L.

As the photopolymerization initiator, a bifunctional or tri- or more functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring photosensitive composition can be improved. Specific examples of the bifunctional or tri- or more functional photoradical polymerization initiator include dimers of the oxime compounds described in JP2010-527339A, JP2011-524436A, WO2015/004565A, paragraph Nos. 0412 to 0417 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; and the photopolymerization initiator (A) described in paragraph Nos. 0017 to 0026 of JP2017-151342A.

The content of the photopolymerization initiator in the total solid content of the coloring photosensitive composition according to the embodiment of the present invention is preferably 0.1% to 30% by mass. The lower limit is preferably 0.5% by mass or more and more preferably 1% by mass or more. The upper limit is preferably 20% by mass or less and more preferably 15% by mass or less. In the coloring photosensitive composition according to the embodiment of the present invention, the photopolymerization initiator may be used singly or in combination of two or more kinds thereof. In a case where two or more kinds thereof are used, the total content thereof is preferably within the above-described range.

<Resin>

The coloring photosensitive composition according to the embodiment of the present invention can contain a resin. The resin is blended in, for example, an application for dispersing particles such as a pigment in a coloring photosensitive composition or an application as a binder. Mainly, a resin which is used for dispersing particles such as a pigment is also referred to as a dispersant. However, such applications of the resin are only exemplary, and the resin can also be used for other purposes in addition to such applications.

The weight-average molecular weight (Mw) of the resin is preferably 3,000 to 2,000,000. The upper limit is preferably 1,000,000 or less and more preferably 500,000 or less. The lower limit is preferably 4,000 or more and more preferably 5,000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. These resins may be used singly or as a mixture of two or more kinds thereof. In addition, the resins described in paragraph Nos. 0041 to 0060 of JP2017-206689A, and the resins described in paragraph Nos. 0022 to 0071 of JP2018-010856A can also be used.

[Resin Having Acid Group]

The coloring photosensitive composition according to the embodiment of the present invention preferably includes a resin having an acid group as the resin. According to this aspect, the developability of the coloring photosensitive composition can be improved, and pixels having excellent rectangularity can be easily formed. Examples of the acid group include a carboxy group, a phosphoric acid group, a sulfo group, and a phenolic hydroxy group, and a carboxy group is preferable. The resin having an acid group can be used, for example, as an alkali-soluble resin.

The resin having an acid group preferably includes a repeating unit having an acid group in the side chain, and more preferably includes 5% to 70% by mole of repeating units having an acid group in the side chain with respect to the total repeating units of the resin. The upper limit of the content of the repeating unit having an acid group in the side chain is preferably 50% by mole or less and more preferably 30% by mole or less. The lower limit of the content of the repeating unit having an acid group in the side chain is preferably 10% by mole or more and more preferably 20% by mole or more.

It is also preferable that the resin having an acid group includes a repeating unit derived from a monomer component including a compound represented by Formula (ED1) and/or a compound represented by Formula (ED2) (hereinafter, these compounds may be referred to as an “ether dimer”).

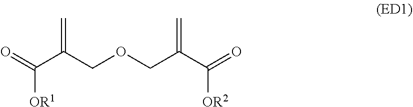

In Formula (ED1), R^{L} and R² each independently represent a hydrogen atom or a hydrocarbon group having 1 to 25 carbon atoms, which may have a substituent.

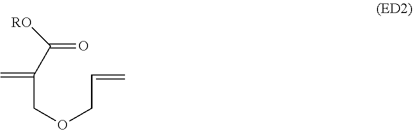

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

Specific examples of the ether dimer can be found in paragraph No. 0317 of JP2013-029760A, the content of which is incorporated herein by reference.

It is also preferable that the resin used in the present invention includes a repeating unit derived from a compound represented by Formula (X).

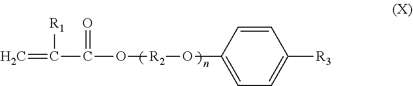

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring. n represents an integer of 1 to 15.

With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. A commercially available product can also be used as the resin having an acid group.

The acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. The weight-average molecular weight (Mw) of the resin having an acid group is preferably 5,000 to 100,000. In addition, the number-average molecular weight (Mn) of the resin having an acid group is preferably 1,000 to 20,000.

Examples of the resin having an acid group include a resin having the following structures. In the structures, the parenthesized subscripts represent the content (% by mole) of each repeating unit.

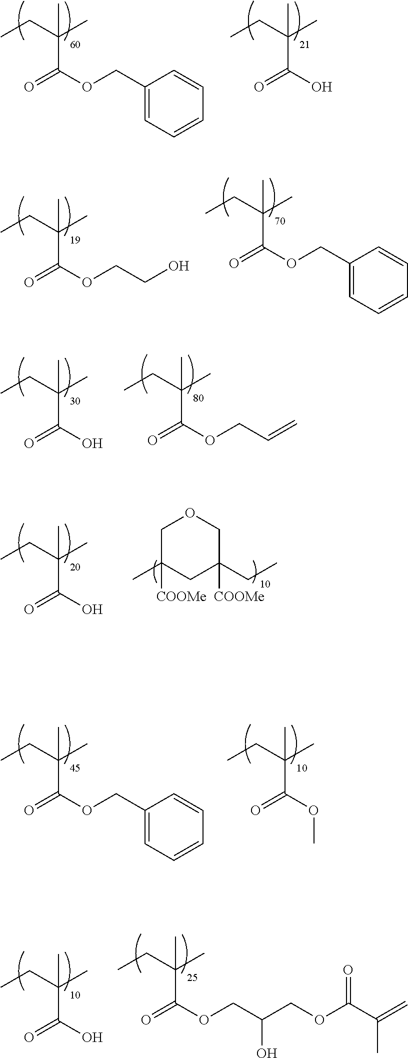

[Dispersant]

The coloring photosensitive composition according to the embodiment of the present invention can also include a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70% by mole or more in a case where the total amount of the acid group and the basic group is 100% by mole, and more preferably a resin substantially consisting of only an acid group. The acid group included in the acidic dispersant (acidic resin) is preferably a carboxy group. The acid value of the acidic dispersant (acidic resin) is preferably 20 to 180 mgKOH/g, more preferably 30 to 150 mgKOH/g, and still more preferably 50 to 100 mgKOH/g. In addition, the basic dispersant (basic resin) represents a resin in which the amount of the basic group is larger than the amount of the acid group. The basic dispersant (basic resin) is preferably a resin in which the amount of the basic group is more than 50% by mole in a case where the total amount of the acid group and the basic group is 100% by mole. The basic group included in the basic dispersant is preferably an amino group.

The resin used as a dispersant preferably includes a repeating unit having an acid group. In a case where the resin used as a dispersant includes a repeating unit having an acid group, the generation of the development residue can be further suppressed in the formation of a pattern by a photolithography method.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa14 or less, and a side chain which has 40 to 10,000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

In addition, the above-described resin (alkali-soluble resin) having an acid group can also be used as a dispersant.

In addition, it is also preferable that the resin used as a dispersant is a resin including a repeating unit having an ethylenic unsaturated group in the side chain. The content of the repeating unit having an ethylenic unsaturated group in the side chain is preferably 10% by mole or more, more preferably 10% to 80% by mole, and still more preferably 20% to 70% by mole with respect to the total repeating units of the resin.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. The dispersing agents described in paragraph Nos. 0041 to 0130 of JP2014-130338A can also be used, the contents of which are incorporated herein by reference. The resin described as a dispersant can be used for an application other than the dispersant. For example, the resin can also be used as a binder.

—Dispersant Having Curable Group—

Suitable examples of the dispersant used in the present invention also include a dispersant having a curable group.

As the curable group in the above-described dispersant, an ethylenic unsaturated group is preferable, at least one group selected from the group consisting of a vinyl group, a vinylphenyl group, an allyl group, a (meth)acryloyl group, a (meth)acrylamide group, and a maleimide group is more preferable, a (meth)acryloyl group is still more preferable, and an acryloyl group is particularly preferable.

In addition, the curable group is preferably included in the side chain, and also preferably included at the molecular terminal of the side chain.

In the present invention, the compounds corresponding to the above-described colorless pigment derivative A1 and the above-described colored pigment derivative A2 do not correspond to the dispersant having a curable group.

In addition, the dispersant is preferably a compound not having the above-described coloring agent partial structure.

In addition, the preferred weight-average molecular weight of the dispersant is preferably 10,000 to 100,000.

<<Constitutional Unit Represented by Formula D1>>

The dispersant having a curable group preferably has a constitutional unit represented by Formula D1.

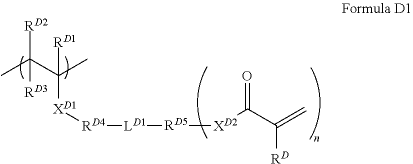

In Formula D1, R^{D1} to R^{D3} each independently represent a hydrogen atom or an alkyl group, X^{D1} represents —COO—, —CONR^{D6}—, or an arylene group, where R^{D6} represents a hydrogen atom, an alkyl group, or an aryl group, R^{D4} represents a divalent linking group, L^{D1} represents a group represented Formula D2 or Formula D3, R^{D5} represents an (n+1)-valent linking group, X^{D2} represents an oxygen atom or NR^{D7}—, where R^{D7} represents a hydrogen atom, an alkyl group, or an aryl group, R^{D} represents a hydrogen atom or a methyl group, and n represents an integer of 1 or more.

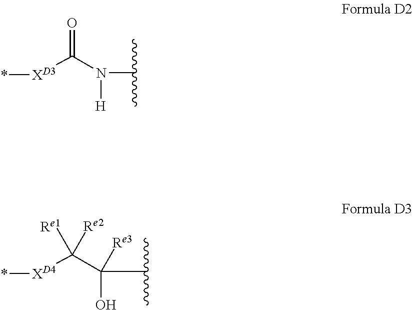

In Formulae D2 and D3, X^{D3} represents an oxygen atom or —NH—, X^{D4} represents an oxygen atom or COO—, R^{e1} to R^{e3} each independently represent a hydrogen atom or an alkyl group, where at least two of R^{e1} to R^{e3} may be bonded to each other to form a ring structure, * and a wavy line represent a bonding position with other structures.

In addition, the structure represented by Formula D3 may include a structure represented by Formula D3′, as a structural isomer.

In Formula D3′, X^{D5} has the same meaning as X^{D4} in Formula D3, and R^{e4} to R^{e6} have the same meanings as R^{e1} to R^{e3} in Formula D3, and the preferred aspects are also the same.

In addition, in Formula D3′, at least two of R^{e4} to R^{e6} may be bonded to each other to form a ring structure, and * and a wavy line represent a bonding position with other structures.

The structure represented by Formula D3′ may exist as a structural isomer by, for example, reacting a group such as a carboxy group and a phenolic hydroxyl group with an epoxy group.

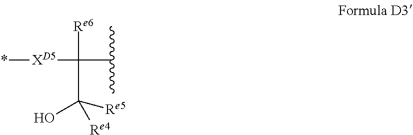

By using the above-described dispersant having a curable group in the coloring photosensitive composition, deep portion curability of the obtained cured product is likely to be excellent.

The reason why the above-described effect is obtained is not clear, but presumed as follows.

In a case of using the above-described dispersant having a curable group, since the resin components are polymerized with each other, it is considered that the obtained cured product is likely to be excellent in deep portion curability.

In particular, in a resin having the constitutional unit represented by Formula D1, since the constitutional unit has, in the side chain, the group represented by Formula D2 or Formula D3, which is a polar group, it is considered that, in the composition, the width of movement of the (meth)acryloyl group is increased, and the reactivity is excellent. In addition, since the constitutional unit has the group represented by Formula D2 or Formula D3, dispersibility is excellent due to that aggregation of the resins is suppressed, and the reactivity of the (meth)acryloyl group is more improved. Therefore, it is considered that the coloring photosensitive composition having excellent deep portion curability can be easily obtained.

In addition, by having the constitutional unit represented by Formula D1, a highly reactive (meth)acryloyl group can be introduced at a position away from the main chain through the group represented by Formula D2 or Formula D3. As a result, the (meth)acryloyl groups in the resin molecule do not react with each other, and the probability of reacting with the (meth)acryloyl group of other resin molecules or with other crosslinking components (for example, the polymerizable compound and the like) in the composition is increased. Therefore, it is considered that the crosslinking reaction proceeds efficiently in a composition having a pigment concentration, and the deep portion curability and formation of a pattern shape can be improved.

In addition, since the constitutional unit represented by Formula D1 has a relatively long side chain structure and has the polar group represented by Formula D2 or Formula D3 in the side chain, it is considered that adsorbability to the pigment is enhanced, and three-dimensional resilience which suppresses aggregation of pigment particles exhibits. As a result, it is considered that the dispersibility of the pigment is improved.

Furthermore, in a case of having a constitutional unit represented by Formula D4 described later, it is considered that carboxylic acid serving as an adsorptive group can be introduced at a position away from the main chain to enhance pigment adsorbability and improve dispersion stability.

In addition, by introducing the constitutional unit represented by Formula D1, it is considered that substrate adhesiveness, formation of a pattern shape, and deep portioncurability are also excellent, and further, by having the constitutional unit represented by Formula D4 described later, it is considered that the dispersion stability is improved.

From the viewpoint of deep portion curability, R^{D1} to R^{D3} in Formula D1 are each independently preferably a hydrogen atom or a methyl group, and more preferably a hydrogen atom. In addition, from the viewpoint of deep portion curability, it is still more preferable that R^{D1} is a hydrogen atom or a methyl group, and R^{D2} and R^{D3} are hydrogen atoms. In a case where L^{D1} is the group represented by Formula D2, R^{D1} is still more preferably a methyl group, and in a case where L^{D1} is the group represented by Formula D3, R^{D1} is still more preferably a hydrogen atom.

From the viewpoint of deep portion curability, X^{D1} in Formula D1 is preferably —COO— or —CONR^{D6}— and more preferably —COO—. In a case where X^{D1} is an arylene group, it is preferable to be a divalent aromatic hydrocarbon group having 6 to 20 carbon atoms, more preferable to be a phenylene group or a naphthylene group, and still more preferable to be a phenylene group. In a case where X^{D1} is —COO—, it is preferable that the carbon atom in —COO— is bonded to the carbon atom to which R^{D1} in Formula D1 is bonded. In a case where X^{D1} is —CONR^{D6}—, it is preferable that the carbon atom in —CONR^{D6}— is bonded to the carbon atom to which R^{D1} in Formula D1 is bonded.

R^{D6} is preferably a hydrogen atom or an alkyl group and more preferably a hydrogen atom.

From the viewpoint of deep portion curability, R^{D4} in Formula D1 is preferably a hydrocarbon group or a group in which two or more hydrocarbon groups are bonded to one or more structures selected from the group consisting of ether bonds and ester bonds, and more preferably a hydrocarbon group or a group in which two or more hydrocarbon groups are bonded to one or more ester bonds.

In addition, R^{D4} in Formula D1 is preferably a group in which two or more groups selected from the group consisting of an alkylene group, an ether group, a carbonyl group, a phenylene group, a cycloalkylene group, and an ester bond are bonded, and more preferably a group in which two or more groups selected from the group consisting of an alkylene group, an ether group, and an ester bond are bonded.

In addition, from the viewpoint of deep portion curability, R^{D4} in the formula is preferably a group having a total of 2 to 60 atoms, more preferably a group having a total of 2 to 50 atoms, and particularly preferably a group having a total of 2 to 40 atoms.

Furthermore, from the viewpoint of deep portion curability, it is particularly preferable that R^{D4} is a group selected from the group consisting of a hydrocarbon group, an alkyleneoxy group, an alkylenecarbonyloxy group, and any group represented by the following structures, and R^{D5} is an alkylene group or a group in which two or more alkylene groups are bonded to one or more structures selected from the group consisting of ether bonds and ester bonds.

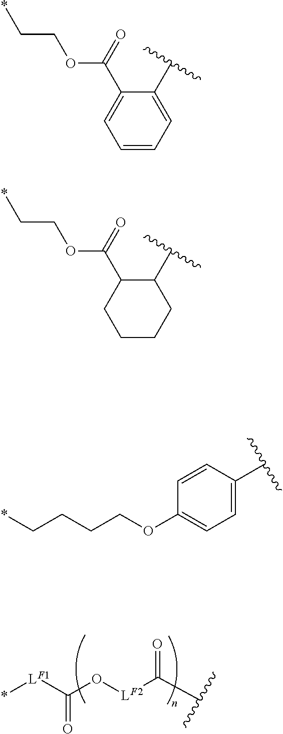

In the formulae, * and a wavy line represent a bonding position with other structures, and it is preferable that * represents a bonding site with X^{D1} in Formula D1 and a wavy line represents a bonding position with L^{D1}.

In addition, in the formulae, L^{F1} and L^{F2} each independently represent a hydrocarbon group, and n represents an integer of 0 or more.

An aspect in which L^{F1} and L^{F2} are each independently an alkylene group having 2 to 20 carbon atoms is also preferable.

An aspect in which L^{F1} and L^{F2} are the same groups is also preferable.

An aspect in which n is 0 to 100 is also preferable.

From the viewpoint of deep portion curability, n in Formula D1 is preferably an integer of 1 to 6, more preferably an integer of 1 to 3, and still more preferably 1.

From the viewpoint of deep portion curability, R^{D5} in Formula D1 is preferably a divalent linking group, more preferably an alkylene group or a group in which two or more alkylene groups are bonded to one or more structures selected from the group consisting of ether bonds and ester bonds, still more preferably an alkyleneoxyalkylene group, and particularly preferably a methyleneoxy-n-butylene group.

In addition, from the viewpoint of deep portion curability, R^{D5} in Formula D1 is preferably a group having a total of 2 to 40 atoms, more preferably a group having a total of 2 to 30 atoms, and particularly preferably a group having a total of 2 to 20 atoms.

From the viewpoint of deep portion curability, X^{D2} in Formula D1 is preferably an oxygen atom.

R^{D7} is preferably a hydrogen atom or an alkyl group and more preferably a hydrogen atom.

R^{D} is preferably a hydrogen atom.

From the viewpoint of dispersibility, L^{D1} in Formula D1 is preferably the group represented by Formula D2, and from the viewpoint of formation of a pattern shape and suppression of development residue, L^{D1} in Formula D1 is preferably the group represented by Formula D3.

In Formulae D2 and D3, it is preferable that * is a bonding site with R^{D4} and a wavy line is a bonding site with R^{D5}.

From the viewpoint of deep portion curability and dispersibility, X^{D3} in Formula D2 is preferably an oxygen atom.

In addition, in a case where L^{D1} is the group represented by Formula D2, from the viewpoint of deep portion curability and dispersibility, it is particularly preferable that R^{D4} is a group selected from the group consisting of an ethylene group, an n-propylene group, an isopropylene group, an n-butylene group, and an isobutylene group, and R^{D5} is an ethylene group.

From the viewpoint of deep portion curability, formation of a pattern shape, and suppression of development residue, X^{D4} in Formula D3 is preferably —COO—. In a case where X^{D4} is —COO—, it is preferable that the oxygen atom in —COO— is bonded to the carbon atom to which R^{e1} is bonded.

From the viewpoint of deep portion curability, formation of a pattern shape, and suppression of development residue, R^{e1} to R^{e3} in Formula D3 are preferably hydrogen atoms.

In addition, in a case where L^{D1} is the group represented by Formula D3, from the viewpoint of deep portion curability, formation of a pattern shape, and suppression of development residue, it is particularly preferable that R^{D4} is a hydrocarbon group, a group in which two or more hydrocarbon groups are bonded to one or more structures selected from the group consisting of ether bonds and ester bonds, or any group represented by the following structures, and R^{D3} is an alkylene group or a group in which two or more alkylene groups are bonded to one or more structures selected from the group consisting of ether bonds and ester bonds.

Preferred examples of the group represented by Formula D2 include a group represented by Formula D2-1 or Formula D2-2.

In addition, preferred examples of the group represented by Formula D3 include a group represented by Formula D3-1 or Formula D3-2.

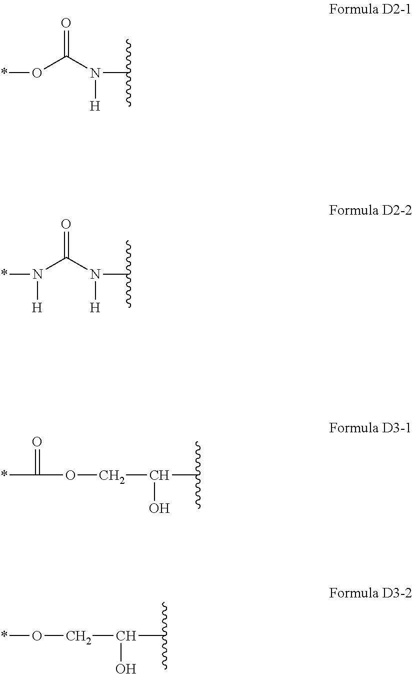 [SMILES: *NC(=O)O* ; *NC(=O)N* ; *C(=O)OCC(*)O ; *OCC(*)O]

* and a wavy line have the same meanings as * and the wavy line in Formula D2 or Formula D3, and the preferred aspects are also the same.

In addition, in the structures represented by Formula D3-1 and Formula D3-2, at least a part of the structures may be replaced with a structure represented by, with regard to Formula D3-1, Formula D3-1′, or with regard to Formula D3-2, Formula D3-2′. As an example, the structure represented by Formula D3-1′ may exist as a structural isomer in the reaction of a carboxylic acid compound with a compound having an epoxy group and an acryloyl group. As an example, the structure represented by Formula D3-2′ may exist as a structural isomer in the reaction of a phenol compound with a compound having an epoxy group and an acryloyl group.

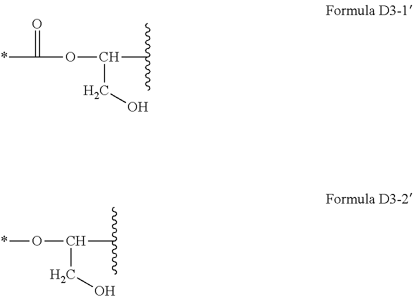 [SMILES: *C(=O)OC(*)CO ; *OC(*)CO]

Preferred examples of the constitutional unit represented by Formula D1 include the following structures, and it is needless to say that the constitutional unit is not limited thereto. In the following specific examples, m represents an integer of 2 or more, and n represents an integer of 1 or more.

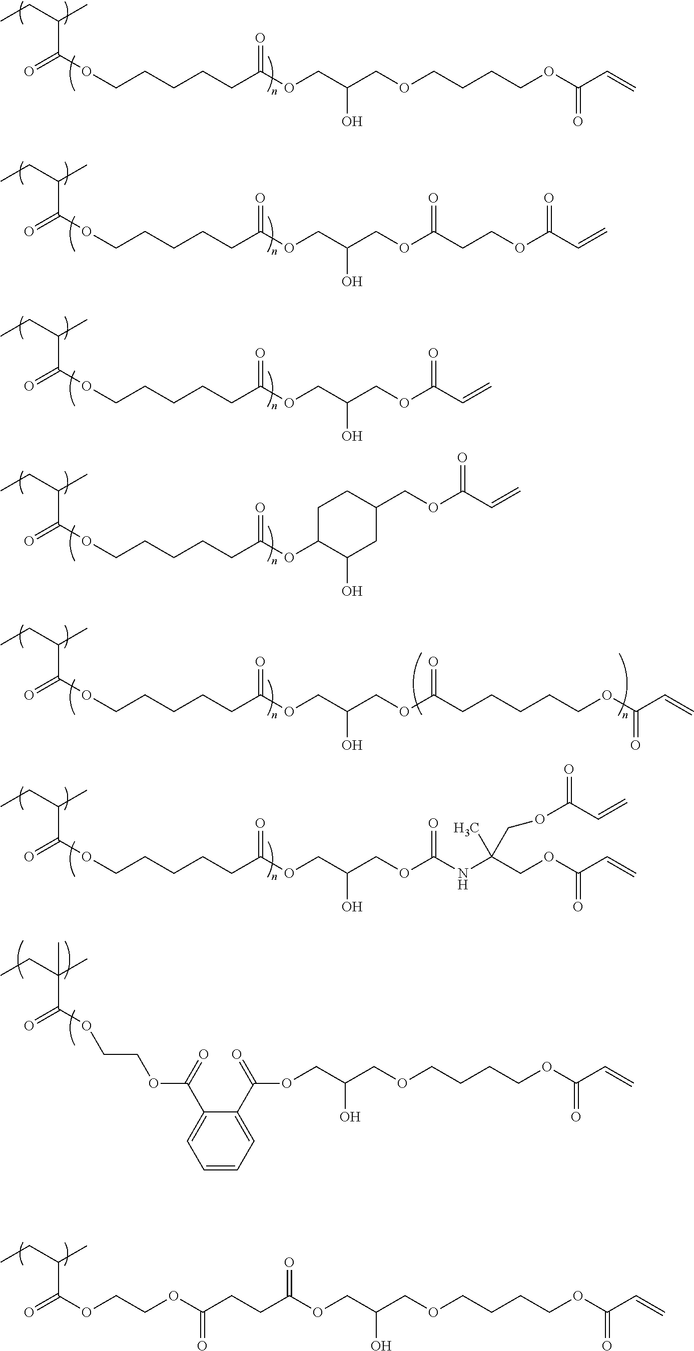

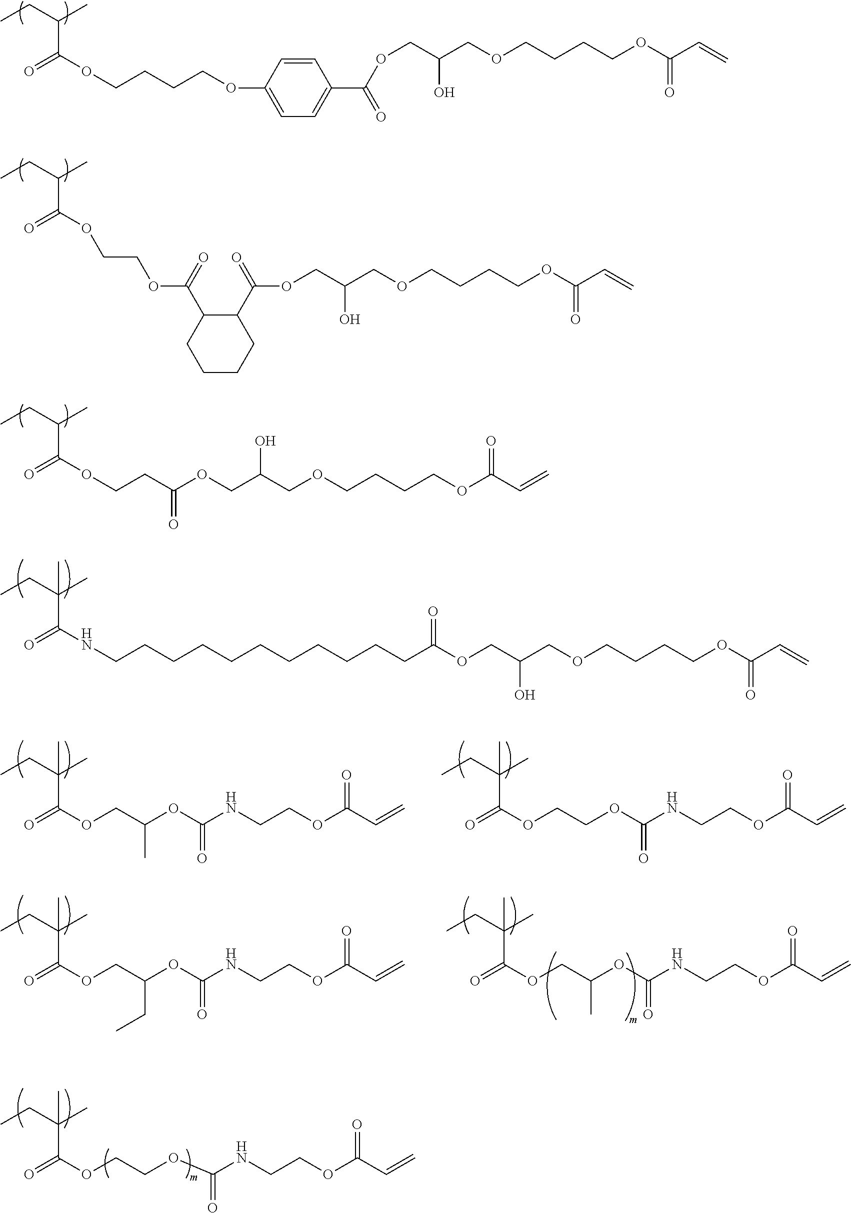

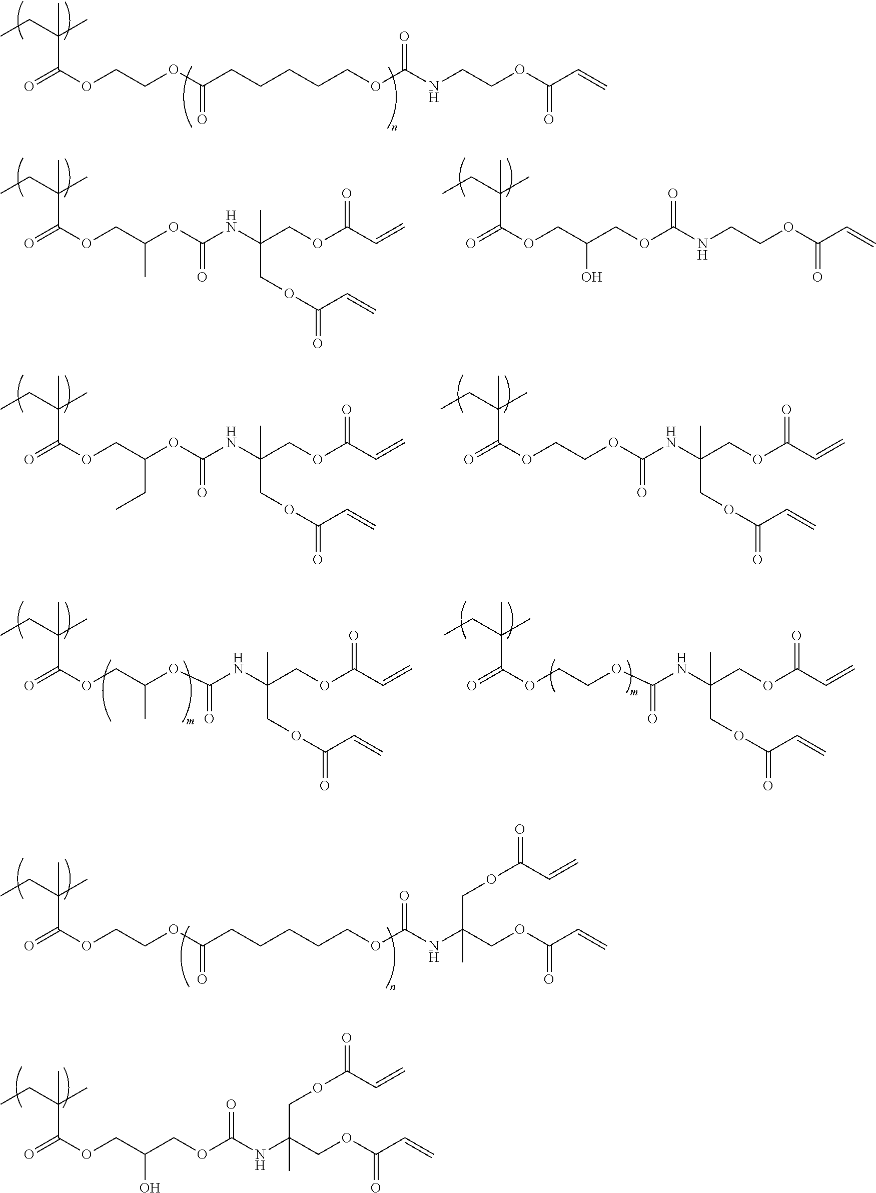

The dispersant having a curable group may have one kind of the constitutional unit represented by Formula D1, or may have two or more kinds thereof.

From the viewpoint of developability, formation of a pattern shape, dispersion stability, and deep portion curability, the content of the constitutional unit represented by Formula D1 is preferably 1% to 80% by mass, more preferably 1% to 70% by mass, and particularly preferably 1% to 60% by mass with respect to the total mass of the dispersant having a curable group.

<<Constitutional Unit Represented by Formula D4>>

From the viewpoint of dispersion stability and developability, the dispersant having a curable group preferably further has a constitutional unit represented by Formula D4.

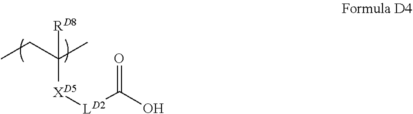

In Formula D4, R^{D8} represents a hydrogen atom or an alkyl group, XD5 represents —COO—, —CONR^{B}—, or an arylene group, where R^{B} represents a hydrogen atom, an alkyl group, or an aryl group, and L^{D2} represents an aliphatic hydrocarbon group having 1 to 10 carbon atoms, an aromatic hydrocarbon group having 6 to 20 carbon atoms, or a group in which two or more groups selected from the group consisting of aliphatic hydrocarbon groups having 1 to 10 carbon atoms and aromatic hydrocarbon groups having 6 to 20 carbon atoms are bonded to one or more groups selected from the group consisting of ether bonds and ester bonds. Furthermore, in a case where X^{D5} is an arylene group, L^{D2} may be a single bond.

R^{D8} in Formula D4 is preferably a hydrogen atom.

From the viewpoint of dispersion stability, X^{D5} in Formula D4 is preferably —COO— or —CONR^{B}— and more preferably —COO—. In a case where X^{D5} is —COO—, it is preferable that the carbon atom in —COO— is bonded to the carbon atom to which R^{D8} in Formula D4 is bonded. In a case where X^{D5} is —CONR^{B}—, it is preferable that the carbon atom in —CONR^{B}— is bonded to the carbon atom to which R^{D8} in Formula D4 is bonded.

R^{B} is preferably a hydrogen atom or an alkyl group and more preferably a hydrogen atom.

From the viewpoint of dispersion stability, L^{D2} in Formula D4 is preferably an aliphatic hydrocarbon group having 1 to 10 carbon atoms, or a group in which two or more aliphatic hydrocarbon groups having 1 to 10 carbon atoms are bonded to one or more ester bonds, still more preferably an aliphatic hydrocarbon group having 1 to 10 carbon atoms, and particularly preferably an alkylene group having 1 to 10 carbon atoms.

Preferred examples of the constitutional unit represented by Formula D4 include the following structures, and it is needless to say that the constitutional unit is not limited thereto. In the following specific examples, n represents an integer of 1 or more.

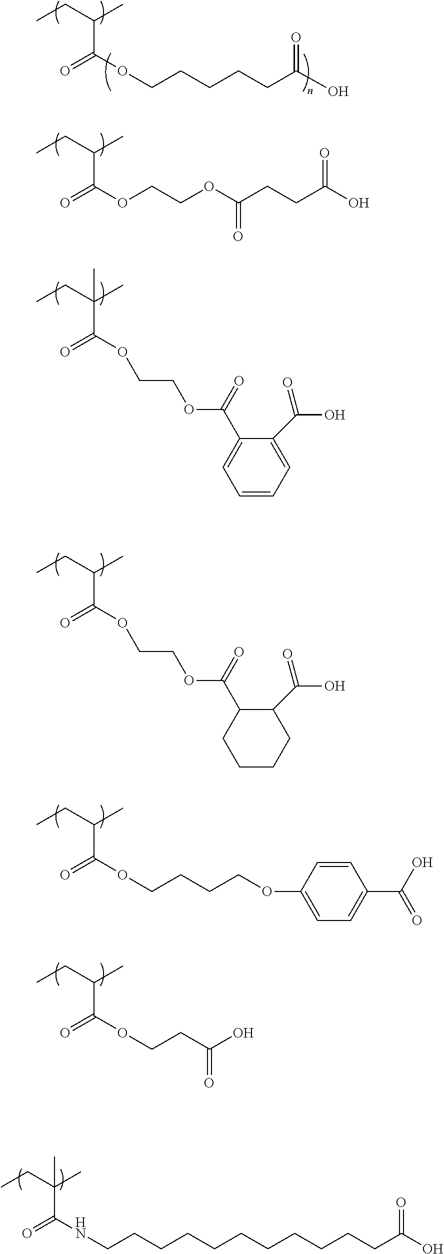

The dispersant having a curable group may have one kind of the constitutional unit represented by Formula D4, or may have two or more kinds thereof.

From the viewpoint of developability, formation of a pattern shape, and dispersion stability, the content of the constitutional unit represented by Formula D4 is preferably 20% by mass to 80% by mass, more preferably 20% by mass to 70% by mass, and particularly preferably 20% by mass to 60% by mass with respect to the total mass of the dispersant having a curable group.

<<Constitutional Unit Represented by Formula D5>>

From the viewpoint of dispersion stability, the dispersant having a curable group preferably further has a constitutional unit represented by Formula D5, and from the viewpoint of dispersion stability and developability, the dispersant having a curable group more preferably further has the constitutional unit represented by Formula D4 and a constitutional unit represented by Formula D5.

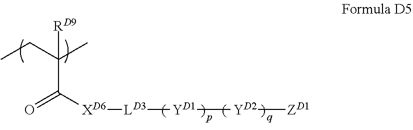

In Formula D5, R^{D9} represents a hydrogen atom or an alkyl group, X^{D6} represents an oxygen atom or NR^{C}—, where R^{C} represents a hydrogen atom, an alkyl group, or an aryl group, L^{D3} represents a divalent linking group, Y^{D1} and Y^{D2} each independently represent an alkyleneoxy group or an alkylenecarbonyloxy group, Z^{D1} represents an aliphatic hydrocarbon group having 1 to 20 carbon atoms or an aromatic hydrocarbon group having 6 to 20 carbon atoms, and p and q each independently represent an integer of 0 or more, where the value of p+q is 1 or more.

R^{D9} in Formula D5 is preferably a hydrogen atom or a methyl group and more preferably a methyl group.

From the viewpoint of dispersion stability, X^{D6} in Formula D5 is preferably an oxygen atom.

R^{C} is preferably a hydrogen atom or an alkyl group and more preferably a hydrogen atom.

From the viewpoint of dispersion stability, L^{D3} in Formula D5 is preferably a group having a total of 2 to 30 atoms, more preferably a group having a total of 3 to 20 atoms, and particularly preferably a group having a total of 4 to 10 atoms.

In addition, from the viewpoint of dispersion stability, L^{D3} in Formula D5 is preferably a group having a urethane bond or a urea bond, more preferably a group having a urethane bond, and particularly preferably a group in which an alkylene group and a urethane bond are bonded to each other.

From the viewpoint of dispersion stability, it is preferable that Y^{D1} and Y^{D2} in Formula D5 are each independently an alkylenecarbonyloxy group, and it is more preferable that Y^{D1} and Y^{D2} are different alkylenecarbonyloxy groups with each other. In addition, p pieces of Y^{D1}'s and q pieces of Y^{D2}'s may be randomly arranged, or may be arranged by forming a block of p pieces of Y^{D1}'s and a block of q pieces of Y^{D2}'s.

From the viewpoint of dispersion stability, the number of carbon atoms in the alkylenecarbonyloxy group is preferably 2 to 30, more preferably 3 to 10, and particularly preferably 5 to 8.

From the viewpoint of dispersion stability, it is preferable that p is an integer of 1 or more and q is an integer of 0 or more, it is more preferable that p is an integer of 1 or more and q is an integer of 1 or more, and it is particularly preferable that p is an integer of 3 or more and q is an integer of 3 or more.

In addition, p and q are each independently preferably 50 or less, more preferably 30 or less, and particularly preferably 20 or less.

From the viewpoint of dispersion stability, Z^{D1} in Formula D5 is preferably an aliphatic hydrocarbon group having 1 to 20 carbon atoms, more preferably an alkyl group having 4 to 20 carbon atoms, and particularly preferably an alkyl group having 6 to 20 carbon atoms.

In addition, from the viewpoint of dispersion stability, the above-described alkyl group in Z^{D1} is preferably a branched alkyl group.

Preferred examples of the constitutional unit represented by Formula D5 include the following structures, and it is needless to say that the constitutional unit is not limited thereto. In the following specific examples, n represents an integer of 1 or more, and a and b each independently represent an integer of 1 or more.

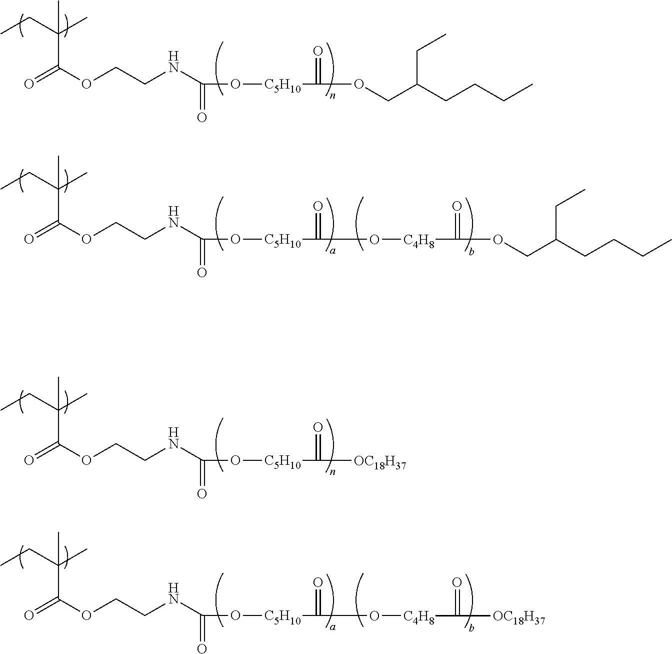

The above-described dispersant having a curable group may have one kind of the constitutional unit represented by Formula D5, or may have two or more kinds thereof.

From the viewpoint of developability, and dispersion stability, the content of the constitutional unit represented by Formula D5 is preferably 5% by mass to 80% by mass, more preferably 5% by mass to 70% by mass, and particularly preferably 5% by mass to 60% by mass with respect to the total mass of the dispersant having a curable group.

<<Constitutional Unit Represented by Formula D6>>

From the viewpoint of curability, the dispersant having a curable group preferably further has a constitutional unit represented by Formula D6, and it is more preferable that the dispersant having a curable group further has the constitutional unit represented by Formula D4 from the viewpoint of dispersion stability and developability, the constitutional unit represented by Formula D5 from the viewpoint of dispersion stability, and a constitutional unit represented by Formula D6 from the viewpoint of curability.

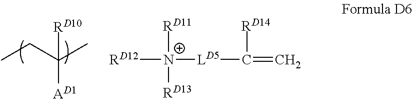

In Formula D6, R^{D10} and R^{D14} each independently represent a hydrogen atom or an alkyl group, L^{D5} represents a divalent linking group, A^{D1} represents a group including a structure in which a proton is separated from an acid group, and R^{D11}, R^{D12} and R^{D13} each independently represent an aliphatic hydrocarbon group having 1 to 20 carbon atoms or an aromatic hydrocarbon group having 6 to 20 carbon atoms.

R^{D10} and R^{D14} in Formula D6 each independently represent a hydrogen atom or a methyl group and are preferably methyl groups.

L^{D5} in Formula D6 is preferably a linear, branched, or cyclic alkylene group, an ether bond, an ester bond, a urea bond, a urethane bond, or a group of a combination of two or more of these groups, and more preferably a group represented by Formula D6-1 or Formula D6-2.

A^{D1} in Formula D6 is preferably a group including a structure in which at least one proton is separated from at least one acid group selected from the group consisting of a carboxylic acid group, a sulfonic acid group, a phosphoric acid group, a phosphinic acid group, and a phosphonic acid group, and from the viewpoint of dispersion stability, more preferably a group including a structure in which a proton is separated from carboxylic acid. In addition, A^{D1} may include two or more acid groups, or may include only one acid group. Examples of a preferred aspect thereof include an aspect in which A^{D1} includes only one acid group.

From the viewpoint of dispersion stability, R^{D11}, R^{D12} and R^{D13} in Formula D6 are each independently preferably an alkyl group having 1 to 20 carbon atoms or a phenyl group, and particularly preferably an alkyl group having 1 to 20 carbon atoms.

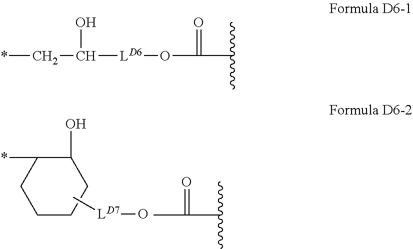

In Formulae D6-1 and D6-2, L^{D6} and L^{D7} represent a divalent linking group, * represents a bonding site with the nitrogen atom in Formula D6, and a wavy line represents a bonding site with the carbon atom to which R^{D14} in Formula D6 is bonded.

In Formula D6-1, L^{D6} is preferably an alkylene group, an ether group, or a group in which two or more of these groups are bonded. The number of carbon atoms in the alkylene group is preferably 1 to 20 and more preferably 1 to 10. In addition, the group represented by Formula D6-1 is preferably a group represented by Formula D6-3.

In Formula D6-2, L^{D7} is preferably an alkylene group. The number of carbon atoms in the alkylene group is preferably 1 to 20 and more preferably 1 to 10. In addition, it is sufficient that L^{D7} is bonded to any ring-membered atom of the cyclohexane ring, shown in Formula D6-2, to which the hydroxy group (—OH) and * are bonded. The bonding position is not particularly limited, but in a case where a ring-membered atom to which the hydroxy group is bonded in Formula D6-2 is defined as a 1-position and a ring-membered atom to which * is bonded is defined as a 2-position, it is preferable to bond with a ring-membered atom at a 5-position.

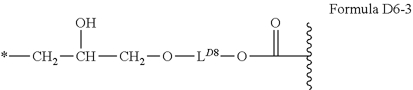

In Formula D6-3, L^{D6} and L^{D7} represent a divalent linking group, * represents a bonding site with the nitrogen atom in Formula D6, and a wavy line represents a bonding site with the carbon atom to which R^{D14} in Formula D6 is bonded.

In addition, in the structure represented by Formula D6-1, at least a part of the structure may be replaced with a structure represented by Formula D6-1′. The structure represented by Formula D6-1′ may exist as a structural isomer by, as an example, reacting a group such as a carboxylic acid and a phenolic hydroxyl group with an epoxy group.

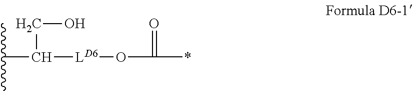

Preferred examples of the constitutional unit represented by Formula D6 include a structure in which at least one selected from the group A shown below and at least one selected from the group B shown below are combined, and it is needless to say that the constitutional unit is not limited thereto. In the following specific examples, n represents an integer of 1 or more, and Et represents an ethyl group.

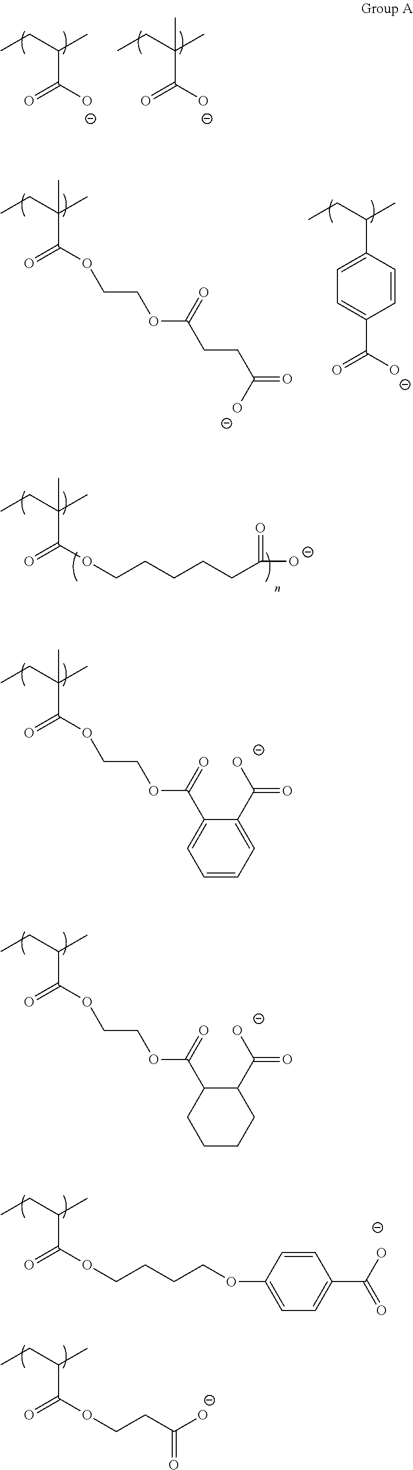

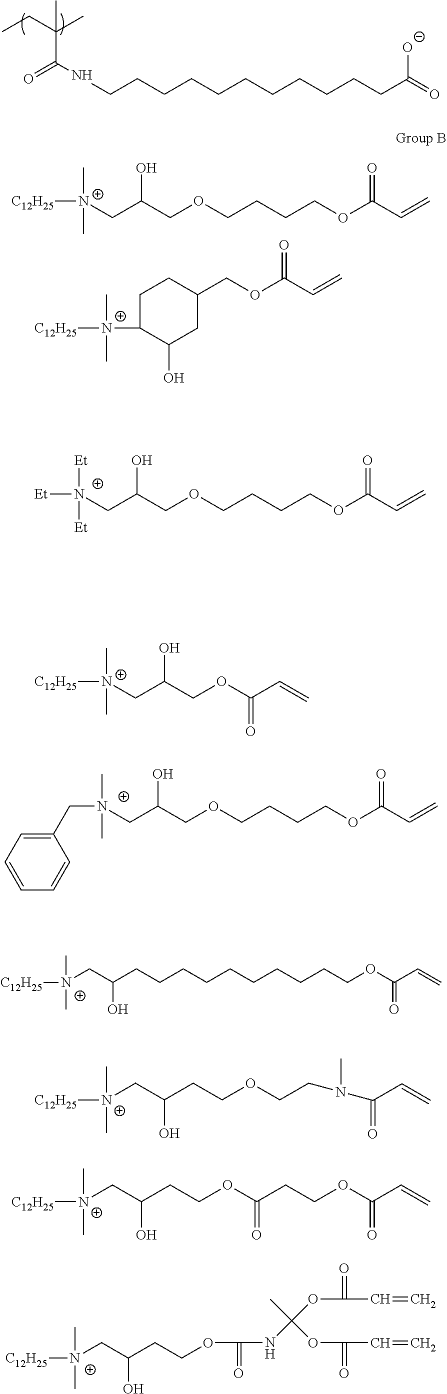

<<Other Constitutional Units>>

The dispersant having a curable group may have other constitutional units in addition to the above-described constitutional units represented by Formula D1, Formula D4, Formula D5, and Formula D6.

The other constitutional units are not particularly limited, and a known constitutional unit may be used.

The weight-average molecular weight (Mw) of the dispersant having a curable group is preferably 1,000 or more, more preferably 1,000 to 200,000, and particularly preferably 1,000 to 100,000.

From the viewpoint of deep portion curability, formation of a pattern shape, and substrate adhesiveness, the ethylenic unsaturated bonding value of the dispersant having a curable group is preferably 0.01 mmol/g to 2.5 mmol/g, more preferably 0.05 mmol/g to 2.3 mmol/g, still more preferably 0.1 mmol/g to 2.2 mmol/g, and particularly preferably 0.1 mmol/g to 2.0 mmol/g.

The ethylenic unsaturated bonding value of the dispersant having a curable group represents a molar amount of ethylenic unsaturated group per 1 g of solid content of the dispersant having a curable group. The ethylenic unsaturated bonding value is obtained by extracting a low-molecular-weight component (a) of an ethylenic unsaturated group moiety (for example, in a case where the constitutional unit represented by Formula D1 of the dispersant having a curable group has an acryloxy group, acrylic acid) from the dispersant having a curable group by an alkali treatment, measuring the content thereof by a high performance liquid chromatography (HPLC), and calculating the ethylenic unsaturated bonding value from the following expression based on the measured value. Specifically, 0.1 g of a measurement sample is dissolved in a tetrahydrofuran and methanol-mixed solution (50 mL/15 mL), 10 mL of a 4 mol/L sodium hydroxide aqueous solution is added thereto, and the mixture is reacted at 40° C. for 2 hours. The reaction solution is neutralized with 10.2 mL of a 4 mol/L methanesulfonic acid aqueous solution, the mixed solution to which 5 mL of ion exchange water and 2 mL of methanol are added is transferred to a 100 mL volumetric flask, and then the mixed solution is diluted in the volumetric flask by methanol to prepare a measurement sample for HPLC. Thereafter, the ethylenic unsaturated bonding value is measured under the following conditions. The content of the low-molecular-weight component (a) is calculated from a calibration curve of the low-molecular-weight component (a) prepared separately, and the ethylenic unsaturated bonding value is calculated from the following expression.

[Ethylenic Unsaturated Bonding Value Calculation Expression]

Ethylenic unsaturated bonding value [mmol/g]=(Content [ppm] of low-molecular-weight component (a)/Molecular weight [g/mol] of low-molecular-weight component (a)/(Weighed value [g] of liquid-prepared polymer)×(concentration of solid contents [%] of polymer solution/100)×10)

—HPLC Measurement Conditions—

Measuring equipment: Agilent-1200 (manufactured by Agilent Technologies, Inc.)

Column: Synergi 4u Polar-RP 80A manufactured by Phenomenex; 250 mm×4.60 mm (inner diameter)+guard column

Column temperature: 40° C.

Analysis time: 15 minutes

Flow rate: 1.0 mL/min (maximum liquid delivery pressure: 182 bar (18.2 MPa))

Injection amount: 5 μl

Detection wavelength: 210 nm

Eluent: tetrahydrofuran (for stabilizer-free HPLC)/buffer solution (ion exchange aqueous solution containing 0.2% by volume of phosphoric acid and 0.2% by volume of triethylamine)=55/45 (% by volume)

In the present specification, % by volume is a value at 25° C.

The coloring photosensitive composition may contain one kind of the dispersant having a curable group, or may contain two or more kinds thereof.

In a case where the coloring photosensitive composition contains a dispersant having a curable group, from the viewpoint of deep portion curability and dispersion stability, the content of the dispersant having a curable group is preferably 10% to 45% by mass, more preferably 12% to 40% by mass, and particularly preferably 14% to 35% by mass with respect to the total solid content of the coloring photosensitive composition.

In addition, from the viewpoint of deep portion curability and dispersion stability, the content of the dispersant having a curable group is preferably 20 to 60 parts by mass, more preferably 22 to 55 parts by mass, and particularly preferably 24 to 50 parts by mass with respect to 100 parts by mass of the pigment.

The method for synthesizing the dispersant having a curable group is not particularly limited, and a known or a method applying the known method can be used for the synthesis.

Examples thereof include a method of synthesizing a precursor of the above-described dispersant having a curable group by a known method, and introducing a group having an acryloyl group in the constitutional unit represented by Formula D1 by a polymer reaction. Examples of the polymer reaction include a reaction of a carboxy group in the precursor of the dispersant having a curable group with a compound having an epoxy group and an acryloyl group, and a reaction of a hydroxy group in the precursor of the dispersant having a curable group with a compound having an isocyanato group and an acryloyl group.

In addition, the above-described dispersant having a curable group is composed of different constitutional units such as a constitutional unit responsible for developability, a constitutional unit responsible for dispersibility, and a constitutional unit responsible for curability, and in order to effectively exhibit different functions, it is preferable that composition of the dispersant having a curable group is uniform.

Examples of a method for homogenizing composition of the dispersant having a curable group include a method of adding dropwise a monomer to the reaction system so as to match the consumption rates of different monomers. In general, in a case where a concentration difference is present in the reaction system by increasing the initial concentration of a monomer having a slow consumption rate in the reaction system and then adding dropwise a monomer having a high consumption rate thereto, it is possible to match the reaction rates.

[Content]

In a case where the coloring photosensitive composition according to the embodiment of the present invention includes a resin, the content of the resin in the total solid content of the coloring photosensitive composition (the total content of components corresponding to resins included in the coloring photosensitive composition) is preferably 5% to 50% by mass. The lower limit is preferably 10% by mass or more and more preferably 15% by mass or more. The upper limit is preferably 40% by mass or less, more preferably 35% by mass or less, and still more preferably 30% by mass or less. In addition, the content of the resin having an acid group, in the total solid content of the coloring photosensitive composition, is preferably 5% to 50% by mass. The lower limit is preferably 10% by mass or more and more preferably 15% by mass or more. The upper limit is preferably 40% by mass or less, more preferably 35% by mass or less, and still more preferably 30% by mass or less. In addition, from the reason that excellent developability is easily obtained, the content of the resin having an acid group in the total amount of the resin is preferably 30% by mass or more, more preferably 50% by mass or more, still more preferably 70% by mass or more, and particularly preferably 80% by mass or more. The upper limit may be 100% by mass, 95% by mass, or 90% by mass or less.

In addition, from the viewpoint of curability, developability, and film-forming property, the total content of the polymerizable compound and resin in the total solid content of the coloring photosensitive composition is preferably 10% to 65% by mass. The lower limit is preferably 15% by mass or more, more preferably 20% by mass or more, and still more preferably 30% by mass or more. The upper limit is preferably 60% by mass or less, more preferably 50% by mass or less, and still more preferably 40% by mass or less. In addition, the coloring photosensitive composition preferably contains 30 to 300 parts by mass of the resin with respect to 100 parts by mass of the polymerizable compound. The lower limit is preferably 50 parts by mass or more and more preferably 80 parts by mass or more. The upper limit is preferably 250 parts by mass or less and more preferably 200 parts by mass or less.

<Compound Having Cyclic Ether Group>

The coloring photosensitive composition according to the embodiment of the present invention can contain a compound having a cyclic ether group. Examples of the cyclic ether group include an epoxy group and an oxetanyl group. The compound having a cyclic ether group is preferably a compound having an epoxy group. Examples of the compound having an epoxy group include a compound having one or more epoxy groups in one molecule, and a compound having two or more epoxy groups in one molecule is preferable. It is preferable to have 1 to 100 epoxy groups in one molecule. The upper limit of the number of epoxy groups may be, for example, 10 or less or 5 or less. The lower limit of the number of epoxy groups is preferably 2 or more. As the compound having an epoxy group, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents thereof are incorporated herein by reference.

The compound having an epoxy group may be a low-molecular-weight compound (for example, having a molecular weight of less than 2,000, and further, a molecular weight of less than 1,000) or a high-molecular-weight compound (macromolecule) (for example, having a molecular weight of 1000 or more, and in a case of a polymer, having a weight-average molecular weight of 1,000 or more). The weight-average molecular weight of the compound having an epoxy group is preferably 200 to 100,000 and more preferably 500 to 50,000. The upper limit of the weight-average molecular weight is preferably 10,000 or less, more preferably 5,000 or less, and still more preferably 3,000 or less.

As the compound having an epoxy group, an epoxy resin can be preferably used. Examples of the epoxy resin include an epoxy resin which is a glycidyl etherified product of a phenol compound, an epoxy resin which is a glycidyl etherified product of various novolak resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3,300 g/eq, more preferably 310 to 1,700 g/eq, and still more preferably 310 to 1,000 g/eq.

Examples of a commercially available product of the compound having a cyclic ether group include EHPE 3150 (manufactured by DAICEL-ALLNEX LTD.), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

In a case where the coloring photosensitive composition according to the embodiment of the present invention contains a compound having a cyclic ether group, the content of the compound having a cyclic ether group in the total solid content of the coloring photosensitive composition is preferably 0.1% to 20% by mass. The lower limit is, for example, preferably 0.5% by mass or more, and more preferably 1% by mass or more. The upper limit is, for example, preferably 15% by mass or less and still more preferably 10% by mass or less. The compound having a cyclic ether group may be used singly or in combination of two or more kinds thereof. In a case of using two or more kinds thereof, the total content thereof is preferably within the above-described range.

<Silane Coupling Agent>

The coloring photosensitive composition according to the embodiment of the present invention may contain a silane coupling agent. According to this aspect, adhesiveness of a film to be obtained with a support can be further improved. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

The content of the silane coupling agent in the total solid content of the coloring photosensitive composition is preferably 0.1% to 5% by mass. The upper limit is preferably 3% by mass or less and more preferably 2% by mass or less. The lower limit is preferably 0.5% by mass or more and more preferably 1% by mass or more. The silane coupling agent may be used singly or in combination of two or more kinds thereof. In a case of using two or more kinds thereof, the total content thereof is preferably within the above-described range.

<Solvent>

The coloring photosensitive composition according to the embodiment of the present invention can contain a solvent. Examples of the solvent include an organic solvent. Basically, the solvent is not particularly limited as long as it satisfies solubility of the respective components or coatability of the coloring photosensitive composition. Examples of the organic solvent include an ester-based solvent, a ketone-based solvent, an alcohol-based solvent, an amide-based solvent, an ether-based solvent, and a hydrocarbon-based solvent. With regard to details thereof, reference can be made to the description in paragraph No. 0223 of WO2015/166779A, the contents of which are incorporated herein by reference. In addition, an ester-based solvent substituted with a cyclic alkyl group or a ketone-based solvent substituted with a cyclic alkyl group can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

In the present invention, a solvent having a low metal content is preferably used. For example, the metal content in the solvent is preferably 10 mass parts per billion (ppb) or less. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method for removing impurities such as a metal from the solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The solvent may include isomers (compounds having the same number of atoms and different structures). In addition, only one kind of isomers may be included, or a plurality of isomers may be included.

In the present invention, the organic solvent preferably has the content of peroxides of 0.8 mmol/L or less, and more preferably, the organic solvent does not substantially include peroxides.

The content of the solvent in the coloring photosensitive composition is preferably 10% to 95% by mass, more preferably 20% to 90% by mass, and still more preferably 30% to 90% by mass.

In addition, from the viewpoint of environmental regulation, it is preferable that the coloring photosensitive composition according to the embodiment of the present invention does not substantially contain environmentally regulated substances. In the present invention, the description “does not substantially contain environmentally regulated substances” means that the content of the environmentally regulated substances in the coloring photosensitive composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring photosensitive composition according to the embodiment of the present invention, and may be incorporated into the coloring photosensitive composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or coloring photosensitive composition produced by mixing these compounds.

<Polymerization Inhibitor>

The coloring photosensitive composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. The content of the polymerization inhibitor in the total solid content of the coloring photosensitive composition is preferably 0.0001% to 5% by mass.

<Surfactant>

The coloring photosensitive composition according to the embodiment of the present invention can contain a surfactant. As the surfactant, various surfactants such as a fluorine-based surfactant, a nonionic surfactant, a cationic surfactant, an anionic surfactant, and a silicone-based surfactant can be used. With regard to the surfactant, reference can be made to the description in paragraph Nos. 0238 to 0245 of WO2015/166779A, the contents of which are incorporated herein by reference.

In the present invention, it is preferable that the surfactant is a fluorine-based surfactant. By containing a fluorine-based surfactant in the coloring photosensitive composition, liquid characteristics (particularly, fluidity) are further improved, and liquid saving properties can be further improved. In addition, it is possible to form a film with a small thickness unevenness.

The fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the coloring photosensitive composition is also good.

Examples of the fluorine-based surfactant include surfactants described in paragraph Nos. 0060 to 0064 of JP2014-041318A (paragraph Nos 0060 to 0064 of the corresponding WO2014/017669A) and the like, and surfactants described in paragraph Nos 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as the fluorine-based surfactant used in the present invention.

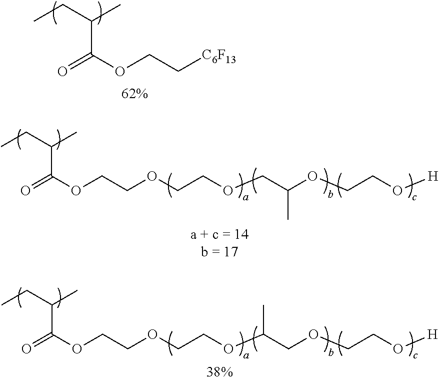

The weight-average molecular weight of the compounds is preferably 3,000 to 50,000, and is, for example, 14,000. In the compound, “%” representing the proportion of a repeating unit is mol %.

In addition, as the fluorine-based surfactant, a fluorine-containing polymer including a repeating unit having an ethylenic unsaturated group in the side chain can be used. Specific examples thereof include the compounds described in paragraph Nos. 0050 to 0090 and paragraph Nos. 0289 to 0295 of JP2010-164965A, and for example, MEGAFACE RS-101, RS-102, RS-718K, and RS-72-K manufactured by DIC Corporation. As the fluorine-based surfactant, the compounds described in paragraph Nos. 0015 to 0158 of JP2015-117327A can also be used.

Examples of the nonionic surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Japan Ltd.), NCW-101, NCW-1001, and NCW-1002 (manufactured by Wako Pure Chemical Industries, Ltd.), PIONIN D-6112, D-6112-W, and D-6315 (manufactured by Takemoto Oil & Fat Co., Ltd.), and OLFINE E1010, and SURFYNOL 104, 400, and 440 (manufactured by Nissin Chemical Industry Co., Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Silicone Co., Ltd.), and BYK307, BYK323, and BYK330 (all of which are manufactured by BYK Chemie).

The content of the surfactant in the total solid content of the coloring photosensitive composition is preferably 0.001% by mass to 5.0% by mass and more preferably 0.005% to 3.0% by mass. The surfactant may be used singly or in combination of two or more kinds thereof. In a case of using two or more kinds thereof, the total content thereof is preferably within the above-described range.

<Ultraviolet Absorber>

The coloring photosensitive composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Specific examples of the ultraviolet absorber include a compound having the following structures. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016).

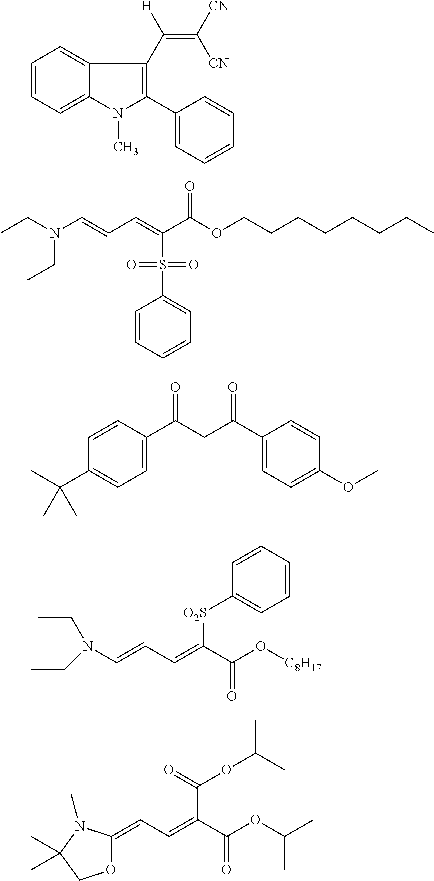

The content of the ultraviolet absorber in the total solid content of the coloring photosensitive composition is preferably 0.01% to 10% by mass and more preferably 0.01% to 5% by mass. In the present invention, the ultraviolet absorber may be used singly or in combination of two or more kinds thereof. In a case where two or more kinds thereof are used, the total content thereof is preferably within the above-described range.

<Antioxidant>

The coloring photosensitive composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitability used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation)9.

The content of the antioxidant in the total solid content of the coloring photosensitive composition is preferably 0.01% to 20% by mass and more preferably 0.3% to 15% by mass. The antioxidant may be used singly or in combination of two or more kinds thereof. In a case where two or more kinds thereof are used, the total content thereof is preferably within the above-described range.

<Oxidant>

The coloring photosensitive composition according to the embodiment of the present invention can contain an oxidant.

The oxidant may include a compound which also acts as the above-described polymerization inhibitor.

Examples of the oxidant include quinone compounds and quinodimethane compounds. As the quinone compound, benzoquinone, naphthoquinone, anthraquinone, chloranil, dichlorodicyanobenzoquinone (DDQ), and the like can be used. As the quinodimethane compound, 7,7,8,8-tetracyanoquinodimethane (TCNQ), 2-fluoro-7,7,8,8-tetracyanoquinodimethane (FTCNQ), 2,5-difluoro-7,7,8,8-tetracyanoquinodimethane (F2TCNQ), tetrafluorotetracyanoquinodimethane (F4TCNQ), and the like can be used.

It is preferable that the lowest unoccupied molecular orbital (LUMO) of the oxidant is lower than that of the pigment or dye included. The LUMO of the oxidant is preferably −3.5 eV or less, more preferably −3.8 eV or less, and most preferably −4.0 eV or less.

The content of the oxidant in the total solid content of the coloring photosensitive composition is preferably 0.0001% to 10% by mass, more preferably 0.0005% to 5% by mass, and most preferably 0.001% to 1% by mass. The oxidant may be used singly or in combination of two or more kinds thereof. In a case where two or more kinds thereof are used, the total content thereof is preferably within the above-described range.

<Other Components>

Optionally, the coloring photosensitive composition according to the embodiment of the present invention may further contain a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the coloring photosensitive composition according to the embodiment of the present invention may contain a potential antioxidant. Examples of the potential antioxidant include a compound in which a site functioning as an antioxidant is protected by a protecting group, and the protecting group is eliminated by heating the compound at 100° C. to 250° C. or heating the compound at 80° C. to 200° C. in the presence of an acid or basic catalyst so that the compound functions as an antioxidant. Examples of the potential antioxidant include the compounds described in WO2014/021023A, WO2017/030005A, and JP2017-008219A. Examples of a commercially available product of the potential antioxidant include ADEKA ARKLS GPA-5001 (manufactured by ADEKA Corporation).

In addition, in order to adjust the refractive index of the film to be obtained, the coloring photosensitive composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure, and in this case, the core portion may be hollow.

In addition, the coloring photosensitive composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034, 0058, and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

For example, in a case where a film is formed by coating, the viscosity (25° C.) of the coloring photosensitive composition according to the embodiment of the present invention is preferably 0.05 to 100 mPa·s. The lower limit is more preferably 0.1 mPa·s or more and still more preferably 0.2 mPa·s or more. The upper limit is more preferably 10 mPa·s or less, still more preferably 5 mPa·s or less, and particularly preferably 3 mPa·s or less.

In the coloring photosensitive composition according to the embodiment of the present invention, the content of free metal which is not bonded to or coordinated with a pigment or the like is preferably 100 ppm or less, more preferably 50 ppm or less, and still more preferably 10 ppm or less, it is particularly preferable to not contain the free metal substantially. In the present specification, ppm is based on mass. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described free metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the coloring photosensitive composition according to the embodiment of the present invention, the content of free halogen which is not bonded to or coordinated with a pigment or the like is preferably 100 ppm or less, more preferably 50 ppm or less, and still more preferably 10 ppm or less, it is particularly preferable to not contain the free halogen substantially. Examples of halogen include F, Cl, Br, I, and anions thereof. Examples of a method for reducing free metals and halogens in the coloring photosensitive composition include washing with ion exchange water, filtration, ultrafiltration, and purification with an ion exchange resin.

It is also preferable that the coloring photosensitive composition according to the embodiment of the present invention does not substantially include terephthalic acid ester.

<Storage Container>

A storage container of the coloring photosensitive composition according to the embodiment of the present invention is not particularly limited, and a known storage container can be used. In addition, as the storage container, it is also preferable to use a multilayer bottle having an inner wall constituted with six layers from six kinds of resins or a bottle having a 7-layer structure from 6 kinds of resins for the purpose of suppressing incorporation of impurities into raw materials or coloring photosensitive compositions. Examples of such a container include the containers described in JP2015-123351A.

In addition, as a storage container used for the coloring photosensitive composition according to the embodiment of the present invention or a composition used for producing an image sensor, for the purpose of preventing metal elution from the container inner wall, improving storage stability of the composition, and suppressing the alteration of components, it is also preferable that the inner wall of the storage container is formed of glass, stainless steel, or the like.

Storage conditions of the coloring photosensitive composition according to the embodiment of the present invention is not particularly limited, and a known method in the related art can be used. In addition, a method described in JP2016-180058A can be used.

<Method for Preparing Coloring Photosensitive Composition>

The coloring photosensitive composition according to the embodiment of the present invention can be prepared by mixing the above-described components with each other. In the preparation of the coloring photosensitive composition, all the components may be dissolved and/or dispersed at the same time in a solvent to prepare the coloring photosensitive composition, or the respective components may be appropriately left in two or more solutions or dispersion liquids and mixed to prepare the coloring photosensitive composition upon use (during coating), as desired.

In addition, in the preparation of the coloring photosensitive composition, a process for dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

It is preferable that, in the preparation of the coloring photosensitive composition, the coloring photosensitive composition is filtered through a filter for the purpose of removing foreign matters, reducing defects, or the like. As the filter, any filters that have been used in the related art for filtration use and the like may be used without particular limitation. Examples of the filter include filters formed of materials including, for example, a fluororesin such as polytetrafluoroethylene (PTFE), a polyamide-based resin such as nylon (for example, nylon-6 and nylon-6,6), and a polyolefin resin (including a polyolefin resin having a high-density or an ultrahigh molecular weight) such as polyethylene and polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha., Ltd., Nihon Entegris K. K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

(Film)

The film according to an embodiment of the present invention is a film formed from the coloring photosensitive composition according to the embodiment of the present invention. The film according to the embodiment of the present invention can be used for a color filter, a near-infrared transmission filter, a near-infrared cut filter, a black matrix, a light-shielding film, a refractive index adjusting film, and the like. For example, the film according to an embodiment of the present invention can be preferably used as a colored layer of a color filter.

The thickness of the film according to the embodiment of the present invention can be appropriately adjusted according to the purpose. For example, the thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

<Method for Producing Film>

The film according to the embodiment of the present invention can be produced through a step of applying the coloring photosensitive composition according to the embodiment of the present invention on a support. The method for producing the film according to the embodiment of the present invention preferably further includes a step of forming a pattern (pixel). A photolithography method is preferable as a method of forming a pattern (pixel).

Pattern formation by the photolithography method preferably includes a step of forming a coloring photosensitive composition layer on a support using the coloring photosensitive composition according to the embodiment of the present invention, a step of patternwise exposing the coloring photosensitive composition layer, and a step of removing an unexposed area of the coloring photosensitive composition layer by development to form a pattern (pixel). A step (pre-baking step) of baking the coloring photosensitive composition layer and a step (post-baking step) of baking the developed pattern (pixel) may be provided, optionally.

[Step of Forming Coloring Photosensitive Composition Layer]

In the step of forming a coloring photosensitive composition layer, the coloring photosensitive composition layer is formed on a support using the coloring photosensitive composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of materials, or planarize the surface of the substrate.

In the step of forming the coloring photosensitive composition layer, the coloring photosensitive composition is applied to a support.

As a method for applying the coloring photosensitive composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprint method. A method for applying the ink jet is not particularly limited, and examples thereof include a method described in “Extension of Use of Ink Jet-Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring photosensitive composition, reference can be made to the description in WO2017/030174A and WO2017/018419A, the contents of which are incorporated herein by reference.

The coloring photosensitive composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

[Exposing Step]

Next, the coloring photosensitive composition layer is patternwise exposed (exposing step). For example, the coloring photosensitive composition layer can be subjected to patternwise exposure by performing exposure using a stepper exposure machine or a scanner exposure machine through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50,000,000 W/m² or more, more preferably 100,000,000 W/m² or more, and still more preferably 200,000,000 W/m² or more. In addition, the upper limit of the maximum instantaneous illuminance is preferably 1,000,000,000 W/m² or less, more preferably 800,000,000 W/m² or less, and still more preferably 500,000,000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure dose) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

[Developing Step]

Next, the unexposed area of the coloring photosensitive composition layer is removed by development to form a pattern (pixel). The removal of the unexposed area of the coloring photosensitive composition layer by development can be carried out using a developer. Thus, the coloring photosensitive composition layer of the unexposed area in the exposing step is eluted into the developer, and as a result, only a photocured portion remains. As the developer, an organic alkaline developer causing no damage on a base of element, circuit, or the like is desirable. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

As the developer, an aqueous alkaline solution (alkaline developer) obtained by diluting an alkali agent with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the aqueous alkaline solution is preferably 0.001% to 10% by mass and more preferably 0.01% to 1% by mass. In addition, the developer may further contain a surfactant. Examples of the surfactant include the surfactants described above, and the surfactant is preferably a nonionic surfactant. From the viewpoint of transportation, storage, and the like, the developer may be first produced as a concentrated liquid and then diluted to a concentration required upon use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring photosensitive composition layer after development while rotating the support on which the coloring photosensitive composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a treatment after development in order to complete curing, and the heating temperature is preferably, for example, 100° C. to 240° C. and more preferably 200° C. to 240° C. The post-baking can be performed continuously or batchwise by using a heating unit such as a hot plate, a convection oven (hot-air circulating dryer), and a high-frequency heater so that the film after development satisfies the conditions.

In a case of carrying out the additional exposure treatment, light used for the exposure is preferably light having a wavelength of 400 nm or less. In addition, the additional exposure treatment may be carried out by the method described in KR10-2017-0122130A.

The width of the pixel is preferably 0.5 to 20.0 The lower limit is preferably 1.0 μm or more and more preferably 2.0 μm or more. The upper limit is preferably 15.0 μm or less and more preferably 10.0 μm or less.

The Young's modulus of the pixel is preferably 0.5 to 20 GPa and more preferably 2.5 to 15 GPa.

It is preferable that the pixel has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness can be measured, for example, using an atomic force microscope (AFM) Dimension 3100 manufactured by Veeco Instruments, Inc.

In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.).

It is desired that the volume resistivity value of the pixel is high. Specifically, the volume resistivity value of the pixel is preferably 10⁹ Ω×cm or more and more preferably 10¹¹ Ω×cm or more. The upper limit is not specified, but is, for example, preferably 10¹⁴ Ω×cm or less. The volume resistivity value of the pixel can be measured, for example, using an ultra-high resistance meter 5410 (manufactured by Advantest Corporation).

(Color Filter)

The color filter according to an embodiment of the present invention is a color filter formed from the coloring photosensitive composition according to the embodiment of the present invention. It is preferable that the color filter according to the embodiment of the present invention has the film according to the embodiment of the present invention. In a case where the film according to the embodiment of the present invention is used for a color filter, as the pigment, it is preferable to use a chromatic pigment.

For example, the film thickness of the color filter according to the embodiment of the present invention is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more. The color filter according to the embodiment of the present invention can be used for a solid-state imaging element such as a charge coupled device (CCD) and a complementary metal-oxide semiconductor (CMOS), an image display device, or the like.

In addition, the color filter according to the embodiment of the present invention may include the film according to the embodiment of the present invention and a protective layer. The protective layer and the film according to the embodiment of the present invention may be in contact with each other, another layer may be provided therebetween, or a gap may be provided therebetween. By including the protective layer, various functions such as oxygen shielding, low reflection, hydrophilicity/hydrophobicity, and shielding of light (ultraviolet rays, near-infrared rays, infrared rays, and the like) having a specific wavelength can be imparted. The thickness of the protective layer is preferably 0.01 to 10 μm and still more preferably 0.1 to 5 μm. Examples of a method for forming the protective layer include a method of forming the protective layer by applying a resin composition dissolved in a solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluorine resin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the solvent contained in the resin composition, a known solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic particles, an absorber of a specific wavelength (for example, ultraviolet rays, near-infrared rays, infrared rays, and the like), a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. For example, as an ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. As the infrared absorber, for example, a cyclic tetrapyrrole coloring agent, an oxocarbon coloring agent, a cyanine coloring agent, a quaterrylene coloring agent, a naphthalocyanine coloring agent, a nickel complex coloring agent, a copper ion coloring agent, an iminium coloring agent, a subphthalocyanine coloring agent, a xanthene coloring agent, an azo coloring agent, a dipyrromethene coloring agent, a pyrrolopyrrole coloring agent, or the like can be used. With regard to details thereof, reference can be made to the description in paragraph Nos. 0020 to 0072 of JP2018-054760A, JP2009-263614A, and WO2017/146092A, the contents of which are incorporated herein by reference. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

(Solid-State Imaging Element)

The solid-state imaging element according to an embodiment of the present invention includes the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device protective film formed of silicon nitride or the like, which is formed to cover the entire surface of the light-shielding film and the light receiving portion of the photodiodes, on the light-shielding film; and have a color filter on the device protective film. Furthermore, the solid-state imaging element may also be configured, for example, such that it has a light collecting unit (for example, a microlens, which is the same hereinafter) on a device protective film under a color filter (a side closer to the substrate), or has a light collecting unit on a color filter. In addition, the color filter may have a structure in which each coloring pixel is embedded in a space partitioned in, for example, a lattice shape by a partition wall. The partition wall in this case preferably has a low refractive index for each coloring pixel. Examples of an imaging device having such a structure include the devices described in JP2012-227478A, JP2014-179577A, and WO2018/043654A. An imaging device including the solid-state imaging element according to the embodiment of the present invention can also be used as a vehicle camera, a monitoring camera, and the like, in addition to a digital camera or electronic equipment (mobile phones or the like) having an imaging function.

(Image Display Device)

The image display device according to an embodiment of the present invention includes the film according to the embodiment of the present invention. Examples of the image display device include a liquid crystal display device or an organic electroluminescence display device. The definitions of image display devices or the details of the respective image display devices are described in, for example, “Electronic Display Device (written by Akio Sasaki, Kogyo Chosakai Publishing Co., Ltd., published in 1990)”, “Display Device (written by Sumiaki Ibuki, Sangyo Tosho Co., Ltd., published in 1989)”, and the like. In addition, the details of a liquid crystal display device can be found in, for example, “Next-Generation Liquid Crystal Display Techniques (edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Preparation of Dispersion Liquid (1)>

A pigment (G pigment (green pigment): 8.29 parts by mass, Y pigment (yellow pigment): 2.07 parts by mass) shown in the following table, a colorless pigment derivative A1 shown in the following table, a colored pigment derivative A2 shown in the following table, a dispersant shown in the following table, and 71.92 parts by mass of propylene glycol monomethyl ether acetate (PGMEA) shown in the following tables were mixed. Thereafter, 230 parts by mass of zirconia beads having a diameter of 0.3 mm were added thereto to perform a dispersion treatment for 5 hours using a paint shaker, and the beads were separated by filtration to produce a dispersion liquid. The numerical values indicating the contents described in the following table are parts by mass. For example, in the description of PG36 PG58 (50/50) in the column of “G pigment” in the dispersion liquid G-18, it indicates that PG36 and PG38 were used in a ratio of 50/50 (mass ratio) as the G pigment.

In addition, in the column of “(A1)/(A1+A2) (% by mass)”, the “content (% by mass) of the pigment derivative A1 to the total mass of the pigment derivative A1 and the pigment derivative A2” is described, and in the column of “(A1+A2)/pigment”, the “total content (part by mass) of the pigment derivative A1 and the pigment derivative A2 with respect to 100 parts by mass of the pigment” is described, respectively.

In addition, in Table 2, the description of “-” indicates that the corresponding compound is not contained.

TABLE 2

| | | | | Derivative | | | | | | | | |
|---|---|---|---|---|---|---|---|---|---|---|---|---|
| | | | | Colorless | | | Colored | | | (A1 + A2) / | | |
| | | | | pigment | | | pigment | Part | (A1) / | pigment | Dispersant | |
| | | Pigment | | derivative | | Part by | derivative | by | (A1 + A2) | (part by | | Part by |
| | | G pigment | Y pigment | A1 | Absorption | mass | A2 | mass | (% by mass) | mass) | Type | mass |
| Dispersion | G-1 | PG36 | PY150 | (A1)-1 | A | 0.5 | (A2)-1 | 0.5 | 50 | 10 | P-1 | 30 |
| liquid | G-2 | PG58 | PY150 | (A1)-1 | A | 0.5 | (A2)-1 | 0.5 | 50 | 10 | P-1 | 30 |
| | G-3 | PG58 | PY185 | (A1)-1 | A | 0.5 | (A2)-1 | 0.5 | 50 | 10 | P-1 | 30 |
| | G-4 | PG36 | PY185 | (A1)-1 | A | 0.5 | (A2)-1 | 0.5 | 50 | 10 | P-1 | 30 |
| | G-5 | PG36 | PY185 | (A1)-1 | A | 0.1 | (A2)-1 | 0.9 | 10 | 10 | P-1 | 30 |
| | G-6 | PG36 | PY185 | (A1)-1 | A | 0.3 | (A2)-1 | 0.7 | 30 | 10 | P-1 | 30 |
| | G-7 | PG36 | PY185 | (A1)-1 | A | 0.9 | (A2)-1 | 0.1 | 90 | 10 | P-1 | 30 |
| | G-8 | PG36 | PY185 | (A1)-1 | A | 0.3 | (A2)-1 | 0.3 | 50 | 6 | P-1 | 30 |
| | G-9 | PG36 | PY185 | (A1)-1 | A | 1.3 | (A2)-1 | 1.3 | 50 | 25 | P-1 | 30 |
| | G-10 | PG36 | PY185 | (A1)-10 | A | 0.5 | (A2)-2 | 0.5 | 50 | 10 | P-1 | 30 |
| | G-11 | PG36 | PY185 | (A1)-11 | A | 0.5 | (A2)-2 | 0.5 | 50 | 10 | P-1 | 30 |
| | G-12 | PG36 | PY185 | (A1)-12 | A | 0.5 | (A2)-2 | 0.5 | 50 | 10 | P-1 | 30 |
| | G-13 | PG36 | PY185 | (A1)-12 | A | 0.5 | (A2)-2 | 0.5 | 50 | 10 | P-2 | 30 |
| | G-14 | PG36 | PY185 | (A1)-14 | A | 0.5 | (A2)-4 | 0.5 | 50 | 10 | P-1 | 30 |
| | G-15 | PG36 | PY185 | (A1)-15 | A | 0.5 | (A2)-5 | 0.5 | 50 | 10 | P-1 | 30 |
| | G-16 | PG36 | PY185 | (A1)-16 | B | 0.5 | (A2)-6 | 0.5 | 50 | 10 | P-1 | 30 |
| | G-17 | PG36 | PY185 | (A1)-17 | A | 0.5 | (A2)-7 | 0.5 | 50 | 10 | P-1 | 30 |
| | G-18 | PG36 | PY185 | (A1)-17 | A | 0.5 | (A2)-8 | 0.5 | 50 | 10 | P-1 | 30 |
| | | PG58 | | | | | | | | | | |
| | | (50/50) | | | | | | | | | | |
| | G-19 | PG36 | PY150 | (A1)-17 | A | 0.5 | (A2)-9 | 0.5 | 50 | 10 | P-1 | 30 |
| | | | PY185 | | | | | | | | | |
| | | | (50/50) | | | | | | | | | |
| | G-20 | PG36 | PY185 | (A1)-20 | C | 0.5 | (A2)-10 | 0.5 | 50 | 10 | P-1 | 30 |
| | G-21 | PG36 | PY185 | (A1)-21 | A | 0.5 | (A2)-11 | 0.5 | 50 | 10 | P-1 | 30 |
| | G-22 | PG36 | PY185 | (A1)-22 | A | 0.5 | (A2)-12 | 0.5 | 50 | 10 | P-1 | 30 |
| | G-23 | PG36 | PY185 | (A1)-23 | A | 0.5 | (A2)-13 | 0.5 | 50 | 10 | P-1 | 30 |
| | G-24 | PG36 | PY185 | (A1)-24 | A | 0.5 | (A2)-14 | 0.5 | 50 | 10 | P-1 | 30 |
| | G-25 | PG36 | PY185 | (A1)-35 | C | 0.5 | (A2)-16 | 0.5 | 50 | 10 | P-1 | 30 |
| | G-26 | PG36 | PY185 | (A1)-36 | A | 0.5 | (A2)-18 | 0.5 | 50 | 10 | P-1 | 30 |
| | G-27 | PG36 | PY185 | (A1)-37 | A | 0.5 | (A2)-18 | 0.5 | 50 | 10 | P-2 | 30 |
| | G-28 | PG36 | PY185 | (A1)-38 | A | 0.5 | (A2)-18 | 0.5 | 50 | 10 | P-3 | 30 |
| | G-29 | PG36 | PY185 | (A1)-39 | A | 0.5 | (A2)-19 | 0.5 | 50 | 10 | P-3 | 30 |
| | G-30 | PG36 | PY185 | (A1)-1 | A | 0.5 | (A2)-20 | 0.5 | 50 | 10 | P-3 | 30 |
| | | | | (A1)-39 | | | | | | | | |
| | | | | (50/50) | | | | | | | | |
| | G-31 | PG36 | PY185 | (A1)-41 | A | 0.5 | (A2)-21 | 0.5 | 50 | 10 | P-3 | 30 |
| | G-32 | PG36 | PY185 | (A1)-42 | A | 0.5 | (A2)-22 | 0.5 | 50 | 10 | P-3 | 30 |
| | G-33 | PG36 | PY185 | (A1)-1 | A | 0.06 | (A2)-1 | 0.06 | 50 | 1 | P-1 | 30 |
| | G-34 | PG36 | PY185 | (A1)-1 | A | 0.03 | (A2)-1 | 0.03 | 50 | 0.6 | P-1 | 30 |
| | G-35 | PG36 | PY185 | (A1)-1 | A | 2 | (A2)-1 | 2 | 50 | 39 | P-1 | 30 |
| | G-r1 | PG36 | PY185 | — | — | — | (A2)-r1 | 1.0 | — | 10 | P-1 | 30 |
| | G-r2 | PG36 | PY185 | (A1)-r1 | B | 1.0 | — | — | — | 10 | P-1 | 30 |

Details of the materials indicated by the abbreviations in the above table are as follows.

[G Pigment]
PG36: C. I. Pigment Green 36
PG58: C. I. Pigment Green 58

[Y Pigment]
PY150: C. I. Pigment Yellow 150
PY185: C. I. Pigment Yellow 185

[Colorless Pigment Derivative A1]
(A1)-1: compound having the same structure as the compound (A1)-1 described in the specific example of the colorless pigment derivative A1 described above. In addition, (A1)-10 and the like are also compounds having the same structures as the compounds (A1)-10 and the like in the above-described specific examples.
(A1)-r1: compound having the following structure

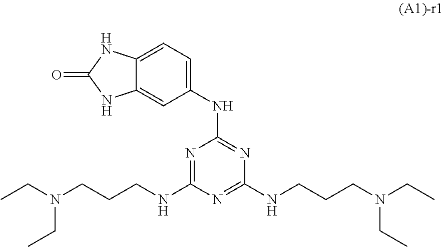 [SMILES: CCN(CC)CCCNc1nc(NCCCN(CC)CC)nc(Nc2ccc3[nH]c(=O)[nH]c3c2)n1]

[Colored Pigment Derivative A2]
(A2)-1: compound having the same structure as the compound (A2)-1 described in the specific example of the colored pigment derivative A2 described above. In addition, (A2)-2 and the like are also compounds having the same structures as the compounds (A2)-2 and the like in the above-described specific examples.
(A2)-r1: compound having the following structure

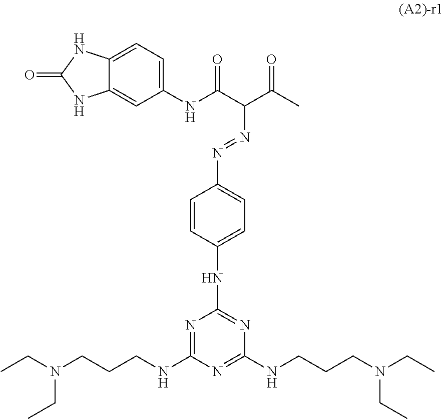 [SMILES: CCN(CC)CCCNc1nc(NCCCN(CC)CC)nc(Nc2ccc(/N=N/C(C(C)=O)C(=O)Nc3ccc4[nH]c(=O)[nH]c4c3)cc2)n1]

[Dispersant]
P-1: 30% by mass of propylene glycol monomethyl ether acetate (PGMEA) solution of a resin having the following structure. The numerical value described together with the main chain indicates a molar ratio, and the numerical value described together with the side chain indicates the number of repeating units. Mw=20,000.

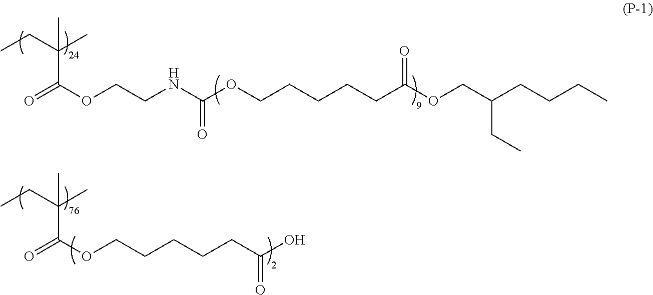

P-2: 30% by mass of PGMEA solution of a resin having the following structure. The numerical value described together with the main chain indicates a molar ratio, and the numerical value described together with the side chain indicates the number of repeating units. Mw=28,000. In the formula, r=15, s=63, t=5, u=17, and n=9.

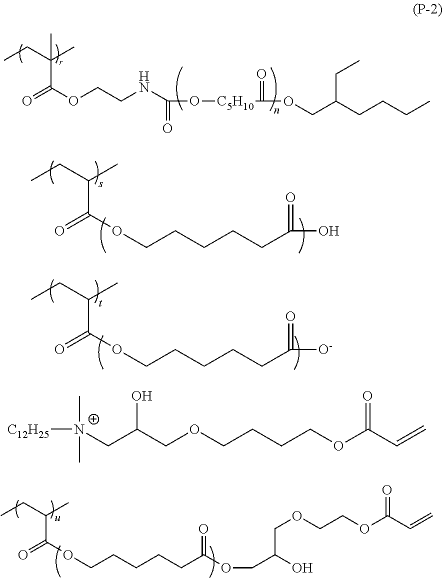

P-3: 30% by mass of PGMEA solution of a resin having the following structure. The numerical value described together with the main chain indicates a molar ratio, and the numerical value described together with the side chain indicates the number of repeating units. Mw=22,000.

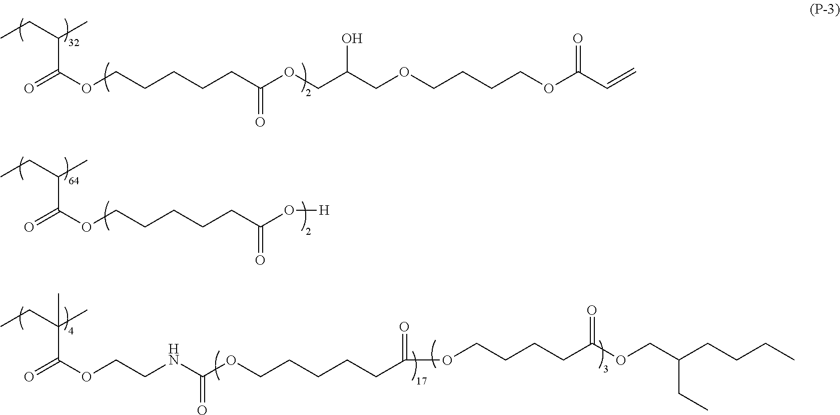

[Molar Light Absorption Coefficient of Colorless Pigment Derivative A1]

The maximum value (εmax) of the molar light absorption coefficient of the colorless pigment derivative A1 in a wavelength range of 400 to 700 nm was measured according to the following method, and evaluated according to the following evaluation standard. The evaluation results are shown in the column “Absorption” of Table 2.

εmax of each compound was measured as follows.

20 mg of each compound was dissolved in 200 mL of methanol, and methanol was added to 2 mL of this solution so as to be 50 mL. The absorbance of this solution was measured in a wavelength range of 200 to 800 nm using Cary 5000 UV-Vis-NIR spectrophotometer (manufactured by Agilent Technologies, Inc.) to calculate max at a wavelength of 400 to 700 nm.

—Evaluation Standard—

A: maximum value (εmax) of a molar light absorption coefficient in a wavelength range of 400 to 700 nm was 100 L·mol⁻¹·cm⁻¹ or less.

B: maximum value (εmax) of a molar light absorption coefficient in a wavelength range of 400 to 700 nm was more than 100 L·mol⁻¹·cm⁻¹ and 1000 L·mol⁻¹·cm⁻¹ or less.

C: maximum value (εmax) of a molar light absorption coefficient in a wavelength range of 400 to 700 nm was more than 1000 L·mol⁻¹·cm⁻¹ and 3000 L·mol⁻¹·cm⁻¹ or less.

D: maximum value (εmax) of a molar light absorption coefficient in a wavelength range of 400 to 700 nm was more than 3000 L·mol⁻¹·cm⁻¹.

[Molar Light Absorption Coefficient of Colored Pigment Derivative A2]

With regard to each of the above-described (A2)-1 to (A2)-22 and (A2)-r1, the maximum value (εmax) of the molar light absorption coefficient in a wavelength range of 400 to 700 nm was measured.

In each compound, the maximum value (εmax) of the molar light absorption coefficient in a wavelength range of 400 to 700 nm was more than 3,000 L·mol⁻¹·cm⁻¹.

εmax of each compound was measured by the same method as in the above-described molar light absorption coefficient of the colorless pigment derivative A1, and evaluated according to the following evaluation standard. The evaluation results are shown in the following table.

—Evaluation Standard—

A: εmax was 5000 L·mol⁻¹·cm⁻¹ or more.

B: εmax was 4000 L·mol⁻¹·cm⁻¹ or more and less than 5000 L·mol⁻¹·cm⁻¹ or more.

C: εmax was more than 3000 L·mol⁻¹·cm⁻¹ or more and less than 4000 L·mol⁻¹·cm⁻¹ or more.

TABLE 3

| | εmax evaluation result |
|---|---|
| (A2)-1 | C |
| (A2)-2 | B |
| (A2)-3 | B |
| (A2)-4 | A |
| (A2)-5 | A |
| (A2)-6 | A |
| (A2)-7 | C |
| (A2)-8 | B |
| (A2)-9 | A |
| (A2)-10 | B |
| (A2)-11 | A |
| (A2)-12 | A |
| (A2)-13 | A |
| (A2)-14 | A |
| (A2)-15 | B |
| (A2)-16 | A |
| (A2)-17 | B |
| (A2)-18 | A |
| (A2)-19 | A |
| (A2)-20 | A |
| (A2)-21 | A |
| (A2)-22 | A |
| (A2)-23 | A |
| (A2)-24 | A |
| (A2)-r1 | A |

<Preparation of Dispersion Liquid (2)>

A pigment shown in the following table, 0.5 parts by mass of the colorless pigment derivative (A1)-1, 0.5 parts by mass of the colored pigment derivative (A2)-1, 15 parts by mass of the dispersant P-3 (30% by mass of PGMEA solution), and 73.64 parts by mass of PGMEA solvent were mixed. Thereafter, 230 parts by mass of zirconia beads having a diameter of 0.3 mm were added thereto to perform a dispersion treatment for 5 hours using a paint shaker, and the beads were separated by filtration to produce a dispersion liquid. The numerical values indicating the contents described in the following table are parts by mass.

In the preparation of G-r3 and G-r4, the content of the colorless pigment derivative (A1)-1 was changed from 0.5 parts by mass to 0 part by mass (not contained), and the content of the colored pigment derivative (A2)-1 was changed from 0.5 parts by mass to 1.0 part by mass.

In addition, in the column of “(A1)/(A1+A2) (% by mass)”, the “content (% by mass) of the pigment derivative A1 to the total mass of the pigment derivative A1 and the pigment derivative A2” is described, and in the column of “(A1+A2)/pigment”, the “total content (part by mass) of the pigment derivative A1 and the pigment derivative A2 with respect to 100 parts by mass of the pigment” is described, respectively.

TABLE 4

| | | Pigment | | | | | | (A1) / | (A1 + A2) / |
|---|---|---|---|---|---|---|---|---|---|
| | | | Part by | | Part by | | Part by | (A1 + A2) | pigment |
| | | Pigment 1 | mass | Pigment 2 | mass | Pigment 3 | mass | (% by mass) | (part by mass) |
| Dispersion | G-36 | PG36 | 7.3 | PY185 | 0.4 | PY150 | 2.7 | 50 | 10 |
| liquid | G-37 | PG36 | 7.3 | PY185 | 0.8 | PY150 | 2.3 | 50 | 10 |
| | G-38 | PG36 | 7.3 | PY185 | 1.1 | PY150 | 2.0 | 50 | 10 |
| | G-39 | PG36 | 7.3 | PY185 | 1.4 | PY150 | 1.7 | 50 | 10 |
| | G-40 | PG58 | 7.3 | PY185 | 0.4 | PY231 | 2.7 | 50 | 10 |
| | G-41 | PG58 | 7.3 | PY185 | 1.4 | PY231 | 1.7 | 50 | 10 |
| | G-42 | PG36 | 7.3 | PY185 | 2.7 | PY129 | 0.4 | 50 | 10 |
| | G-43 | PG36 | 7.3 | PY185 | 1.7 | PY129 | 1.4 | 50 | 10 |
| | G-r3 | PG36 | 7.3 | PY185 | 0.4 | PY150 | 2.7 | — | 10 |
| | G-r4 | PG58 | 7.3 | PY185 | 0.4 | PY231 | 2.7 | — | 10 |

Details of the materials other than those described above, which are indicated by the abbreviations in the above table, are as follows.

[Y Pigment]
PY129: C. I. Pigment Yellow 129
PY231: C. I. Pigment Yellow 231

### Examples 1 to 50 and Comparative Examples 1 and 2

The following raw materials were mixed to prepare a coloring photosensitive composition.

In Table 5, the description of “F-1/F-6” and the like in the column of “Photopolymerization initiator” indicates that a total of 0.33 parts by mass of “F-1” and “F-6” as the photopolymerization initiators were contained, and the content mass ratio of “F-1” and “F-6” was 1:1.

<Composition of Coloring Photosensitive Composition>
Dispersion liquid (G-) of type shown in Table 5: 39.4 parts by mass
Resin D1: 0.58 parts by mass
Polymerizable compound E1 (KAYARAD DPHA, manufactured by Nippon Kayaku Co., Ltd.): 0.54 parts by mass
Photopolymerization initiator (F-) shown in Table 5: 0.33 parts by mass
Surfactant H1: 4.17 parts by mass
p-methoxyphenol: 0.0006 parts by mass
7,7,8,8-tetracyanoquinodimethane: 0.02 parts by mass
PGMEA: 7.66 parts by mass

Details of the materials indicated by the above abbreviations are as follows.

Resin D1: resin having the following structure. The numerical value described together with the main chain indicates a molar ratio. Mw=11,000.

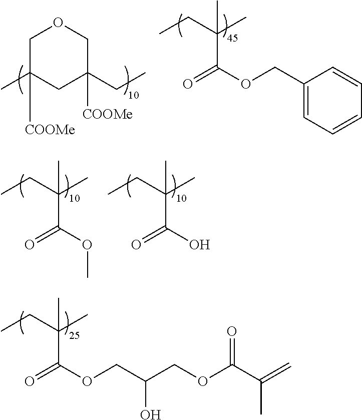

Polymerizable compound E1: KAYARAD DPHA (manufactured by Nippon Kayaku Co., Ltd.)

Photopolymerization initiator F: following compound; F-1 to F-3 are not oxime compounds, and F-4 to F-6 are oxime compounds.
F-1: IRGACURE 369 (manufactured by BASF; molar light absorption coefficient at 365 nm: 800 L·mol⁻¹·cm⁻¹)
F-2: IRGACURE 819 (manufactured by BASF; molar light absorption coefficient at 365 nm: 500 L·mol⁻¹·cm⁻¹)
F-3: IRGACURE 907 (manufactured by BASF; molar light absorption coefficient at 365 nm: 1,100 L·mol⁻¹·cm⁻¹)
F-4: IRGACURE OXE01 (manufactured by BASF; molar light absorption coefficient at 365 nm: 1,500 L·mol⁻¹·cm⁻¹)
F-5: IRGACURE OXE02 (manufactured by BASF; molar light absorption coefficient at 365 nm: 3,500 L·mol⁻¹·cm⁻¹)
F-6: IRGACURE OXE03 (manufactured by BASF; molar light absorption coefficient at 365 nm: 15,000 L·mol⁻¹·cm⁻¹)

Surfactant H1: 1% by mass PGMEA solution of the following mixture (Mw=14,000). In the following formula, “%” representing the proportion of a repeating unit is % by mole)

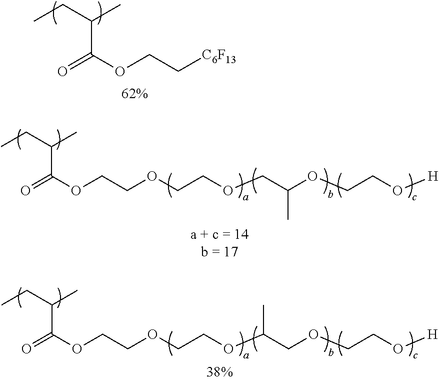

<Evaluation of Dispersibility>

The viscosity of the coloring photosensitive composition obtained in each example or comparative example was measured by “RE-85L” manufactured by TOKI SANGYO CO., LTD. The viscosity of the coloring photosensitive composition was measured in a state in which the temperature was adjusted to 25° C. The measurement results were evaluated according to the following evaluation standard. The evaluation results are shown in Table 5. It can be said that the smaller the viscosity, the better the dispersibility.

[Evaluation Standard]

A: viscosity was 3 mPa·s or less.

B: viscosity was more than 3 mPa·s and 5 mPa·s or less.

C: viscosity was more than 5 mPa·s and 10 mPa·s or less.

D: viscosity was more than 10 mPa·s.

<Evaluation of Storage Stability>

With regard to each example or comparative example, the viscosity of the coloring photosensitive composition obtained as described above was measured by “RE-85L” manufactured by TOKI SANGYO CO., LTD. After that, the coloring photosensitive composition was left to stand under the conditions of 45° C. and 3 days, and then the viscosity thereof was measured again. Storage stability was evaluated according to the following evaluation standard from a viscosity difference (ΔVis) before and after leaving to stand. It can be said that the smaller the numerical value of the viscosity difference (ΔVis), the better the storage stability. The viscosity of the coloring photosensitive composition after leaving to stand was measured in a state in which the temperature was adjusted to 25° C. The evaluation standard is as follows, and the evaluation results are shown in the table below.

[Evaluation Standard]

A: ΔVis was 0.5 mPa·s or less.

B: ΔVis was more than 0.5 mPa·s and 1.0 mPa·s or less.

C: ΔVis was more than 1.0 mPa·s and 2.0 mPa·s or less.

D: ΔVis was more than 2.0 mPa·s.

<Evaluation of Adhesiveness>

An 8-inch (20.32 cm) silicon wafer was coated with CT-4000L (manufactured by FUJIFILM Electronic Materials Co., Ltd.) by using a spin coater such that the thickness after post-baking was 0.1 and then an undercoat layer was formed by heating the silicon wafer at 220° C. for 300 seconds using a hot plate to obtain a silicon wafer (support) with an undercoat layer. Next, each coloring photosensitive composition was applied using a spin coater. Next, the silicon wafer was post-baked using a hot plate at 100° C. for 2 minutes. The film thickness of the layer of the coloring photosensitive composition after post-baking was 0.5 μm.

Next, using an i-ray stepper exposure device FPA-3000 i5+(manufactured by Canon Corporation), exposure was performed with an exposure dose of 200 mJ/cm² through a mask having a Bayer pattern in which a predetermined pixel (pattern) size was formed. As the mask, a mask having a Bayer pattern in which a pixel pattern is formed in a shape of 0.7 μm square, 0.8 μm square, 0.9 μm square, 1.0 μm square, 1.1 μm square, 1.2 μm square, 1.3 μm square, 1.4 μm square, 1.5 μm square, 1.7 μm square, 2.0 μm square, 3.0 μm square, 5.0 μm square, or 10.0 μm square was used.

Next, puddle development was performed at 23° C. for 60 seconds using a tetramethylammonium hydroxide (TMAH) 0.3% by mass aqueous solution. Thereafter, rinsing was performed by a spin shower using pure water. Next, a pattern (pixel) was formed by heating at 200° C. for 5 minutes using a hot plate.

Using a high-resolution field emission beam (FEB) measuring device (HITACHI CD-SEM) S9380II (manufactured by Hitachi High-Tech Corporation.), a pattern having a size of 0.7 μm square, 0.8 μm square, 0.9 μm square, 1.0 μm square, 1.1 μm square, 1.2 μm square, 1.3 μm square, 1.4 μm square, 1.5 μm square, 1.7 μm square, 2.0 μm square, 3.0 μm square, 5.0 μm square, or 10.0 μm square was observed, and the minimum pattern size in which the pattern was formed without peeling was defined as a minimum contact line width. It means that the smaller the minimum contact line width, the better the adhesiveness is.

[Evaluation Standard]

A: minimum contact line width was 1.2 μm square or less.

B: minimum contact line width was more than 1.2 μm square and 1.4 μm square or less.

C: minimum contact line width was more than 1.4 μm square and 1.6 μm square or less.

D: minimum contact line width was more than 1.6 μm square.

<Evaluation of Contrast>

With regard to each example or comparative example, the coloring photosensitive composition was applied to a glass substrate, and a sample was produced such that the thickness of the coating film after drying was 1 The sample was placed between two polarizing plates (USP-50C manufactured by SIGMAKOKI Co., LTD.), the amount of transmitted light in a case where the polarization axes were parallel to each other and the amount of transmitted light in a case where the polarization axes were perpendicular to each other were measured, the ratio thereof was defined as contrast (this evaluation method was based on “7th Color Optical Conference in 1990, Color filter for 512-color 10.4”-size thin film transistor liquid crystal display (TFT-LCD), Ueki, Ozeki, Fukunaga, and Yamanaka”). The results of the measurement evaluation are shown in Table 5. Here, a high contrast shows a high adhesion.

Specifically, the obtained coloring photosensitive composition was applied to a 100 mm×100 mm glass substrate (1737, manufactured by Corning Incorporated) by a spin coating method such that the thickness of the coating film after curing was 1 μm. After the above-described coating, the coloring photosensitive composition was dried (pre-baked) in an oven at 90° C. for 60 seconds. Thereafter, the entire surface of the coating film was exposed at 200 mJ/cm² (illuminance: 20 mW/cm²), and the exposed coating film was covered with a 1% aqueous solution of an alkaline developer CDK-1 (manufactured by FUJIFILM Electronic Materials Co., Ltd.) and allowed to stand still for 60 seconds. After standing still, pure water was sprayed in a shower to wash away the developer. The coating film exposed and developed as developed above was heat-treated (post-baked) in an oven at 220° C. for 1 hour, thereby forming a colored resin film (film according to the embodiment of the present invention) on a glass substrate to produce a colored filter substrate (color filter). A polarizing plate was placed on the above-described colored resin film of the colored filter substrate, and the glass substrate and the colored resin film were sandwiched between the polarizing plate and another polarizing plate from the glass substrate side. Thereafter, the brightness in a case where the polarization axes of the polarizing plate were parallel to each other and the brightness in a case where the polarization axes of the polarizing plate were orthogonal to each other were measured using a BM-5 manufactured by TOPCON CORPORATION, and the value obtained by dividing the brightness in a case of being parallel by the brightness in a case of being orthogonal (=brightness in case of being parallel/brightness in case of being orthogonal) was used as an index for evaluating the contrast. A large value shows a high contrast.

[Evaluation Standard]

A: value was 5,000 or more.

B: value was 2,000 or more and less than 5,000.

C: value was 1,000 or more and less than 2,000.

D: value was less than 1,000.

TABLE 5

| | | Photo | | | | |
|---|---|---|---|---|---|---|
| | Type of | poly- | | | Ad- | |
| | dispersion | merization | Dispers- | Storage | hesive- | Con- |
| | liquid | initiator | ibility | stability | ness | trast |
| Example 1 | G-1 | F-4 | B | A | B | C |
| Example 2 | G-2 | F-4 | B | B | B | C |
| Example 3 | G-3 | F-4 | A | B | A | A |
| Example 4 | G-4 | F-4 | A | B | B | B |
| Example 5 | G-5 | F-4 | A | B | C | A |
| Example 6 | G-6 | F-4 | A | B | B | B |
| Example 7 | G-7 | F-4 | A | B | A | C |
| Example 8 | G-8 | F-4 | C | C | B | B |
| Example 9 | G-9 | F-4 | A | A | B | B |
| Example 10 | G-10 | F-4 | B | B | C | B |
| Example 11 | G-11 | F-4 | B | B | C | B |
| Example 12 | G-12 | F-4 | B | B | C | B |
| Example 13 | G-13 | F-4 | B | B | A | B |
| Example 14 | G-14 | F-4 | A | A | A | A |
| Example 15 | G-15 | F-4 | A | A | A | A |
| Example 16 | G-16 | F-4 | A | A | A | A |
| Example 17 | G-17 | F-4 | A | A | A | C |
| Example 18 | G-18 | F-4 | A | A | A | B |
| Example 19 | G-19 | F-4 | A | A | A | A |
| Example 20 | G-20 | F-4 | A | A | A | B |
| Example 21 | G-21 | F-4 | A | A | A | A |
| Example 22 | G-22 | F-4 | B | A | D | A |
| Example 23 | G-23 | F-4 | B | A | D | A |
| Example 24 | G-24 | F-4 | B | A | A | A |
| Example 25 | G-25 | F-4 | B | B | C | A |
| Example 26 | G-26 | F-4 | A | A | C | A |
| Example 27 | G-27 | F-4 | A | A | A | A |
| Example 28 | G-28 | F-4 | A | A | A | A |
| Example 29 | G-29 | F-4 | A | A | A | A |
| Example 30 | G-30 | F-4 | A | A | A | A |
| Example 31 | G-31 | F-4 | A | A | A | A |
| Example 32 | G-31 | F-4 | A | A | A | A |
| Example 33 | G-4 | F-1 | A | B | C | B |
| Example 34 | G-4 | F-2 | A | B | C | B |
| Example 35 | G-4 | F-3 | A | B | C | B |
| Example 36 | G-4 | F-5 | A | B | A | B |
| Example 37 | G-4 | F-6 | A | B | A | B |
| Example 38 | G-4 | F-1/F-6 | A | A | A | B |
| Example 39 | G-4 | F-4/F-6 | A | A | A | B |
| Example 40 | G-33 | F-4 | C | C | B | B |
| Example 41 | G-34 | F-4 | C | C | C | C |
| Example 42 | G-35 | F-4 | A | A | C | C |
| Example 43 | G-36 | F-4 | A | B | B | B |
| Example 44 | G-37 | F-4 | A | B | B | B |
| Example 45 | G-38 | F-4 | A | B | B | B |
| Example 46 | G-39 | F-4 | A | B | B | B |
| Example 47 | G-40 | F-4 | A | B | A | A |
| Example 48 | G-41 | F-4 | A | B | A | A |
| Example 49 | G-42 | F-4 | A | B | B | B |
| Example 50 | G-43 | F-4 | A | B | B | B |
| Comparative | G-r1 | F-4 | A | D | D | A |
| Example 1 | | | | | | |
| Comparative | G-r2 | F-4 | A | A | A | D |
| Example 2 | | | | | | |
| Comparative | G-r3 | F-4 | A | D | D | A |
| Example 3 | | | | | | |
| Comparative | G-r4 | F-4 | A | D | D | A |
| Example 4 | | | | | | |

As described above, as shown in Examples and Comparative Examples, the coloring photosensitive composition of Examples is excellent in both adhesiveness with a support and contrast of the obtained film.

Since the coloring photosensitive composition in Comparative Example 1 does not include the colorless pigment derivative A1 and includes only the colored pigment derivative A2, the adhesiveness of the obtained film is inferior.

Since the coloring photosensitive composition in Comparative Example 2 does not include the colored pigment derivative A2 and includes only the colorless pigment derivative A1, the contrast of the obtained film is inferior.

Since the coloring photosensitive composition in Comparative Example 3 does not include the colorless pigment derivative A1 and includes only the colored pigment derivative A2, the adhesiveness of the obtained film is inferior.

Since the coloring photosensitive composition in Comparative Example 4 does not include the colorless pigment derivative A1 and includes only the colored pigment derivative A2, the adhesiveness of the obtained film is inferior.

In addition, in a case where, in Example 1, PY150 included in the composition G-1 was changed to C. I. Pigment Yellow 139 in the same part by mass, and the same experiments as in Example 1 were performed, the same results as in Example 1 were obtained.

### Examples 201 to 239

A silicon wafer was coated with a Green composition using a spin coating method so that the thickness of a film after post-baking was 1.0 μm. Next, the coating film was heated using a hot plate at 100° C. for 2 minutes. Next, using an i-ray stepper exposure device FPA-3000 i5+(manufactured by Canon Corporation), the coating film was exposed with light having a wavelength of 365 nm at an exposure dose of 1000 mJ/cm² through a mask having a 2 μm×2 μm dot pattern. Next, puddle development was performed at 23° C. for 60 seconds using a tetramethylammonium hydroxide (TMAH) 0.3% by mass aqueous solution. Next, the coating film was rinsed by spin showering and was cleaned with pure water. Next, the Green composition was patterned by heating (post-baking) at 200° C. for 5 minutes using a hot plate. Likewise, a Red composition and a Blue composition were sequentially patterned to form red, green, and blue-colored patterns (Bayer pattern).

As the Green composition, the coloring photosensitive composition of Example 1 was used in Example 201, the coloring photosensitive composition of Example 2 was used in Example 202, and similarly, the coloring photosensitive compositions of Examples 3 to 39 were used in Examples 203 to 239, respectively.

The Red composition and the Blue composition will be described later.

The Bayer pattern refers to a pattern, as disclosed in the specification of U.S. Pat. No. 3,971,065A, in which a 2×2 array of color filter element having one Red element, two Green elements, and one Blue element is repeated.

The obtained color filter was respectively incorporated into a solid-state imaging element according to a known method. All solid-state imaging elements had a suitable image recognition ability.

[Red Composition]

The following components were mixed and stirred, and the obtained mixture was filtered through a nylon filter (manufactured by Nihon Pall Corporation) having a pore size of 0.45 μm to prepare a Red composition.

Red pigment dispersion liquid: 51.7 parts by mass

40% by mass PGMEA solution of resin D1: 0.6 parts by mass

Polymerizable compound E6: 0.6 parts by mass

Photopolymerization initiator F1: 0.3 parts by mass

Surfactant H1: 4.2 parts by mass

PGMEA: 42.6 parts by mass

[Blue Composition]

The following components were mixed and stirred, and the obtained mixture was filtered through a nylon filter (manufactured by Nihon Pall Corporation) having a pore size of 0.45 μm to prepare a Blue composition.

Blue pigment dispersion liquid: 44.9 parts by mass

40% by mass PGMEA solution of resin D1: 2.1 parts by mass

Polymerizable compound E1: 1.5 parts by mass

Polymerizable compound E6: 0.7 parts by mass

Photopolymerization initiator F1: 0.8 parts by mass

Surfactant H1: 4.2 parts by mass

PGMEA: 45.8 parts by mass

The raw materials used in the preparation of the Red composition and the Blue composition are as follows.

—Red Pigment Dispersion Liquid—

A mixed solution in which 9.6 parts by mass of C. I. Pigment Red 254, 4.3 parts by mass of C. I. Pigment Yellow 139, 6.8 parts by mass of a dispersant (Disperbyk-161, manufactured by BYK Chemie), and 79.3 parts by mass of PGMEA were blended was further mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times. As a result, a Red pigment dispersion liquid was obtained.

—Blue Pigment Dispersion Liquid—

A mixed solution in which 9.7 parts by mass of C. I. Pigment Blue 15:6, 2.4 parts by mass of C. I. Pigment Violet 23, 5.5 parts by mass of a dispersant (Disperbyk-161, manufactured by BYK Chemie), 82.4 parts by mass of PGMEA were blended was further mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times. As a result, a Blue pigment dispersion liquid was obtained.

Resin D1, polymerizable compound E1, photopolymerization initiator F1, and surfactant H1: above-described materials

Polymerizable Compound E6: Compound Having the Following Structure

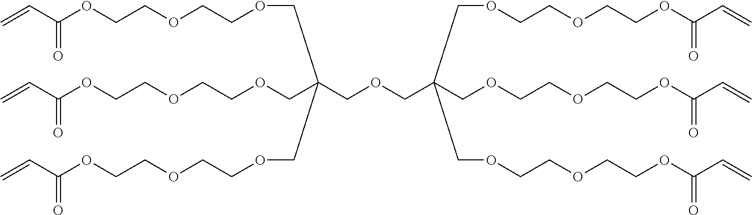 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

What is claimed is:

1. A coloring photosensitive composition comprising:
a pigment derivative A1 in which a maximum value of a molar light absorption coefficient in a wavelength range of 400 to 700 nm is 3,000 L·mol⁻¹·cm⁻¹ or less;
a pigment derivative A2 in which a maximum value of a molar light absorption coefficient in a wavelength range of 400 to 700 nm is more than 3,000 L·mol⁻¹·cm⁻¹;
a pigment;
a polymerizable compound; and
a photopolymerization initiator.

2. The coloring photosensitive composition according to claim 1,
wherein a content of the pigment derivative A1 is 50% to 90% by mass with respect to a total mass of the pigment derivative A1 and the pigment derivative A2.

3. The coloring photosensitive composition according to claim 1,
wherein a total content of the pigment derivative A1 and the pigment derivative A2 is 1 to 30 parts by mass with respect to 100 parts by mass of the pigment.

4. The coloring photosensitive composition according to claim 1,
wherein the pigment derivative A1 is a compound represented by Formula (1),
A¹-L¹-Z¹ (1)
in Formula (1), A¹ represents a group including an aromatic ring,
L¹ represents a single bond or a divalent linking group, and
Z¹ represents a group represented by Formula (Z1), 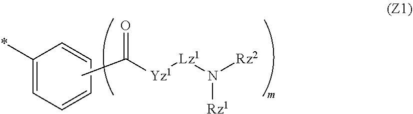
in Formula (Z1), * represents a bonding hand,
Yz¹ represents —N(Ry¹)— or —O—, where Ry¹ represents a hydrogen atom or a hydrocarbon group,
Lz¹ represents a single bond or a divalent linking group,
Rz¹ and Rz² each independently represent a hydrogen atom or a hydrocarbon group, where Rz¹ and Rz² may be bonded to each other through a divalent group to form a ring, and
m represents an integer of 1 to 5.

5. The coloring photosensitive composition according to claim 4,
wherein the group represented by Formula (Z1) is a group represented by Formula (Z2), 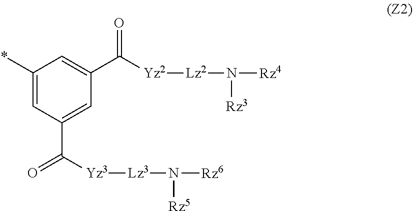
in Formula (Z2), * represents a bonding hand,
Yz² and Yz³ each independently represent —N(Ry²)— or —O—, where Ry^{e} represents a hydrogen atom or a hydrocarbon group,
Lz² and Lz³ each independently represent a divalent linking group, and
Rz³ to Rz⁶ each independently represent a hydrogen atom or a hydrocarbon group, where Rz³ and Rz⁴, and Rz⁵ and Rz⁶ may be respectively bonded to each other through a divalent group to form a ring.

6. The coloring photosensitive composition according to claim 1,
wherein the pigment derivative A2 includes a compound having a coloring agent partial structure, and
the coloring agent partial structure includes a partial structure derived from at least one coloring agent selected from the group consisting of a benzimidazolone coloring agent, a benzimidazolinone coloring agent, a quinophthalone coloring agent, a phthalocyanine coloring agent, an anthraquinone coloring agent, a diketopyrrolopyrrole coloring agent, a quinacridone coloring agent, an azo coloring agent, an isoindolinone coloring agent, an isoindoline coloring agent, a dioxazine coloring agent, a perylene coloring agent, and a thioindigo coloring agent.

7. The coloring photosensitive composition according to claim 1,
wherein the pigment derivative A2 includes at least one partial structure selected from the group consisting of Formulae (Pg-1) to (Pg-10), 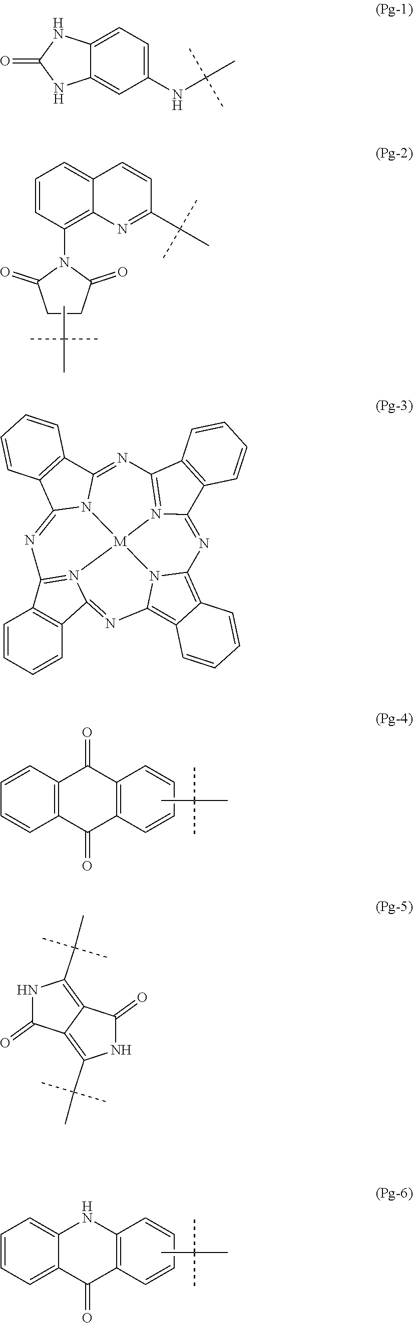 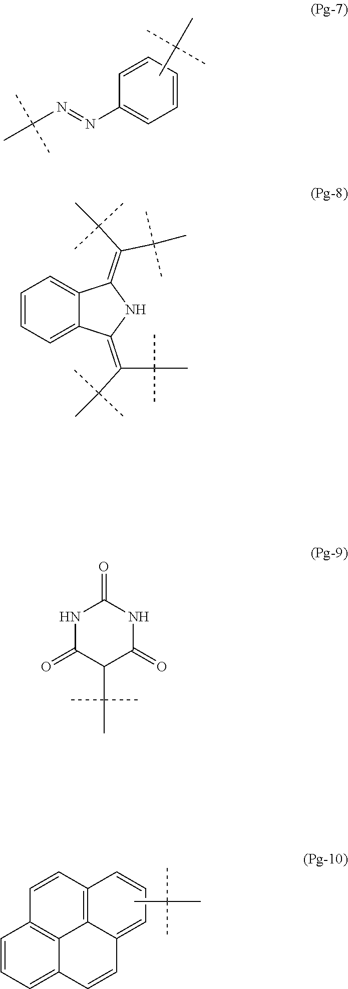
in Formulae (Pg-1) to (Pg-10), a broken line portion represents a bonding site with another structure.

8. The coloring photosensitive composition according to claim 1,
wherein the pigment includes halogenated phthalocyanine.

9. The coloring photosensitive composition according to claim 1,
wherein the photopolymerization initiator includes an oxime compound.

10. The coloring photosensitive composition according to claim 1,
wherein a molar light absorption coefficient of the photopolymerization initiator at a wavelength of 365 nm is 3,000 L·mol⁻¹ cm⁻¹ or more.

11. The coloring photosensitive composition according to claim 1, further comprising:
a dispersant which is a resin.

12. The coloring photosensitive composition according to claim 1, further comprising:
a resin having an acid group.

13. A film formed from the coloring photosensitive composition according to claim 1.

14. A color filter formed from the coloring photosensitive composition according to claim 1.

15. A solid-state imaging element comprising:
the film according to claim 13.

16. An image display device comprising:
the film according to claim 13.
